(19) United States
(12) Patent Application Publication
(10) Pub. No.: US 2026/0262255 A1
(43) Pub. Date: Sep. 3, 2026

(54) SEMICONDUCTOR DEVICE, MEMORY DEVICE, ELECTRONIC DEVICE, AND PROCESSING DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Tsutomu MURAKAWA, Isehara (JP); Hitoshi KUNITAKE, Machida (JP); Sachiaki TEZUKA, Atsugi (JP); Motomu KURATA, Isehara (JP); Yuki OKAMOTO, Ebina (JP); Shoki MIYATA, Atsugi (JP)

(21) Appl. No.: 19/163,966

(22) PCT Filed: Mar. 14, 2024
(86) PCT No.: PCT/IB2024/052438

§ 371 Date: Sep. 10, 2025

(30) Foreign Application Priority Data
Mar. 21, 2023 (JP) 2023-044826
Mar. 31, 2023 (JP) 2023-058277

(51) Int. Cl. H10D 30/67; G11C 11/408; G11C 11/4091; G11C 11/4096; H10B 12/00; H10B 53/10; H10B 53/20; H10B 53/30; H10B 80/00; H10D 1/68; H10D 80/30; H10W 90/00

(52) U.S. Cl. CPC H10D 30/6728; G11C 11/408; G11C 11/4091; G11C 11/4096; H10B 12/33; H10D 1/714; H10D 1/716; H10D 30/6731; H10D 30/6755; H10B 12/036; H10B 12/05; H10B 53/10; H10B 53/20; H10B 53/30; H10B 80/00; H10D 80/30; H10W 90/792

(57) ABSTRACT

A semiconductor device comprising a first layer including a processing portion and a sense amplifier and a second layer including a memory cell is provided. The memory cell is included in a memory device that is used as a cache memory or a main memory in the processing portion. The sense amplifier has a function of reading data retained in the memory cell, and the memory cell includes a transistor and a capacitor. In particular, the transistor is a vertical transistor whose channel formation region is included in a first opening of a first insulating layer. The capacitor includes a first capacitor region in a second opening of a second insulating layer and a second capacitor region in a region overlapping with a top surface of the second insulating layer. The first opening includes a region overlapping with at least part of the second capacitor region.

### TECHNICAL FIELD

One embodiment of the present invention relates to a semiconductor device, a memory device, and a processing device.

Note that one embodiment of the present invention is not limited to the above technical field. The technical field of the invention disclosed in this specification and the like relates to an object, an operation method, or a manufacturing method. Alternatively, one embodiment of the present invention relates to a process, a machine, manufacture, or a composition of matter. Therefore, specific examples of the technical field of one embodiment of the present invention disclosed in this specification include a semiconductor device, a display apparatus (including a liquid crystal display apparatus), a light-emitting apparatus, a power storage device, an imaging device, a memory device, a processing device, a signal processing device, a sensor, an arithmetic device (including a processor), an electronic device, a system, a driving method thereof, a manufacturing method thereof, and a testing method thereof.

### BACKGROUND ART

In recent years, the amount of data subjected to processing has been increasing, which makes a demand for a memory device having a higher memory capacity. A structure in which a plurality of memory cells are stacked above a driver circuit is effective in increasing the recording capacity per unit area (Patent Document 1). When the memory cells are stacked, the recording capacity per unit area can be increased in accordance with the number of stacked memory cells. A further increase in recording capacity per unit area is achieved by stacking a transistor and a capacitor in a memory cell in a DRAM (Dynamic Random Access Memory) (Patent Document 2).

### REFERENCES

### Patent Documents

[Patent Document 1] PCT International Publication No. 2022/238798

[Patent Document 2] Japanese Published Patent Application No. 2012-160718

### SUMMARY OF INVENTION

### Problems to be Solved by the Invention

A memory cell including one transistor and one capacitor is considered. As described above, the recording capacity per unit area in the memory device can be increased when the memory cell has a structure in which a transistor and a capacitor are stacked. Even when the capacitance value of the capacitor is increased by employing a trench structure, a circuit area increase can be avoided. By contrast, the layout area of the transistor, which is a planar transistor, for example, tends to increase compared with that of the capacitor because the planar transistor needs to be provided with an electrode functioning as a source or a drain and a semiconductor layer including a channel formation region provided in the horizontal direction. Thus, the transistor with the reduced layout area can increase the recording capacity per unit area in the memory device.

Furthermore, a wiring (also referred to as a plug or a via wiring in some cases) needs to be provided along the height direction above or below the electrode having a function of one of a source and a drain of the planar transistor to connect the electrode of the transistor and a conductive layer having a function of one of a pair of electrodes of the capacitor. That is, a region for providing the wiring is also required to fabricate the memory cell because the memory cell in which the transistor and the capacitor are stacked includes the wiring provided along the height direction.

An object of one embodiment of the present invention is to provide a memory device with high recording density. Another object of one embodiment of the present invention is to provide a memory device with a small circuit area. Another object of one embodiment of the present invention is to provide a memory device with a high yield. Another object of one embodiment of the present invention is to provide a memory device with reduced manufacturing cost. Another object of one embodiment of the present invention is to provide an electronic device including the memory device. Another object of one embodiment of the present invention is to provide a novel memory device or a novel electronic device.

The above-described memory cell is used in, for example, a cache memory included in a processing device, a main memory connected to a processing device, or the like in some cases. The processing device in this specification and the like refers to, for example, an arithmetic device including a processing portion capable of performing arithmetic processing and the memory device (e.g., a processor such as a CPU (Central Processing Unit)) in some cases.

An example of a means to raise the driving speed of the processing device is to speed up the communication between the processing portion that performs arithmetic processing and the cache memory or the main memory in the processing device.

Furthermore, the circuit area of the cache memory or the main memory is sometimes limited because the cache memory or the main memory included in the processing device is placed in the vicinity of the processing portion. The limited circuit area might lead to limited memory capacity of the cache memory or the main memory.

An object of one embodiment of the present invention is to provide a processing device where high-speed communication is possible between a processing portion and a cache memory or a main memory. Another object of one embodiment of the present invention is to provide a processing device including a cache memory or a main memory with large memory capacity. Another object of one embodiment of the present invention is to provide a processing device including a cache memory or a main memory with high recording density. Another object of one embodiment of the present invention is to provide a processing device with a reduced circuit area.

Note that the objects of one embodiment of the present invention are not limited to the above objects. The above objects do not preclude the existence of other objects. Note that the other objects are objects that are not described in this section and are described below. The objects that are not described in this section can be derived from the description of the specification, the drawings, and the like and can be extracted as appropriate from the description by those skilled in the art. Note that one embodiment of the present invention does not necessarily achieve all of the above objects and the other objects.

### Means for Solving the Problems

In view of the above problems, one embodiment of the present invention is a semiconductor device in which a conductive layer having a function of a source and a conductive layer having a function of a drain are positioned at different levels and a transistor whose channel length direction has a component of the height direction and a capacitor are stacked. In a specific structure example of the semiconductor device, the capacitor is provided in the lower part and the transistor is provided in the upper part.

The capacitor includes a first capacitor region and a second capacitor region. The first capacitor region is a region including a trench capacitor provided in an opening provided in a first interlayer film, and the second capacitor region is a region of a capacitor including a pair of planar electrodes provided on a top surface of the first interlayer film and a dielectric sandwiched between the pair of electrodes.

Specifically, for example, the capacitor includes an upper electrode having a function of one of the pair of electrodes, the dielectric, and a lower electrode having a function of the other of the pair of electrodes. The lower electrode includes regions in contact with a side surface of the first interlayer film corresponding to a side surface of a first opening provided in the first interlayer film, a bottom portion of the first opening provided in the first interlayer film, and the top surface of the first interlayer film. The dielectric includes regions in contact with a top surface of the lower electrode and the top surface of the first interlayer film. The upper electrode includes a region overlapping with the lower electrode with the dielectric therebetween. In the capacitor, the first capacitor region corresponds to the capacitor region provided in the first opening, and the second capacitor region corresponds to a region of the lower electrode, the dielectric, and the upper electrode that are stacked over the top surface of the first interlayer film.

The upper electrode of the capacitor also has a function of one of a source and a drain of the transistor.

A second interlayer film and a conductive layer functioning as the other of the source and the drain of the transistor are provided in this order above the first interlayer film and the upper electrode of the capacitor. In each of the second interlayer film and the conductive layer, a second opening reaching the second capacitor region of the capacitor is provided.

A semiconductor layer including a channel formation region of the transistor includes regions in contact with side surfaces of the second interlayer film and the conductive layer corresponding to a side surface of the second opening, and a top surface of the upper electrode of the capacitor and a top surface of the conductive layer corresponding to a bottom portion of the second opening. A gate insulating film of the transistor includes regions in contact with a top surface of the semiconductor layer and a top surface of the second interlayer film. A gate electrode functioning as a gate of the transistor includes a region overlapping with the semiconductor layer with the gate insulating film therebetween.

The memory device included in the processing device preferably includes the above semiconductor device. The memory device is preferably placed above the processing portion included in the processing device.

Typical structure examples of a semiconductor device, a memory device, an electronic device, and a processing device of one embodiment of the present invention are described below.

(1)

An embodiment of the present invention is a semiconductor device including a transistor and a capacitor. The transistor is positioned above the capacitor.

The transistor includes a first conductive layer having a function of one of a source and a drain, a semiconductor layer comprising a channel formation region, a second conductive layer having a function of the other of the source and the drain, a first insulating layer having a function of a gate insulating film, and a third conductive layer having a function of a gate. The second conductive layer is positioned above the first conductive layer with a second insulating layer therebetween. The second insulating layer and the second conductive layer include a first opening reaching the first conductive layer. The semiconductor layer includes regions in contact with a side surface of each of the second insulating layer and the second conductive layer corresponding to a side surface of the first opening, a top surface of the first conductive layer corresponding to a bottom portion of the first opening, and a top surface of the second conductive layer. The first insulating layer includes regions in contact with a top surface of the semiconductor layer and a top surface of the second insulating layer. The third conductive layer includes a region overlapping with the first opening and the semiconductor layer above the first insulating layer.

The capacitor includes a first capacitor region in a second opening provided in a third insulating layer and a second capacitor region in a region overlapping with a top surface of the third insulating layer. The capacitor includes the first conductive layer having a function of one of a pair of electrodes in each of the first capacitor region and the second capacitor region, and the first opening includes a region overlapping with at least part of the first conductive layer included in the second capacitor region.

(2)

Another embodiment of the present invention can be a structure where, in (1) described above, the capacitor includes a fourth insulating layer having a function of a dielectric and a fourth conductive layer having a function of the other of the pair of electrodes. In particular, the fourth conductive layer preferably includes regions in contact with a side surface of the third insulating layer corresponding to a side surface of the second opening and the top surface of the third insulating layer; the fourth insulating layer preferably includes regions in contact with a top surface of the fourth conductive layer and the top surface of the third insulating layer; and the first conductive layer preferably includes a region overlapping with the fourth conductive layer above the fourth insulating layer.

(3)

Another embodiment of the present invention can be a structure where, in (2) described above, a fifth conductive layer is included. In particular, the fifth conductive layer preferably includes a region corresponding to a bottom portion of the second opening, and the fourth conductive layer preferably includes a region in contact with a top surface of the fifth conductive layer corresponding to the bottom portion of the second opening.

(4)

Another embodiment of the present invention can be a structure where, in (1) described above, the semiconductor layer includes one or more selected from indium, zinc, and an element M in the channel formation region.

Note that the element M is one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, cobalt, magnesium, and antimony.

(5)

Another embodiment of the present invention is a memory device including a memory layer including the semiconductor device according to (1) to (4) described above and a driver circuit. The memory layer is positioned above the driver circuit. The driver circuit includes a write circuit transmitting writing data to the semiconductor device, a read circuit for reading data retained in the semiconductor device, and a selection circuit selecting the semiconductor device to/from which writing/reading is performed.

(6)

Another embodiment of the present invention can be a structure where, in (5) described above, a plurality of the memory layers are included. In particular, the plurality of memory layers are preferably stacked above the driver circuit.

(7)

Another embodiment of the present invention is an electronic device including the memory device in (6) described above and a housing.

(8)

One embodiment of the present invention is a processing device including a processing portion, a sense amplifier, and a memory cell. The memory cell is positioned above each of the processing portion and the sense amplifier. The memory cell also has a function of retaining data related to a task processed in the processing portion. The sense amplifier has a function of reading the data retained in the memory cell.

The memory cell includes a transistor and a capacitor. The transistor is positioned above the capacitor. The transistor includes a first conductive layer having a function of one of a source and a drain, a semiconductor layer comprising a channel formation region, a second conductive layer having a function of the other of the source and the drain, a first insulating layer having a function of a gate insulating film, and a third conductive layer having a function of a gate. The second conductive layer is positioned above the first conductive layer with a second insulating layer therebetween. The second insulating layer and the second conductive layer include a first opening reaching the first conductive layer. The semiconductor layer includes regions in contact with a side surface of each of the second insulating layer and the second conductive layer corresponding to a side surface of the first opening, a top surface of the first conductive layer corresponding to a bottom portion of the first opening, and a top surface of the second conductive layer. The first insulating layer includes regions in contact with a top surface of the semiconductor layer and a top surface of the second insulating layer. The third conductive layer includes a region overlapping with the first opening and the semiconductor layer above the first insulating layer.

The capacitor includes a first capacitor region in a second opening provided in a third insulating layer positioned below the second insulating layer and a second capacitor region in a region overlapping with a top surface of the third insulating layer. The capacitor includes the first conductive layer having a function of one of a pair of electrodes in each of the first capacitor region and the second capacitor region, and the first opening includes a region overlapping with at least part of the first conductive layer included in the second capacitor region.

(9) Another embodiment of the present invention can be a structure where, in (8) described above, the memory cell functions as a cache memory or a main memory in the processing portion.
(10)

Another embodiment of the present invention can be a structure where, in (9) described above, the processing portion includes a control portion, an arithmetic portion, a scan flip-flop circuit, and a backup circuit. In particular, the control portion preferably has a function of performing power gating on the scan flip-flop circuit. The scan flip-flop preferably has a function of retaining the data related to the task processed in the arithmetic portion. The backup circuit preferably has a function of retaining the data while power supply to the scan flip-flop circuit is stopped by the power gating.

(11)

Another embodiment of the present invention can be a structure where, in (10) described above, a first layer is included. Specifically, the first layer can include the sense amplifier, the control portion, the arithmetic portion, the scan flip-flop circuit, and the driver circuit. In particular, the driver circuit preferably includes a write circuit transmitting writing data to the memory cell and a selection circuit selecting the memory cell to/from which writing/reading is performed.

(12)

Another embodiment of the present invention can be a structure where, in (11) described above, a second layer positioned above the first layer is included. Specifically, the second layer can include a plurality of memory cell arrays including the memory cell. In particular, the plurality of memory cell arrays are preferably stacked.

(13)

Another embodiment of the present invention can be a structure where, in any one of (8) to (12) described above, the capacitor includes a fourth insulating layer having a function of a dielectric and a fourth conductive layer having a function of the other of the pair of electrodes. In particular, the fourth conductive layer preferably includes regions in contact with a side surface of the third insulating layer corresponding to a side surface of the second opening and the top surface of the third insulating layer; the fourth insulating layer preferably includes regions in contact with a top surface of the fourth conductive layer and the top surface of the third insulating layer regions in contact with a top surface of the fourth conductive layer and the top surface of the third insulating layer; and the first conductive layer preferably includes a region overlapping with the fourth conductive layer above the fourth insulating layer. In addition, a capacitor having a trench structure is preferably provided in the first capacitor region.

(14)

Another embodiment of the present invention can be a structure where, in (13) described above, a fifth conductive layer including a region overlapping with the third insulating layer is included. In particular, the fifth conductive layer preferably includes a region corresponding to a bottom portion of the second opening, and the fourth conductive layer preferably includes a region in contact with a top surface of the fifth conductive layer corresponding to the bottom portion of the second opening.

(15)

Another embodiment of the present invention can be a structure where, in (14) above, the semiconductor layer includes one or more selected from indium, zinc, and an element M in the channel formation region.

Note that the element Mis one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, cobalt, magnesium, and antimony.

### Effect of the Invention

With the above structure, the semiconductor layer including the channel formation region of the transistor can be provided in the second capacitor region of the capacitor. Specifically, defective formation of the semiconductor layer in the upper electrode of the second capacitor region can be reduced because the upper electrode included in the second capacitor region of the capacitor has a flatter shape than the upper electrode included in the first capacitor region of the capacitor. Accordingly, the yield of the semiconductor device can be increased. The above structure does not require planarization treatment on the upper electrode of the capacitor, leading to a shorter takt time of the semiconductor device and lower manufacturing costs. Furthermore, the above structure where the transistor is provided above the capacitor achieves a greater reduction in circuit area than the case where the capacitor and the transistor are formed in the same layer. The reduction in circuit area can also increase the recording density of the semiconductor device.

One embodiment of the present invention can provide a memory device with high recording density. Another embodiment of the present invention can provide a memory device with a small circuit area. Another embodiment of the present invention can provide a memory device with a high yield. Another embodiment of the present invention can provide a memory device with reduced manufacturing cost. Another embodiment of the present invention can provide an electronic device including the memory device. Another embodiment of the present invention can provide a novel memory device or a novel electronic device.

In the processing device including the processing portion that performs arithmetic processing, the memory device (cache memory or main memory) including the semiconductor device is placed above the processing portion, so that the distance between wirings through which signals are transmitted can be reduced to speed up the communication between the processing portion and the cache memory or the main memory.

Furthermore, the circuit area of the processing device can be reduced with the processing portion and the cache memory or main memory arranged above and below. In the case where the cache memory or the main memory is placed in a layer different from that of the processing portion, the region where the cache memory or the main memory can be provided is larger than that in the case of being placed in the same layer as the processing portion; accordingly, the memory capacity of the cache memory or the main memory can be increased. Moreover, when the sense amplifier used for operation of the memory device is provided in the same layer as the processing portion, the sense amplifier can be shared between the memory device and another circuit, so that the circuit area of the processing device can be reduced.

Another embodiment of the present invention can provide a processing device where high-speed communication is possible between a processing portion and a cache memory or a main memory. Another embodiment of the present invention can provide a processing device including a cache memory or a main memory with large memory capacity. Another embodiment of the present invention can provide a processing device including a cache memory or a main memory with high recording density. Another embodiment of the present invention can provide a processing device with a reduced circuit area.

Note that the effects of one embodiment of the present invention are not limited to the effects listed above. The effects listed above do not preclude the existence of other effects. Note that the other effects are effects that are not described in this section and will be described below. The effects that are not described in this section can be derived from the description of the specification, the drawings, and the like and can be extracted as appropriate from the description by those skilled in the art. One embodiment of the present invention has at least one of the effects listed above and the other effects. Accordingly, one embodiment of the present invention does not have the effects listed above in some cases.

### BRIEF DESCRIPTION OF THE DRAWINGS

FIG. 1A is a schematic plan view illustrating an example of a semiconductor device, and FIG. 1B to FIG. 1D are schematic cross-sectional views illustrating the example of a semiconductor device.

FIG. 2 is a schematic perspective view illustrating an example of a semiconductor device.

FIG. 3 is a schematic perspective view illustrating an example of a semiconductor device.

FIG. 4A is a schematic plan view illustrating an example of regions of a capacitor included in a semiconductor device, and FIG. 4B is a schematic cross-sectional view illustrating the example of regions of a capacitor included in the semiconductor device.

FIG. 5A is a schematic plan view illustrating an example of regions of a capacitor included in a semiconductor device, and FIG. 5B is a schematic cross-sectional view illustrating the example of regions of a capacitor included in the semiconductor device.

FIG. 6A is a schematic plan view illustrating an example of a semiconductor device, and FIG. 6B to FIG. 6D are schematic cross-sectional views illustrating the example of the semiconductor device.

FIG. 7A is a schematic plan view illustrating an example of a semiconductor device, and FIG. 7B to FIG. 7D are schematic cross-sectional views illustrating the example of the semiconductor device.

FIG. 8A is a schematic plan view illustrating an example of a semiconductor device, and FIG. 8B to FIG. 8D are schematic cross-sectional views illustrating the example of the semiconductor device.

FIG. 9A is a schematic plan view illustrating an example of a method for manufacturing a semiconductor device, and FIG. 9B to FIG. 9D are schematic cross-sectional views illustrating the example of a method for manufacturing a semiconductor device.

FIG. 10A is a schematic plan view illustrating an example of a method for manufacturing a semiconductor device, and FIG. 10B to FIG. 10D are schematic cross-sectional views illustrating the example of a method for manufacturing a semiconductor device.

FIG. 11A is a schematic plan view illustrating an example of a method for manufacturing a semiconductor device, and FIG. 11B to FIG. 11D are schematic cross-sectional views illustrating the example of a method for manufacturing a semiconductor device.

FIG. 12A is a schematic plan view illustrating an example of a method for manufacturing a semiconductor device, and FIG. 12B to FIG. 12D are schematic cross-sectional views illustrating the example of a method for manufacturing a semiconductor device.

FIG. 13A is a schematic plan view illustrating an example of a method for manufacturing a semiconductor device, and FIG. 13B to FIG. 13D are schematic cross-sectional views illustrating the example of a method for manufacturing a semiconductor device.

FIG. 14A is a schematic plan view illustrating an example of a method for manufacturing a semiconductor device, and FIG. 14B to FIG. 14D are schematic cross-sectional views illustrating the example of a method for manufacturing a semiconductor device.

FIG. 15A is a schematic plan view illustrating an example of a method for manufacturing a semiconductor device, and FIG. 15B to FIG. 15D are schematic cross-sectional views illustrating the example of a method for manufacturing a semiconductor device.

FIG. 16A is a schematic plan view illustrating an example of a method for manufacturing a semiconductor device, and FIG. 16B to FIG. 16D are schematic cross-sectional views illustrating the example of a method for manufacturing a semiconductor device.

FIG. 17A is a schematic plan view illustrating an example of a method for manufacturing a semiconductor device, and FIG. 17B to FIG. 17D are schematic cross-sectional views illustrating the example of a method for manufacturing a semiconductor device.

FIG. 18A is a schematic plan view illustrating an example of a method for manufacturing a semiconductor device, and FIG. 18B to FIG. 18D are schematic cross-sectional views illustrating the example of a method for manufacturing a semiconductor device.

FIG. 19A is a schematic plan view illustrating an example of a method for manufacturing a semiconductor device, and FIG. 19B to FIG. 19D are schematic cross-sectional views illustrating the example of a method for manufacturing a semiconductor device.

FIG. 20A and FIG. 20B are enlarged views of the schematic plan view of a semiconductor device.

FIG. 21A is a schematic plan view illustrating an example of a method for manufacturing a semiconductor device, and FIG. 21B to FIG. 21D are schematic cross-sectional views illustrating the example of a method for manufacturing a semiconductor device.

FIG. 22A is a schematic plan view illustrating an example of a method for manufacturing a semiconductor device, and FIG. 22B to FIG. 22D are schematic cross-sectional views illustrating the example of a method for manufacturing a semiconductor device.

FIG. 23A is a schematic plan view illustrating an example of a method for manufacturing a semiconductor device, and FIG. 23B to FIG. 23D are schematic cross-sectional views illustrating the example of a method for manufacturing a semiconductor device.

FIG. 24A is a schematic plan view illustrating an example of a method for manufacturing a semiconductor device, and FIG. 24B to FIG. 24D are schematic cross-sectional views illustrating the example of a method for manufacturing a semiconductor device.

FIG. 25A is a schematic plan view illustrating an example of a method for manufacturing a semiconductor device, and FIG. 25B to FIG. 25D are schematic cross-sectional views illustrating the example of a method for manufacturing a semiconductor device.

FIG. 26A is a schematic perspective view illustrating a structure example of a memory device, and FIG. 26B is a block diagram illustrating the structure example of a memory device.

FIG. 27 is a schematic cross-sectional view illustrating a structure example of a memory device. FIG. 28 is a schematic plan view illustrating an example of a memory cell array.

FIG. 29 is a schematic plan view illustrating an example of a memory cell array.

FIG. 30 is a schematic plan view illustrating an example of a memory cell array.

FIG. 31A and FIG. 31B are schematic perspective views illustrating an example of a memory cell array.

FIG. 32A and FIG. 32B are schematic perspective views illustrating an example of a memory cell array.

FIG. 33A and FIG. 33B are schematic perspective views illustrating an example of a memory cell array.

FIG. 34 is a schematic perspective view illustrating an example of a plurality of memory layers.

FIG. 35 is a circuit diagram illustrating a structure example of a memory device.

FIG. 36 is a circuit diagram illustrating a structure example of a memory device.

FIG. 37A is a circuit diagram illustrating a structure example of a memory device, and FIG. 37B is a timing chart illustrating an operation example of the memory device.

FIG. 38 is a block diagram illustrating a structure example of an arithmetic device.

FIG. 39 is a block diagram illustrating a structure example of a memory circuit.

FIG. 40A and FIG. 40B are perspective views illustrating an example of a processing device.

FIG. 41A and FIG. 41B are perspective views illustrating an example of a processing device.

FIG. 42 is a perspective view illustrating an example of a processing device.

FIG. 43 is a perspective view illustrating an example of a processing device.

FIG. 44A to FIG. 44H are circuit diagrams illustrating structure examples of memory cells.

FIG. 45A and FIG. 45B are diagrams each illustrating a hierarchy of a variety of memory devices.

FIG. 46 is a block diagram illustrating a structure example of a processing device.

FIG. 47A and FIG. 47B are schematic views illustrating structure examples of a processing device.

FIG. 48A to FIG. 48D are schematic diagrams illustrating structure examples of a processing device.

FIG. 49 is a circuit diagram illustrating a structure example of a register.

FIG. 50 is a timing chart illustrating an operation example of a register.

FIG. 51A to FIG. 51D are schematic views illustrating operation examples of a register.

FIG. 52 is a timing chart illustrating an operation example of a register.

FIG. 53A to FIG. 53G are schematic views illustrating operation examples of a register.

FIG. 54 is a circuit diagram illustrating a structure example of a memory device.

FIG. 55 is a circuit diagram illustrating a structure example of a memory device.

FIG. 56 is a timing chart illustrating an operation example of a memory device.

FIG. 57A and FIG. 57B are diagrams illustrating examples of electronic components.

FIG. 58A and FIG. 58B are diagrams illustrating examples of electronic devices, and FIG. 58C to FIG. 58E are diagrams illustrating an example of a large computer.

FIG. 59 is a diagram illustrating an example of space equipment.

FIG. 60 is a diagram illustrating an example of a storage system that can be used in a data center.

### MODE FOR CARRYING OUT INVENTION

In this specification and the like, a semiconductor device refers to a device that utilizes semiconductor characteristics, and means a circuit including a semiconductor element (e.g., a transistor, a diode, and a photodiode), or a device including the circuit. The semiconductor device also means all devices that can function by utilizing semiconductor characteristics. An example of a semiconductor device is an integrated circuit. Another example of a semiconductor device is a chip that includes an integrated circuit. Another example of a semiconductor device is an electronic component in which a chip is stored in a package. Moreover, a memory device, a display apparatus, a light-emitting apparatus, an arithmetic device, a lighting device, an electronic device, and the like themselves are semiconductor devices in some cases and include semiconductor devices in other cases.

In the case where there is description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relationship, for example, a connection relationship shown in drawings or texts, a connection relationship other than one shown in drawings or texts is regarded as being disclosed in the drawings or the texts. Each of X and Y denotes an object (e.g., a device, an element, a circuit, a wiring, an electrode, a terminal, a conductive film, or a layer).

For example, in the case where X and Y are electrically connected, one or more elements that allow electrical connection between X and Y (e.g., a switch, a transistor, an inductor, a resistor, a diode, a display device, a light-emitting device, and a load) can be connected between X and Y. Note that a switch has a function of being controlled to be turned on or off. That is, the switch has a function of being in a conduction state (on state) or a non-conduction state (off state) to control whether a current flows or not.

For example, in the case where X and Y are functionally connected, one or more circuits that allow functional connection between X and Y (e.g., a logic circuit (e.g., an inverter, a NAND circuit, or a NOR circuit); a signal converter circuit (e.g., a digital-to-analog converter circuit, an analog-digital converter circuit, or a gamma correction circuit); a potential level converter circuit (e.g., a power supply circuit such as a step-up circuit or a step-down circuit, or a level shifter circuit for changing the potential level of a signal); a voltage source; a current source; a switching circuit; an amplifier circuit (e.g., a circuit that can increase signal amplitude, the amount of current, or the like, an operational amplifier, a differential amplifier circuit, a source follower circuit, or a buffer circuit); a signal generation circuit; a memory circuit; or a control circuit) can be connected between X and Y. For instance, even if another circuit is provided between X and Y, X and Y are regarded as being functionally connected when a signal output from X is transmitted to Y.

Note that an explicit description “X and Y are electrically connected” includes the case where X and Y are electrically connected (i.e., the case where X and Y are connected with another element or another circuit provided therebetween) and the case where X and Y are directly connected (i.e., the case where X and Y are connected without another element or another circuit provided therebetween).

For example, an expression “X, Y, a source (sometimes called one of a first terminal and a second terminal, for example) of a transistor, and a drain (sometimes called the other of the first terminal and the second terminal, for example) of the transistor are electrically connected to each other, and X, the source of the transistor, the drain of the transistor, and Y are electrically connected to each other in this order” can be used. Alternatively, an expression “a source of a transistor is electrically connected to X; a drain of the transistor is electrically connected to Y; and X, the source of the transistor, the drain of the transistor, and Y are electrically connected to each other in this order” can be used. Alternatively, an expression “X is electrically connected to Y through a source and a drain of a transistor, and X, the source of the transistor, the drain of the transistor, and Y are provided in this connection order” can be used. When the connection order in a circuit structure is defined by an expression like the above examples, a source and a drain of a transistor can be distinguished from each other to specify the technical scope. Note that these expressions are non-limiting examples. Here, X and Y each denote an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has both a function of a wiring and a function of an electrode. Thus, electrical connection in this specification includes, in its category, such a case where one conductive film has functions of a plurality of components.

In this specification and the like, a “resistor” can be, for example, a circuit element having a resistance value higher than 0 22 or a wiring having a resistance value higher than 0 22. Therefore, in this specification and the like, a “resistor” includes a wiring having a resistance value, a transistor in which a current flows between a source and a drain, a diode, and a coil. Thus, the term “resistor” can sometimes be replaced with the terms “resistance”, “load”, or “region having a resistance value”. Conversely, the terms “resistance”, “load”, or “region having a resistance value” can sometimes be replaced with the term “resistor”. The resistance value can be, for example, preferably higher than or equal to 1 mΩ and lower than or equal to 10 Ω, further preferably higher than or equal to 5 mΩ and lower than or equal to 5 Ω, still further preferably higher than or equal to 10 mΩ and lower than or equal to 1 Ω. For another example, the resistance value is preferably higher than or equal to 1 Ω and lower than or equal to 1×10⁹ Ω.

In this specification and the like, a “capacitor” can be, for example, a circuit element having an electrostatic capacitance value higher than 0 F, a region of a wiring having an electrostatic capacitance value higher than 0 F or gate capacitance of a transistor. The term “capacitor” or “gate capacitance” can be replaced with the term “capacitance” in some cases. Conversely, the term “capacitance” can be replaced with the term “capacitor” or “gate capacitance” in some cases. In addition, a “capacitor” (including a “capacitor” with three or more terminals) includes an insulator and a pair of conductors between which the insulator is interposed. Thus, the term “pair of conductors” of “capacitor” can be replaced with “pair of electrodes”, “pair of conductive regions”, “pair of regions”, or “pair of terminals”. In addition, the terms “one of a pair of terminals” and “the other of the pair of terminals” are referred to as a first terminal and a second terminal, respectively, in some cases. Note that the electrostatic capacitance value can be higher than or equal to 0.05 fF and lower than or equal to 10 pF, for example. For another example, the electrostatic capacitance value is preferably higher than or equal to 1 pF and lower than or equal to 10 μF.

In this specification and the like, a transistor includes three terminals called a gate, a source, and a drain. The gate is a control terminal for controlling the conduction state of the transistor. Two terminals functioning as the source and the drain are input/output terminals of the transistor. One of the two input/output terminals serves as the source and the other serves as the drain on the basis of the conductivity type (n-channel type or p-channel type) of the transistor and the levels of potentials applied to the three terminals of the transistor. Thus, the terms “source” and “drain” can sometimes be replaced with each other in this specification and the like. In this specification and the like, expressions “one of a source and a drain” (or a first electrode or a first terminal) and “the other of the source and the drain” (or a second electrode or a second terminal) are used in description of the connection relationship of a transistor. Depending on the transistor structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, the gates may be referred to as a first gate, a second gate, a third gate, and the like in this specification and the like In this specification and the like, for example, a transistor with a multi-gate structure having two or more gate electrodes can be used as the transistor. With the multi-gate structure, channel formation regions are connected to each other in series; accordingly, a plurality of transistors are connected to each other in series. Thus, with the multi-gate structure, the amount of an off-state current can be reduced, and the breakdown voltage of the transistor can be increased (the reliability can be improved). Alternatively, with the multi-gate structure, drain-source current does not change very much even if drain-source voltage changes at the time of an operation in a saturation region, so that a flat slope of voltage-current characteristics can be obtained. By utilizing the flat slope of the voltage-current characteristics, an ideal current source circuit or an active load having an extremely high resistance value can be obtained. Accordingly, a differential circuit, a current mirror circuit, and the like having excellent properties can be obtained.

The case where a single circuit element is illustrated in a circuit diagram may include a case where the circuit element includes a plurality of circuit elements. For example, the case where a single resistor is illustrated in a circuit diagram may include a case where two or more resistors are electrically connected to each other in series. For another example, the case where a single capacitor is illustrated in a circuit diagram may include a case where two or more capacitors are electrically connected to each other in parallel. For another example, the case where a single transistor is illustrated in a circuit diagram may include a case where two or more transistors are electrically connected to each other in series and gates of the transistors are electrically connected to each other. Similarly, for another example, the case where a single switch is illustrated in a circuit diagram may include a case where the switch includes two or more transistors, the two or more transistors are electrically connected to each other in series or in parallel, and gates of the transistors are electrically connected to each other.

In this specification and the like, a node can be referred to as a terminal, a wiring, an electrode, a conductive layer, a conductor, or an impurity region depending on the circuit structure and the device structure. Furthermore, a terminal, a wiring, or the like can be referred to as a node.

In this specification and the like, a selector sometimes refers to, for example, a circuit in which a plurality of input terminals and one output terminal are included, one of the plurality of input terminals is selected, and electrical continuity is established between the selected input terminal and the one output terminal. In other words, the selector is sometimes a circuit in which one of input signals input to the plurality of input terminals is selected and the selected input signal is output to the output terminal. Alternatively, for example, a selector sometimes refers to a circuit in which a plurality of output terminals and one input terminal are included, one of the plurality of output terminals is selected, and electrical continuity is established between the selected output terminal and the one input terminal. In other words, the selector is sometimes a circuit in which one of the plurality of output terminals is selected and an input signal input to the input terminal is output to the selected output terminal. That is, the selector sometimes refers to a multiplexer or a demultiplexer. In particular, in the case where an analog potential or an analog current is input or output, the selector may sometimes refer to an analog multiplexer or an analog demultiplexer.

In this specification and the like, a “voltage” and a “potential” can be replaced with each other as appropriate. A “voltage” refers to a potential difference from a reference potential, and when the reference potential is a ground potential, for example, a “voltage” can be replaced with a “potential”. Note that the ground potential does not necessarily mean 0 V. Moreover, potentials are relative values, and a potential supplied to a wiring, a potential applied to a circuit or the like, and a potential output from a circuit or the like, for example, change with a change of the reference potential.

In this specification and the like, the terms “high-level potential” and “low-level potential” do not mean a particular potential. For example, in the case where two wirings are both described as “functioning as a wiring for supplying a high-level potential”, the levels of the high-level potentials supplied from the wirings are different from each other in some cases. Similarly, in the case where two wirings are both described as “functioning as a wiring for supplying a low-level potential”, the levels of the low-level potentials supplied from the wirings are different from each other in some cases.

A “current” means a charge transfer phenomenon (electrical conduction); for example, the description “electrical conduction of positively charged particles occurs” can be rephrased as “electrical conduction of negatively charged particles occurs in the opposite direction”. Therefore, unless otherwise specified, a “current” in this specification and the like refers to a charge transfer phenomenon (electrical conduction) accompanying carrier movement. Examples of a carrier here include an electron, a hole, an anion, a cation, and a complex ion, and the type of carrier differs between current flow systems (e.g., a semiconductor, a metal, an electrolyte solution, and a vacuum). The “direction of a current” in a wiring or the like refers to the direction in which a carrier with positive charge moves, and the amount of the current is expressed as a positive value. In other words, the direction in which a carrier with negative charge moves is opposite to the direction of a current, and the amount of the current is expressed as a negative value. Thus, in the case where the polarity of a current (or the direction of a current) is not specified in this specification and the like, the description “a current flows from element A to element B” can be rephrased as “a current flows from element B to element A”. The description “a current is input to element A” can be rephrased as “a current is output from element A”.

Ordinal numbers such as “first”, “second”, and “third” in this specification and the like are used in order to avoid confusion among components. Thus, the terms do not limit the number of components. The terms do not limit the order of components, either. For example, a “first” component in one embodiment in this specification and the like can be referred to as a “second” component in other embodiments or the scope of claims. For another example, a “first” component in one embodiment in this specification and the like can be omitted in other embodiments or the scope of claims.

In this specification and the like, the terms for describing positioning, such as “over” and “under”, are sometimes used for convenience to describe the positional relationship between components with reference to drawings. The positional relationship between components is changed as appropriate in accordance with the direction in which the components are described. Thus, the positional relationship is not limited to the terms described in the specification and the like, and can be described with another term as appropriate depending on the situation. For example, the expression “an insulator located over (on) a top surface of a conductor” can be replaced with the expression “an insulator located under (on) a bottom surface of a conductor” when the direction of a drawing illustrating these components is rotated by 180°.

Furthermore, the terms “over” and “under” do not necessarily mean that a component is placed directly over or directly under and in direct contact with another component. For example, the expression “electrode B over insulating layer A” does not necessarily mean that the electrode B is formed over and in direct contact with the insulating layer A, and does not exclude the case where another component is provided between the insulating layer A and the electrode B. Similarly, for example, the expression “electrode B above insulating layer A” does not necessarily mean that the electrode B is formed above and in direct contact with the insulating layer A, and does not exclude the case where another component is provided between the insulating layer A and the electrode B. Similarly, for example, the expression “electrode B under insulating layer A” does not necessarily mean that the electrode B is formed under and in direct contact with the insulating layer A, and does not exclude the case where another component is provided between the insulating layer A and the electrode B.

In this specification and the like, components arranged in a matrix and their positional relationship are sometimes described using terms such as “row” and “column”. The positional relationship between components is changed as appropriate in accordance with the direction in which the components are described. Thus, the positional relationship is not limited to the terms described in the specification and the like, and can be described with another term as appropriate depending on the situation. For example, the term “row direction” can be replaced with the term “column direction” when the direction of the drawing is rotated by 90°.

In this specification and the like, the terms “film” and “layer” can be interchanged with each other depending on the situation. For example, the term “conductive layer” can be replaced with the term “conductive film” in some cases. For another example, the term “insulating film” can be changed into the term “insulating layer” in some cases. Alternatively, the terms “film” and “layer” are not used and can be interchanged with another term depending on the case or the situation. For example, the term “conductive layer” or “conductive film” can be changed into the term “conductor” in some cases. Furthermore, for example, the term “insulating layer” or “insulating film” can be changed into the term “insulator” in some cases.

In this specification and the like, the terms “electrode”, “wiring”, “terminal”, and the like do not limit the functions of such components. For example, an “electrode” is used as part of a “wiring” in some cases, and vice versa. Furthermore, the term “electrode” or “wiring” also refers to, for example, the case where a plurality of “electrodes” or “wirings” are formed in an integrated manner. For example, a “terminal” is used as part of a “wiring” or an “electrode” in some cases, and vice versa. Furthermore, the term “terminal” also refers to the case where one or more selected from “electrodes”, “wirings”, and “terminals” are formed in an integrated manner, for example. Therefore, for example, an “electrode” can be part of a “wiring” or a “terminal”, and a “terminal” can be part of a “wiring” or an “electrode”. Moreover, the term “electrode”, “wiring”, or “terminal” is sometimes replaced with the term “region” depending on the case.

In this specification and the like, the terms “wiring”, “signal line”, and “power supply line” can be interchanged with each other depending on the case or the situation. For example, the term “wiring” can be changed into the term “signal line” in some cases. For another example, the term “wiring” can be changed into the term “power supply line” or the like in some cases. Conversely, the term “signal line” or “power supply line” can be changed into the term “wiring” in some cases. The term “power supply line” can be changed into the term “signal line” in some cases. Conversely, the term “signal line” can be changed into the term “power supply line” in some cases. The term “potential” that is applied to a wiring can be changed into the term “signal” depending on the case or the situation. Conversely, the term “signal” can be changed into the term “potential” in some cases.

In this specification and the like, a timing chart is used in some cases to describe an operation method of a semiconductor device. The timing chart used in this specification and the like shows an ideal operation example and a period, a level of a signal (e.g., a potential or a current), and a timing described in the timing chart are not limited unless otherwise specified. In the timing chart described in this specification and the like, the level of a signal (e.g., a potential or a current) input to a wiring (including a node) and a timing can be changed depending on the situation. For example, even when two periods are shown to have an equal length in the timing chart, the two periods have different lengths in some cases. Furthermore, for example, even when one of two periods is shown long and the other is shown short, the two periods can have the equal length in some cases, or the one period can have a short length and the other can have a long length in other cases.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is included in a channel formation region of a transistor, the metal oxide is referred to as an oxide semiconductor in some cases. That is, when a metal oxide can form a channel formation region of a transistor that has at least one of an amplifying function, a rectifying function, and a switching function, the metal oxide can be referred to as a metal oxide semiconductor. In the case where an OS transistor is mentioned, the OS transistor can also be referred to as a transistor including a metal oxide or an oxide semiconductor.

In this specification and the like, a metal oxide containing nitrogen is also referred to as a metal oxide in some cases. Alternatively, a metal oxide containing nitrogen is called a metal oxynitride in some cases.

In this specification and the like, an impurity in a semiconductor refers to, for example, an element other than a main component of a semiconductor layer. For example, an element with a concentration lower than 0.1 atomic % is an impurity. When an impurity is contained, for example, one or more selected from an increase in the density of defect states in a semiconductor, a decrease in carrier mobility, and a decrease in crystallinity occur in some cases. In the case where the semiconductor is an oxide semiconductor, examples of an impurity that changes characteristics of the semiconductor include Group 1 elements, Group 2 elements, Group 13 elements, Group 14 elements, Group 15 elements, and transition metals other than the main components; specific examples are hydrogen (contained also in water), lithium, sodium, silicon, boron, phosphorus, carbon, and nitrogen.

In this specification and the like, a switch refers to an element having a function of being in a conduction state (on state) or a non-conduction state (off state) to control whether a current flows or not. Alternatively, a switch refers to an element having a function of selecting and changing a current path. Thus, a switch may have two terminals or three or more terminals through which a current flows, in addition to a control terminal. For example, an electrical switch or a mechanical switch can be used. Thus, unless otherwise specified, a switch is not limited to a particular one.

Examples of an electrical switch include a transistor (e.g., a bipolar transistor and a MOS transistor), a diode (e.g., a PN diode, a PIN diode, a Schottky diode, a MIM (Metal Insulator Metal) diode, a MIS (Metal Insulator Semiconductor) diode, and a diode-connected transistor), and a logic circuit in which such elements are combined. Note that in the case of using a transistor as a switch, a “conduction state” of the transistor refers to a state where a source electrode and a drain electrode of the transistor can be regarded as being electrically short-circuited or a state where a current can be made to flow between the source electrode and the drain electrode. Furthermore, a “non-conduction state” of the transistor refers to a state where the source electrode and the drain electrode of the transistor can be regarded as being electrically disconnected. Note that in the case where a transistor operates just as a switch, there is no particular limitation on the polarity (conductivity type) of the transistor.

An example of a mechanical switch is a switch formed using a MEMS (micro electro mechanical systems) technology. Such a switch includes an electrode that can be moved mechanically, and operates by controlling a conduction state and a non-conduction state with movement of the electrode.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “approximately perpendicular” or “substantially perpendicular” indicates a state where two straight lines are placed at an angle greater than or equal to 60° and less than or equal to 120°.

In this specification and the like, one embodiment of the present invention can be constituted by appropriately combining a structure described in an embodiment with any of the structures described in the other embodiments. In addition, in the case where a plurality of structure examples are described in one embodiment, the structure examples can be combined as appropriate.

Note that a content (whole or part thereof) described in one embodiment can be applied to, combined with, or replaced with at least one of another content (whole or part thereof) in the embodiment and a content (whole or part thereof) described in one or a plurality of different embodiments.

Note that in each embodiment, a content described in the embodiment is a content described using a variety of diagrams or a content described with text disclosed in the specification.

Note that by combining a diagram (or part thereof) described in one embodiment with at least one of another part of the diagram, a different diagram (whole or part thereof) described in the embodiment, and a diagram (whole or part thereof) described in one or a plurality of different embodiments, much more diagrams can be provided.

Embodiments described in this specification are described with reference to the drawings. Note that the embodiments can be implemented in many different modes, and it will be readily appreciated by those skilled in the art that modes and details can be changed in various ways without departing from the spirit and scope thereof. Thus, the present invention should not be interpreted as being limited to the description in the embodiments. Note that in the structures of the invention in the embodiments, the same portions or portions having similar functions are denoted by the same reference numerals in different drawings, and repeated description thereof is omitted in some cases. In perspective views and the like, illustration of some components may be omitted for clarity of the drawings.

In this specification and the like, when a plurality of components are denoted with the same reference numerals, and in particular need to be distinguished from each other, an identification sign such as “_1”, “[n]”, or “[m,n]” is sometimes added to the reference numerals. Components denoted with identification signs such as “_1”, “[n]”, and “[m,n]” in the drawings and the like are sometimes described without such identification signs in this specification and the like when the components do not need to be distinguished from each other.

In the drawings in this specification, the size, the layer thickness, or the region is exaggerated for clarity in some cases. Thus, the size, the layer thickness, or the region is not limited to the illustrated scale. The drawings are schematic views showing ideal examples, and embodiments of the present invention are not limited to shapes, values, or the like shown in the drawings. For example, variations in a signal, a voltage, or a current due to noise, variations in a signal, a voltage, or a current due to difference in timing, or the like can be included.

### Embodiment 1

In this embodiment, a memory cell that is a semiconductor device of one embodiment of the present invention will be described.

### Structure Example 1

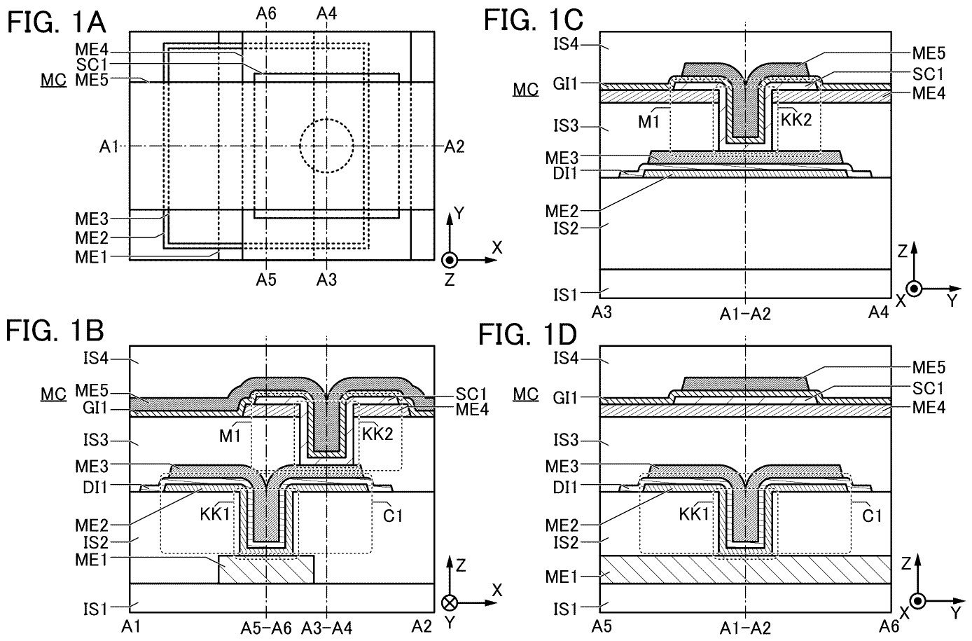

FIG. 1A to FIG. 1D illustrate a structure example of a memory cell MC. FIG. 1A is a schematic plan view of the memory cell MC. FIG. 1B is a schematic cross-sectional view corresponding to a portion taken along dashed-dotted line A1-A2 shown in FIG. 1A. FIG. 1C is a schematic cross-sectional view corresponding to a portion taken along dashed-dotted line A3-A4 in FIG. 1A. FIG. 1B is a schematic cross-sectional view corresponding to a portion taken along dashed-dotted line A5-A6 shown in FIG. 1A.

Note that in FIG. 1A to FIG. 1D, the direction of the dashed-dotted line A1-A2 is an X direction, and the directions of the dashed-dotted line A3-A4 and the dashed-dotted line A5-A6 are each a Y direction. Moreover, a direction perpendicular to the X direction and the Y direction is a Z direction. The X direction and the Y direction can be directions perpendicular to each other. The definition of the X direction, the Y direction, and the Z direction applies to some of the following drawings and does not apply to other drawings. In the description of the schematic plan view in FIG. 1A and the like, in some cases, the right side, the left side, the upper side, and the lower side are referred to as the +X direction, a −X direction, the +Y direction, and a −Y direction, respectively. In the description of the schematic cross-sectional view in FIG. 1B and the like, in some cases, the right side, the left side, the upper side, and the lower side are referred to as the +X direction, the −X direction, the +Z direction, and a −Z direction, respectively. In the description of the schematic cross-sectional views such as FIG. 1C, FIG. 1D, and the like, in some cases, the right side, the left side, the upper side, and the lower side are referred to as the +Y direction, a −Y direction, the +Z direction, and the −Z direction, respectively.

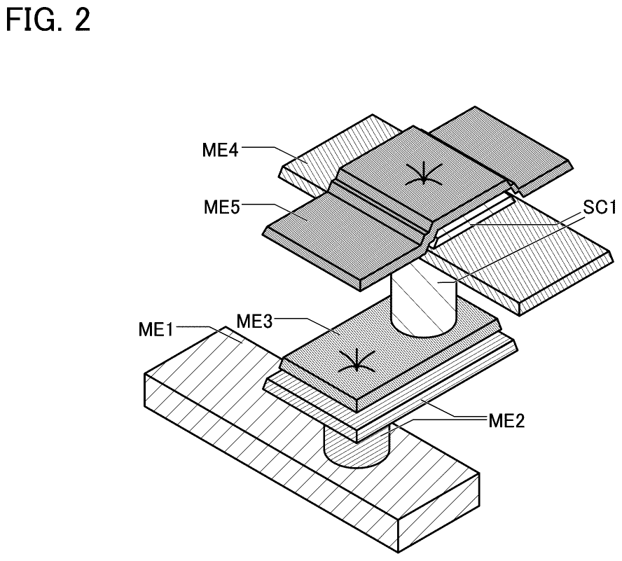

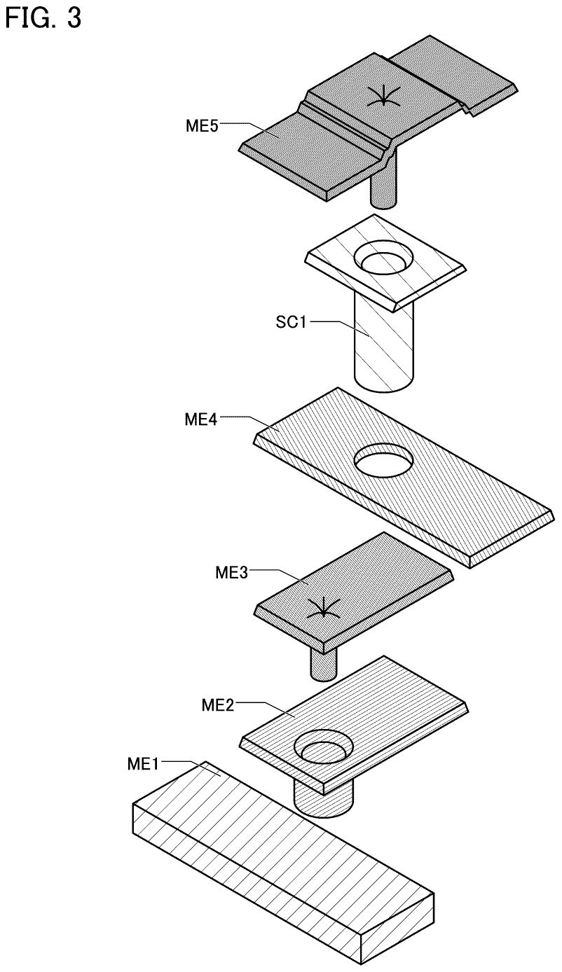

FIG. 2 and FIG. 3 are schematic perspective views of the memory cell MC illustrated in FIG. 1A to FIG. 1D. Note that components such as an insulating layer included in the memory cell MC are omitted in FIG. 2 and FIG. 3. FIG. 3 illustrates some components illustrated in FIG. 2 shifted in the vertical direction.

The memory cell MC illustrated in FIG. 1A to FIG. 1D includes a transistor M1 and a capacitor C1, for example. A memory cell composed of one transistor and one capacitor is particularly referred to as a DRAM in some cases. In particular, a DRAM using a transistor including an oxide semiconductor in its channel formation region is referred to as a DOSRAM (registered trademark) (Dynamic Oxide Semiconductor Random Access Memory) in some cases.

In the memory cell MC, the transistor MI is positioned above the capacitor C1 as illustrated in FIG. 1B to FIG. 1D.

The transistor M1 illustrated in FIG. 1A to FIG. 1D has a structure in which a conductive layer having a function of a source and a conductive layer having a function of a drain are positioned at different levels and a current flowing through a semiconductor layer flows in the height direction. In other words, the channel length direction can be regarded as having a component of the height direction (vertical or Z-direction). Thus, the transistor M1 can also be referred to as a VFET (Vertical Field Effect Transistor), a vertical transistor, a vertical-channel transistor, a vertical-channel-type transistor, or the like. Furthermore, since the channel length of the transistor M1 is determined by the thickness of an insulating layer positioned between the conductive layer having a function of a source and the conductive layer having a function of a drain, the channel length of the transistor M1 can be reduced more easily than the channel length of a planar transistor, for example.

The capacitor C1 illustrated in FIG. 1A to FIG. 1D is a capacitor having a MIM (Metal-Insulator-Metal) structure. The capacitor C1 has a trench structure (also referred to as a cylinder structure in some cases) because the MIM structure is formed on each of a side surface and a bottom portion of an opening KK1 described later, for example. In other words, the opening KK1 includes a capacitor region having the MIM structure on the side surface in the height direction and a capacitor region having the MIM structure on the bottom portion in the plane direction; that is, the capacitor C1 includes a capacitor region having a trench structure. The capacitor C1 includes, for example, a capacitor region in which a dielectric is sandwiched between a pair of electrodes having a planar shape or a substantially planar shape (each referred to as planar electrodes in this specification and the like) above an insulating layer IS2 described later. That is, the capacitor Cl includes a first capacitor region positioned in the opening KK1 and a second capacitor region positioned in a region overlapping with a top surface of the insulating layer IS2. Note that the details of the first capacitor region and the second capacitor region of the capacitor C1 included in the memory cell MC will be described later.

The capacitor C1 includes, for example, a conductive layer ME3 having a function of one of the pair of electrodes, a conductive layer ME2 having a function of the other of the pair of electrodes, and an insulating layer DI1 having a function of the dielectric.

The transistor M1 includes, for example, the conductive layer ME3 having a function of one of a source and a drain, a conductive layer ME4 having a function of the other of the source and the drain, a conductive layer ME5 having a function of a gate, a semiconductor layer SC1 including a channel formation region, and an insulating layer GI1 having a function of a gate insulating film.

As described above, the conductive layer ME3 has both a function of one of the source and the drain of the transistor M1 and a function of one of the pair of electrodes of the capacitor C1.

The transistor M1 and the capacitor C1 are positioned above an insulating layer IS1. The insulating layer IS1 has a function of, for example, a base film above which the transistor M1 and the capacitor C1 are to be provided.

The conductive layer ME1 is positioned above the insulating layer IS1. The conductive layer ME1 has a function of a wiring for supplying an electrical signal (e.g., a potential or a current) to the conductive layer ME2 having a function of the other of the pair of electrodes of the capacitor C1, for example. Thus, the conductive layer ME1 extends along the ±Y direction in FIG. 1A to FIG. 1D as an example.

The insulating layer IS2 is positioned above the insulating layer IS1 and the conductive layer ME1. The insulating layer IS2 has a function of an interlayer film that separates the conductive layer ME1 and the conductive layer ME3, for example. Providing the insulating layer IS2 can prevent direct contact (short circuit) between the conductive layer ME1 and the conductive layer ME3. The insulating layer IS2 includes the opening KK1 in a region overlapping with part of the conductive layer ME1.

The conductive layer ME2 includes regions in contact with a side surface of the insulating layer IS2 corresponding to a side surface of the opening KK1, a top surface of the conductive layer ME1 corresponding to a bottom portion of the opening KK1, and a top surface of the insulating layer IS2.

The insulating layer DI1 includes regions in contact with the top surface of the insulating layer IS2 and a top surface of the conductive layer ME2. In particular, the insulating layer DI1 covers the conductive layer ME2, including an end portion of the conductive layer ME2, which can prevent direct contact (short circuit) between the conductive layer ME2 and the conductive layer ME3.

The conductive layer ME3 is positioned above the insulating layer DI1. Specifically, above the insulating layer DI1, the conductive layer ME3 includes a region overlapping with the conductive layer ME2. In addition, the conductor ME3 is embedded in the opening KK1 in the structure example illustrated in FIG. 1B and FIG. 1D.

In particular, an end portion of the conductive layer ME3 is preferably inside the region overlapping with the conductive layer ME2 above the insulating layer DI1. The end portion of the conductive layer ME3 inside the region overlapping with the conductive layer ME2 leads to, for example, a smaller region where the conductive layer ME3 and the conductive layer ME1 overlap with each other, which can lessen the effect of parasitic capacitance formed between the conductive layer ME3 and the conductive layer ME1. Similarly, a region where the conductive layer ME3 and the conductive layer ME5 overlap with each other becomes smaller, which can lessen the effect of parasitic capacitance formed between the conductive layer ME3 and the conductive layer ME5.

By contrast, when the end portion of the conductive layer ME3 is positioned outside the region overlapping with the conductive layer ME2 above the insulating layer DI1, the conductive layer ME3 covers the end portion of the conductive layer ME2 with the insulating layer DI1 therebetween, which leads to an increased capacitance value of the capacitor C1. In this case, the conductive layer ME3 includes a region in contact with the top surface of the insulating layer IS2. That is, the conductive layer ME3 covers an end portion of the insulating layer DI1.

An insulating layer IS3 and the conductive layer ME4 are stacked in this order above the insulating layer IS2, the insulating layer DI1, and the conductive layer ME3. The insulating layer IS3 has a function of an interlayer film that separates the conductive layer ME3 and the conductive layer ME4, for example. Providing the insulating layer IS3 can prevent direct contact (short circuit) between the conductive layer ME3 and the conductive layer ME4. Furthermore, the insulating layer IS3 and the conductive layer ME4 include an opening KK2 in a region that overlaps with the conductive layer ME3 and does not overlap with the opening KK1, for example.

The conductive layer ME4 has a function of a wiring for supplying an electrical signal (e.g., a potential or a current) to the other of the source and the drain of the transistor MI, for example. Thus, the conductive layer ME4 extends along the ±Y direction in FIG. 1A to FIG. 1D as an example.

The semiconductor layer SC1 includes regions in contact with side surfaces of the insulating layer IS3 and the conductive layer ME4 corresponding to a side surface of the opening KK2, a top surface of the conductive layer ME3 corresponding to a bottom portion of the opening KK2, and a top surface of the conductive layer ME4.

The semiconductor layer SC1 can cover an end portion of the conductor ME4 in the structure of the memory cell MC illustrated in FIG. 1B. That is, the semiconductor layer SC1 may include regions in contact with the top surface of the conductive layer ME4 and the top surface of the insulating layer IS3. Covering the end portion of the conductive layer ME4 with the semiconductor layer SC1 extends the distance between the conductive layer ME4 and the conductive layer ME5, which can lessen the effect of parasitic capacitance formed between the conductive layer ME4 and the conductive layer ME5. Furthermore, covering the end portion of the conductive layer ME4 with the semiconductor layer SC1 increases the contact area between the conductor ME4 and the semiconductor layer SC1, which can reduce the contact resistance between the conductor ME4 and the semiconductor layer SC1.

The insulating layer GI1 includes regions in contact with the top surface of the semiconductor layer SC1, the top surface of the conductive layer ME4, and the top surface of the insulating layer IS3. In particular, the insulating layer GI1 preferably covers end portions of the conductive layer ME4 and the semiconductor layer SC1. Covering the end portions of the conductive layer ME4 and the semiconductor layer SC1 with the insulating layer GI1 can prevent direct contact (short circuit) between the conductive layer ME5, the conductive layer ME4, and the semiconductor layer SC1.

The conductive layer ME5 is positioned above the insulating layer GI1. Specifically, above the insulating layer DI1, the conductive layer ME5 includes a region overlapping with the semiconductor layer SC1. In addition, the conductive layer ME5 is embedded in the opening KK2 in the structure example illustrated in FIG. 1B and FIG. 1C.

The conductive layer ME5 has a function of a wiring for supplying an electrical signal (e.g., a potential or a current) to a gate of the transistor M1, for example. Thus, the conductive layer ME5 extends along the +X direction in FIG. 1A to FIG. 1D as an example.

The insulating layer IS4 is positioned above the insulating layer GI1 and the conductive layer ME5. The insulating layer IS4 has a function of an interlayer film that separates the memory cell MC and a circuit or the like formed above the memory cell MC, for example.

In the memory cell MC in FIG. 1A to FIG. 1D, the insulating layer IS1 to the insulating layer IS4, the insulating layer DI1, the insulating layer GI1, the semiconductor layer SC1, and the conductive layer ME1 to the conductive layer ME5 can each have a single-layer structure, for example. Employing a single-layer structure allows a simpler process and reduced manufacturing cost. In the memory cell MC of one embodiment of the present invention, one or more selected from the insulating layer IS1 to the insulating layer IS4, the insulating layer DI1, the insulating layer GI1, the semiconductor layer SC1, and the conductive layer ME1 to the conductive layer ME5 can have a stacked-layer structure, while the rest can have a single-layer structure. The case where the insulating layer IS1 to the insulating layer IS4, the insulating layer DI1, the insulating layer GI1, the semiconductor layer SC1, and the conductive layer ME1 to the conductive layer ME5 each have a stacked-layer structure is described later.

Next, the first capacitor region positioned in the opening KK1 and the second capacitor region positioned in a region overlapping with the top surface of the insulating layer IS2, which are included in the capacitor C1, are described.

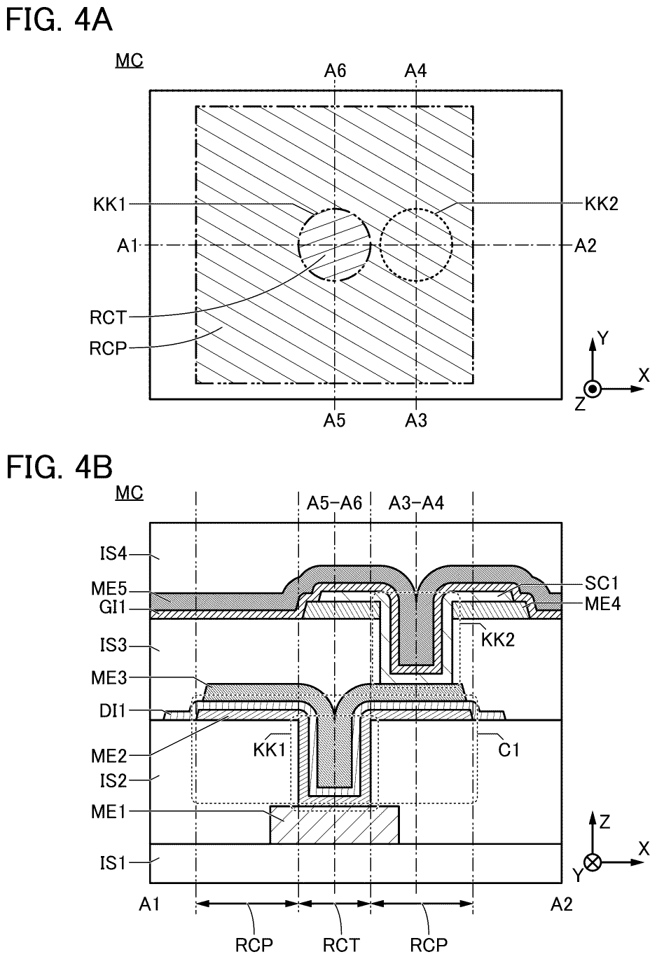

FIG. 4A is a schematic plan view corresponding to FIG. 1A and illustrates the first capacitor region, the second capacitor region, and the opening KK2 in the memory cell MC, and FIG. 4B is a schematic cross-sectional view corresponding to FIG. 4B and illustrates the structure of the memory cell MC, the first capacitor region, the second capacitor region, and the opening KK2.

In FIG. 4A and FIG. 4B, a capacitor region RCT as the first capacitor region and a capacitor region RCP as the second capacitor region are indicated by dashed double-dotted lines.

In FIG. 4A and FIG. 4B, the capacitor region RCT is formed in the opening KK1. The capacitor region RCP is formed in a region of the top surface of the insulating layer IS2 where the conductive layer ME2 is positioned. In particular, the capacitor region RCT and the capacitor region RCP each have a stacked-layer structure of the conductive layer ME2, the insulating layer DI1, and the conductive layer ME3, as described above.

As illustrated in FIG. 4A and FIG. 4B, the opening KK2 of the insulating layer IS3 overlaps with the conductive layer ME3 included in the capacitor region RCP. In other words, the semiconductor layer SC1 includes a region in contact with the top surface of the conductive layer ME3 included in the capacitor region RCP.

On the other hand, in the case where the opening KK2 of the insulating layer IS3 is formed to overlap with the conductive layer ME3 included in the capacitor region RCT, the semiconductor layer SC1 includes a region in contact with the top surface of the conductive layer ME3 included in the capacitor region RCT. Specifically, since the conductive layer ME3 included in the capacitor region RCT is embedded in the opening KK1, the conductive layer ME3 included in the capacitor region RCT has a concave shape in some cases. In forming the semiconductor layer SC1, the insulating layer GI1, and the conductive layer ME5 above the concave shape, formation defects in the stacked-layer structure are more likely to occur than with a uniform film having almost no unevenness (e.g., the conductive layer ME3 included in the capacitor region RCP). For example, the semiconductor layer SC1 formed over the conductive layer ME3 included in the capacitor region RCT may fail to be uniform, which may allow contact between the insulating layer GI1 to be formed later and the conductive layer ME3. The semiconductor layer SC1 and the insulating layer GI1 formed over the conductive layer ME3 may also fail to be uniform, which may allow contact between the conductive layer ME3 and the conductive layer ME5.

As described above, the formation of the opening KK2 of the insulating layer IS3 in the region overlapping with the conductive layer ME3 included in the capacitor region RCP enables the semiconductor layer SC1, the insulating layer GI1, and the conductive layer ME5 to be formed on the top surface of the conductive layer ME3 that is uniform with almost no unevenness, which can reduce the formation defects in the stacked-layer structure. That is, the yield of the memory cell MC can be increased by the formation of the opening KK2 of the insulating layer IS3 in the region overlapping with the conductive layer ME3 included in the capacitor region RCP.

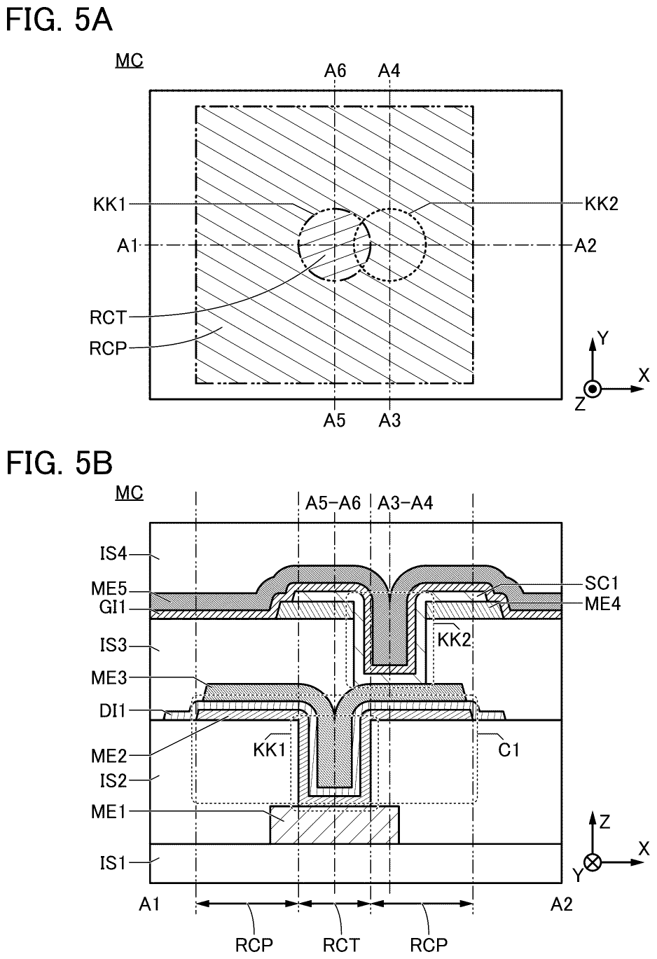

Part of the opening KK2 can include a region overlapping with the capacitor region RCT as long as, in the opening KK2, the formation defects do not occur in the stacked-layer structure of the semiconductor layer SC1, the insulating layer GI1, and the conductive layer ME5. FIG. 5A and FIG. 5B illustrate an example in which the opening KK2 of the insulating layer IS3 overlaps with the conductive layer ME3 included in the capacitor region RCT in addition to the conductive layer ME3 included in the capacitor region RCP. Owing to the overlap between part of the opening KK2 and the capacitor region RCT, the circuit area of the memory cell MC in FIG. 5A and FIG. 5B can be much smaller than the circuit area of the memory cell MC in FIG. 1A to FIG. 1D (FIG. 4A and FIG. 4B).

To summarize the above, the memory cell MC preferably has a structure in which the opening KK2 of the insulating layer IS3 overlaps with at least part of the conductive layer ME3 included in the capacitor region RCP.

### Structure Example 2

Next, a structure example of a memory cell that is the semiconductor device of one embodiment of the present invention and has a structure different from that in FIG. 1A to FIG. 1D is described.

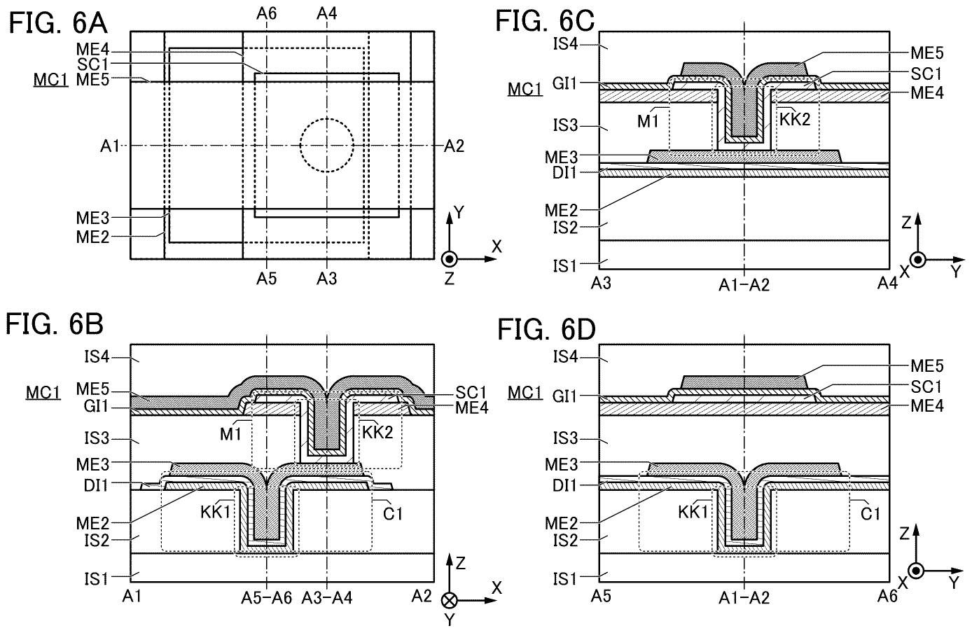

A memory cell MC1 illustrated in FIG. 6A to FIG. 6D is a modification example of the memory cell MC in FIG. 1A to FIG. 1D and is different from the memory cell MC in FIG. 1A to FIG. 1D in that the conductive layer ME1 is not provided and the conductive layer ME2 extends in the ±Y direction.

In the memory cell MC1 illustrated in FIG. 6A to FIG. 6D, the insulating layer IS2 is positioned above the insulating layer IS1. The insulating layer IS2 includes the opening KK1 reaching the insulating layer IS1. The conductive layer ME2 includes regions in contact with the side surface of the insulating layer IS2 corresponding to the side surface of the opening KK1, the top surface of the insulating layer IS1 corresponding to the bottom portion of the opening KK1, and the top surface of the insulating layer IS2.

In this case, the conductive layer ME2 has a function of a wiring for supplying an electrical signal (e.g., a potential or a current) to the other of the pair of electrodes of the capacitor C1, in addition to the function of the other of the pair of electrodes of the capacitor C1, for example. Thus, the conductive layer ME2 extends along the ±Y direction in FIG. 6A to FIG. 6D as an example.

Unlike in the memory cell MC in FIG. 1A to FIG. 1D, there is no conductive layer ME1 over the top surface of the insulating layer IS1 in the memory cell MC1 illustrated in FIG. 6A to FIG. 6D; accordingly, the number of manufacturing steps of the memory cell MC1 illustrated in FIG. 6A to FIG. 6D can be smaller than the number of manufacturing steps of the memory cell MC in FIG. 1A to FIG. 1D. Since the number of manufacturing steps of the memory cell MC1 in FIG. 6A to FIG. 6D is reduced, possible defects during the manufacturing process can be reduced, resulting in a higher yield of the memory cell MC1. Furthermore, due to the reduced number of manufacturing steps of the memory cell MC1 in FIG. 6A to FIG. 6D, the cost of manufacturing the semiconductor device can be reduced.

### Structure Example 3

Next, a structure example of a memory cell that is the semiconductor device of one embodiment of the present invention and differs in structure from those in FIG. 1A to FIG. 1D and FIG. 6A to FIG. 6D is described.

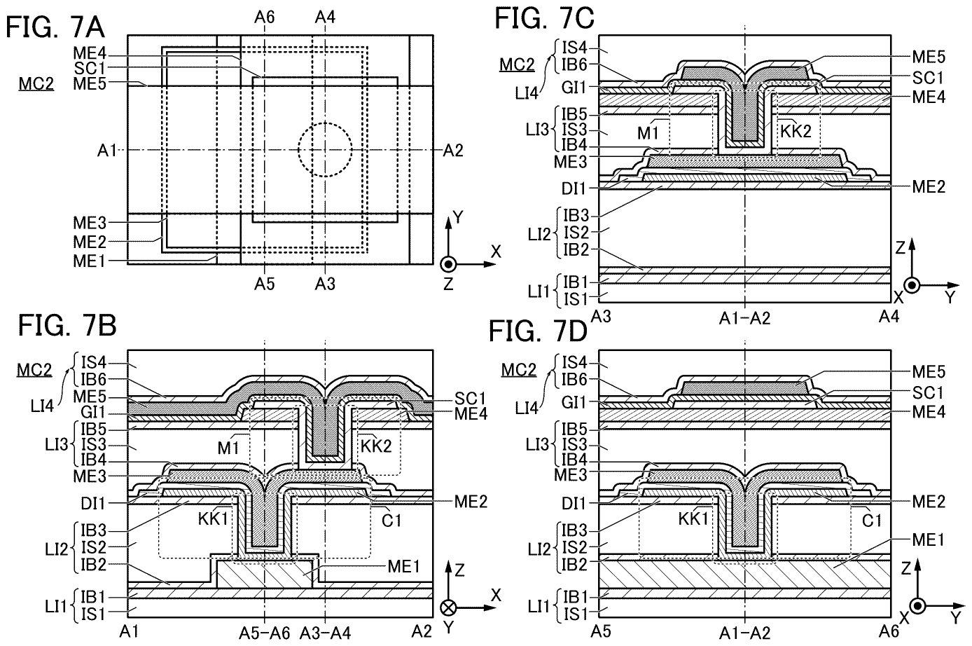

A memory cell MC2 illustrated in FIG. 7A to FIG. 7D is different from the memory cell MC in FIG. 1A to FIG. 1D and the memory cell MC1 in FIG. 6A to FIG. 6D in including an insulating layer IB1 to an insulating layer IB6.

In the memory cell MC2 illustrated in FIG. 7A to FIG. 7D, the insulating layer IB1 is positioned above the insulating layer IS1. The conductive layer ME1 is positioned above the insulating layer IB1, and the insulating layer IB2, the insulating layer IS2, and the insulating layer IB3 are stacked in this order above the conductive layer ME1 and the insulating layer IB1.

The insulating layer IB1 has a function of a barrier insulating film that separates the insulating layer IS1 and the conductive layer ME1, for example. Specifically, the insulating layer IB1 has a function of a barrier insulating film that inhibits diffusion of impurities from the insulating layer IS1 into the conductive layer ME1. Examples of the impurities here include oxygen, which reduces the conductivity of the conductive layer ME1 through oxidation.

Like the insulating layer IB1, the insulating layer IB2 has a function of a barrier insulating film that separates the insulating layer IS2 and the conductive layer ME1, for example. Specifically, the insulating layer IB2 has a function of a barrier insulating film that inhibits diffusion of impurities from the insulating layer IS2 into the conductive layer ME1. Examples of the impurities here include oxygen, like those for the insulating layer IB1.

The insulating layer IB1 and the insulating layer IB2 are formed to surround the conductive layer ME1, whereby the conductivity ME1 can be prevented from being oxidized and the conductivity ME1 can be inhibited from having lower conductivity.

Like the insulating layer IB1 and the insulating layer IB2, the insulating layer IB3 has a function of a barrier insulating film that separates the insulating layer IS2 and the conductive layer ME2, for example. Specifically, the insulating layer IB3 has a function of a barrier insulating film that inhibits diffusion of impurities from the insulating layer IS2 into the conductive layer ME2. Examples of the impurities here include oxygen, like those for the insulating layer IB1.

With the insulating layer IB3 provided between the insulating layer IS2 and the conductive layer ME2, oxidation of the conductive layer ME2 can be prevented in a region where the conductive layer ME2 and the insulating layer IB3 are in contact with each other or in the vicinity of the region, so that the conductive layer ME2 in these regions can be inhibited from having lower conductivity.

The insulating layer IB3 can have a function of a barrier insulating film that prevents transmission of impurities that diffuse into the semiconductor layer SC1 and increase the carrier concentration. In the case where the semiconductor layer SC1 contains an oxide semiconductor, examples of the impurities include a hydrogen atom, a hydrogen molecule, a water molecule, a nitrogen atom, a nitrogen molecule, a nitrogen oxide molecule (e.g., N₂O, NO, or NO₂), and a copper atom. Diffusion of the impurities into the semiconductor layer SC1 reduces the reliability of the transistor M1; thus, a material functioning as a barrier insulating film that prevents the diffusion of the impurities is preferably used for the insulating layer IB3.

In the memory cell MC2, the insulating layer IB2, the insulating layer IS2, and the insulating layer IB3 include the opening KK1 reaching the conductive layer ME1. The conductive layer ME2 includes regions in contact with side surfaces of the insulating layer IB2, the insulating layer IS2, and the insulating layer IB3 which correspond to the side surface of the opening KK1, the top surface of the conductive layer ME1 which corresponds to the bottom portion of the opening KK1, and the top surface of the insulating layer IB3.

In the memory cell MC2, the insulating layer IB4, the insulating layer IS3, and the insulating layer IB5 are stacked in this order above the insulating layer IS2, the conductive layer ME2, the insulating layer DI1, and the conductive layer ME3.

The insulating layer IB4 has a function of a barrier insulating film that separates the insulating layer IS3 and the conductive layer ME3, for example. Specifically, the insulating layer IB4 has a function of a barrier insulating film that inhibits diffusion of impurities from the insulating layer IS3 into the conductive layer ME3. Examples of the impurities here include oxygen, which reduces the conductivity of the conductive layer ME3 through oxidation.

Providing the insulating layer IB4 between the insulating layer IS3 and the conductive layer ME3 can inhibit diffusion of oxygen from the insulating layer IS3 into the conductive layer ME3 and prevent oxidation of the conductive layer ME3. This can inhibit a decrease in the conductivity of the conductive layer ME3.

Like the insulating layer IB3, the insulating layer IB4 can have a function of a barrier insulating film that prevents transmission of impurities that diffuse into the semiconductor layer SC1 and increase the carrier concentration.

The insulating layer IB5 has a function of a barrier insulating film that separates the insulating layer IS3 and the conductive layer ME4, for example. Specifically, the insulating layer IB5 has a function of a barrier insulating film that inhibits diffusion of impurities from the insulating layer IS3 into the conductive layer ME4. Examples of the impurities here include oxygen, which reduces the conductivity of the conductive layer ME4 through oxidation.

Providing the insulating layer IB5 between the insulating layer IS3 and the conductive layer ME4 can inhibit diffusion of oxygen from the insulating layer IS3 into the conductive layer ME4 and prevent oxidation of the conductive layer ME4. This can inhibit a decrease in the conductivity of the conductive layer ME4.

Like the insulating layer IB3, the insulating layer IB5 can have a function of a barrier insulating film that prevents transmission of impurities that diffuse into the semiconductor layer SC1 and increase the carrier concentration.

In the memory cell MC2, the insulating layer IB6 is positioned above the insulating layer GI1 and the conductive layer ME5.

The insulating layer IB6 has a function of a barrier insulating film that separates the insulating layer IS4 and the conductive layer ME5, for example. Specifically, the insulating layer IB6 has a function of a barrier insulating film that inhibits diffusion of impurities from the insulating layer IS4 into the conductive layer ME5. Examples of the impurities here include oxygen, which reduces the conductivity of the conductive layer ME5 through oxidation.

Providing the insulating layer IB6 between the insulating layer IS4 and the conductive layer ME5 can inhibit diffusion of oxygen from the insulating layer IS4 into the conductive layer ME5 and prevent oxidation of the conductive layer ME5. This can inhibit a decrease in the conductivity of the conductive layer ME5.

In FIG. 7B to FIG. 7D, the insulating layer IS1 and the insulating layer IB1 are collectively referred to as an insulating layer LI1, the insulating layer IB2, the insulating layer IS2, and the insulating layer IB3 are collectively referred to as an insulating layer LI2, the insulating layer IB4, the insulating layer IS3, and the insulating layer IB5 are collectively referred to as an insulating layer LI3, and the insulating layer IB6 and the insulating layer IS4 are collectively referred to as an insulating layer LI4.

Thus, it can be said that the memory cell MC2 in FIG. 7A to FIG. 7D has a structure in which the insulating layer IS1, the insulating layer IS2, the insulating layer IS3, and the insulating layer IS4 in the memory cell MC in FIG. 1A to FIG. 1D are respectively replaced with the insulating layer LI1, the insulating layer LI2, the insulating layer LI3, and the insulating layer LI4.

The number of insulating layers included in each of the insulating layer LI1 to the insulating layer LI4 can be two, three, or four or more. For example, although the insulating layer LI1 has two layers in the memory cell MC2 in FIG. 7A to FIG. 7D, the insulating layer LI1 can have three or more layers. Although the insulating layer LI2 has three layers in the memory cell MC2 in FIG. 7A to FIG. 7D, for example, the insulating layer LI2 can have two layers or three or more layers.

The above indicates that the insulating layer IS1 to the insulating layer IS4 in the memory cell MC in FIG. 1A to FIG. 1D can each have not a single-layer structure but a stacked-layer structure including a plurality of insulating layers. As described above, when the insulating layer IS1 to the insulating layer IS4 each have a stacked-layer structure including a barrier insulating film, oxidation of the conductive layer included in the memory cell MC can be prevented and a reduction in the conductivity of the conductive layer can be inhibited. Furthermore, diffusion of impurities into the semiconductor layer of the transistor M1 can be prevented, leading to higher reliability of the transistor M1.

### Structure Example 4

Next, a structure example of a memory cell that is the semiconductor device of one embodiment of the present invention a and differs in structure from those in FIG. 1A to FIG. 1D, FIG. 6A to FIG. 6D, and FIG. 7A to FIG. 7D is described.

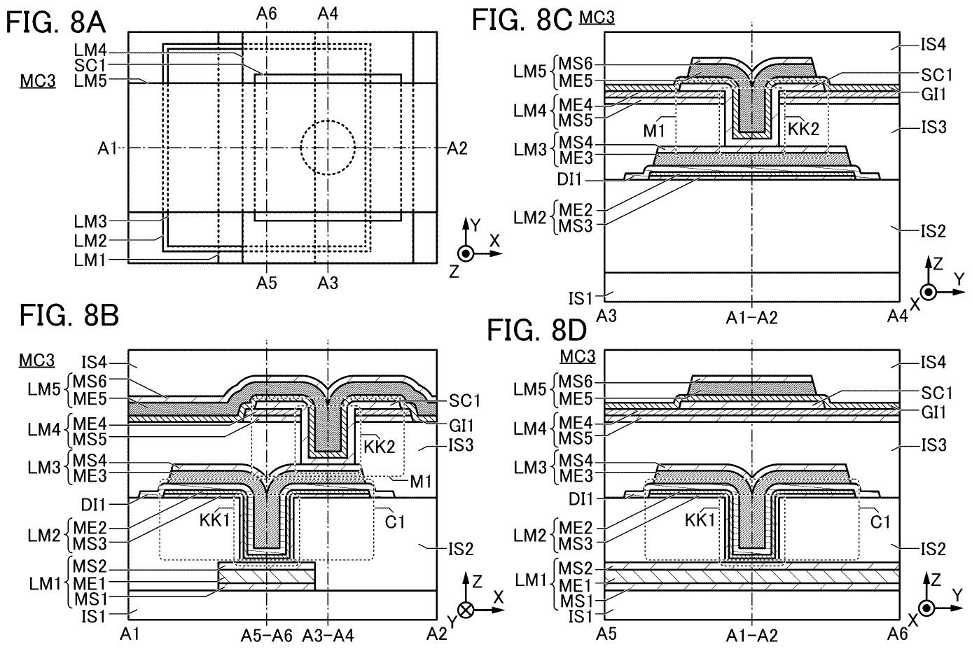

A memory cell MC3 illustrated in FIG. 8A to FIG. 8D is different from the memory cell MC in FIG. 1A to FIG. 1D, the memory cell MC1 in FIG. 6A to FIG. 6D, and the memory cell MC2 in FIG. 7A to FIG. 7D in including a conductive layer MS1 to a conductive layer MS6.

In the memory cell MC3 illustrated in FIG. 8A to FIG. 8D, the conductive layer MS1, the conductive layer ME1, and the conductive layer MS2 are stacked in this order above the insulating layer IS1.

The conductive layer MS1 and the conductive layer MS2 have a function of an auxiliary electrode for the conductive layer ME1, for example. Specifically, the conductive layer MS1 and the conductive layer MS2 each include a conductive material that is less likely to be oxidized or a conductive material that maintains the conductivity even after absorbing oxygen.

When the conductive layer MS1 is provided between the insulating layer IS1 and the conductive layer ME1, the conductivity of the conductive layer MS1 can be maintained even through diffusion of oxygen as an impurity from the insulating layer IS1 into the conductive layer MS1. Furthermore, the conductive layer MS1 can inhibit the diffusion of oxygen from the insulating layer IS1 into the conductive layer ME1 in the case where the conductive layer MS1 also has a function of a barrier conductive film against oxygen.

Similarly, when the conductive layer MS2 is provided between the conductive layer ME1 and the insulating layer IS2, the conductivity of the conductive layer MS2 can be maintained even through diffusion of oxygen as an impurity from the insulating layer IS2 into the conductive layer MS2. Furthermore, he conductive layer MS2 can inhibit the diffusion of oxygen from the insulating layer IS2 into the conductive layer ME1 in the case where the conductive layer MS2 also has a function of a barrier conductive film against oxygen.

Alternatively, in the case where the conductive layer MS1 and the conductive layer MS2 each have a function of a barrier conductive film against oxygen, the diffusion of oxygen from the insulating layer IS1 and the insulating layer IS2 into the conductive layer ME1 can be inhibited, which allows the use of a low-resistance conductive material that is easily oxidized for the conductive layer ME1.

Although an end portion of the conductor ME1 is in contact with the insulator IS2 in the memory cell MC3 in FIG. 8B, the end portion of the conductor ME1 can be covered with one or both of the conductive layer MS1 and the conductive layer MS2 in the memory cell MC3.

In the memory cell MC3, the insulating layer IS2 includes the opening KK1 reaching the conductive layer MS2.

The conductive layer MS3 includes regions in contact with the side surface of the insulating layer IS2 corresponding to the side surface of the opening KK1, the top surface of the conductive layer MS2 corresponding to the bottom portion of the opening KK1, and the top surface of the insulating layer IS2. The conductive layer ME2 is positioned on a top surface of the conductive layer MS3. In other words, the conductive layer ME2 includes a region in contact with the top surface of the conductive layer MS3.

When the conductive layer MS3 is provided between the insulating layer IS2 and the conductive layer ME2, the conductivity of the conductive layer MS3 can be maintained even through diffusion of oxygen as an impurity from the insulating layer IS2 into the conductive layer MS3. Furthermore, the conductive layer MS3 can inhibit the diffusion of oxygen from the insulating layer IS2 into the conductive layer ME3 in the case where the conductive layer MS3 also has a function of a barrier conductive film against oxygen. In that case, a low-resistance conductive material that is easily oxidized can be used for the conductive layer ME3.

The conductive layer MS3 is preferably formed using a material that allows the conductive layer MS3 to adequately cover the side surface and bottom portion of the opening KK1. For the conductive layer ME2, a material having good film-forming properties with respect to the top surface of the conductive layer MS3 is preferably used. For example, in the case where the conductive layer ME2 has poor film-forming properties with respect to the side surface and bottom portion of the opening KK1, it is preferable that the conductive layer MS3 be formed once on the side surface and bottom portion of the opening KK1 and the conductive layer ME2 be formed on the top surface of the conductive layer MS3. That is, providing the conductive layer MS2 between the insulating layer IS2 and the conductive layer ME2 facilitates the formation of the conductive layer ME2 in the opening KK1.

In the memory cell MC3, the conductive layer MS4 is positioned on the top surface of the conductive layer ME3. In other words, the conductive layer MS4 includes a region in contact with the top surface of the conductive layer ME3.

When the conductive layer MS4 is provided between the insulating layer IS3 and the conductive layer ME3, the conductivity of the conductive layer MS4 can be maintained even through diffusion of oxygen as an impurity from the insulating layer IS3 into the conductive layer ME3. Furthermore, the conductive layer MS4 can inhibit the diffusion of oxygen from the insulating layer IS4 into the conductive layer ME3 in the case where the conductive layer MS4 also has a function of a barrier conductive film against oxygen. In that case, a low-resistance conductive material that is easily oxidized can be used for the conductive layer ME3.

Although an end portion of the conductor ME3 is in contact with the insulator IS3 in the memory cell MC3 in FIG. 8B, the end portion of the conductor ME3 can be covered with the conductive layer MS4 in the memory cell MC3.

In the memory cell MC3, the conductive layer MS5 includes a region in contact with the top surface of the insulating layer IS3. The conductive layer ME4 is positioned on a top surface of the conductive layer MS5. In other words, the conductive layer ME4 includes a region in contact with the top surface of the conductive layer MS5.

In the memory cell MC3, the insulating layer IS3, the conductive layer MS5, and the conductive layer ME4 include the opening KK2 reaching the conductive layer ME4.

The semiconductor layer SC1 includes regions in contact with side surfaces of the insulating layer IS3, the conductive layer MS5, and the conductive layer ME4 corresponding to a side surface of the opening KK2, a top surface of the conductive layer MS4 corresponding to a bottom portion of the opening KK2, and a top surface of the conductive layer ME5.

The effect of providing the conductive layer MS4 between the insulating layer IS3 and the conductive layer ME3 can be referred to for the effect of providing the conductive layer MS5 between the insulating layer IS3 and the conductive layer ME4.

In the memory cell MC3, the conductive layer MS6 is positioned on the top surface of the conductive layer ME5. In other words, the conductive layer MS6 includes a region in contact with the top surface of the conductive layer ME5.

When the conductive layer MS6 is provided between the insulating layer IS4 and the conductive layer ME5, the conductivity of the conductive layer MS6 can be maintained even through diffusion of oxygen as an impurity from the insulating layer IS4 into the conductive layer ME5. Furthermore, the conductive layer MS6 can inhibit the diffusion of oxygen from the insulating layer IS4 into the conductive layer ME5 in the case where the conductive layer MS6 also has a function of a barrier conductive film against oxygen. In that case, a low-resistance conductive material that is easily oxidized can be used for the conductive layer ME5.

Although an end portion of the conductor ME5 is in contact with the insulator IS4 in the memory cell MC3 in FIG. 8C and FIG. 8D, the end portion of the conductor ME5 can be covered with the conductive layer MS6 in the memory cell MC3.

In FIG. 8B to FIG. 8D, the conductive layer MS1, the conductive layer ME1, and the conductive layer MS2 are collectively referred to as a conductive layer LM1, the conductive layer MS3 and the conductive layer ME2 are collectively referred to as an insulating layer LM2, the conductive layer ME3 and the conductive layer MS4 are collectively referred to as a conductive layer LM3, the conductive layer MS5 and the conductive layer ME4 are collectively referred to as a conductive layer LM4, and the conductive layer ME5 and the conductive layer MS6 are collectively referred to as a conductive layer LM5.

Thus, it can be said that the memory cell MC3 in FIG. 8A to FIG. 8D has a structure in which the conductive layer ME1, the conductive layer ME2, the conductive layer ME3, the conductive layer ME4, and the conductive layer ME5 in the memory cell MC in FIG. 1A to FIG. 1D are respectively replaced with the conductive layer LM1, the conductive layer LM2, the conductive layer LM3, the conductive layer LM4, and the conductive layer LM5.

The number of insulating layers included in each of the conductive layer LM1 to the conductive layer LM5 can be two, three, or four or more. Although the conductive layer LM1 has three layers in the memory cell MC3 in FIG. 8A to FIG. 8D, for example, the conductive layer LM1 can have two layers or four or more layers. For example, although the conductive layer LM2 has two layers in the memory cell MC3 in FIG. 8A to FIG. 8D, the conductive layer LM2 can have three or more layers.

The above indicates that the conductive layer ME1 to the conductive layer ME5 in the memory cell MC in FIG. 1A to FIG. 1D can each have not a single-layer structure but a stacked-layer structure including a plurality of conductive layers.

Materials that allow low contact resistance between the plurality of conductive layers included in each of the conductive layer LM1 to the conductive layer LM5 are preferably used. For example, materials are preferably used in the conductive layer LM1 so that the conductive layer MS1 and the conductive layer MS2 exhibit low contact resistance with the conductive layer ME1. With the low contact resistance between the plurality of conductive layers included in each of the conductive layer LM1 to the conductive layer LM5, each of the conductive layer LM1 to the conductive layer LM5 can have high conductivity, which can reduce power consumption required for transmitting a signal (e.g., a potential or a current).

Moreover, materials that allow low contact resistance between the conductive layer MS2 and the conductive layer MS3 are preferably used in the conductive layer MS2 and the conductive layer MS3. Thus, in the case where the conductive layer LM1 and the conductive layer LM2 are in contact with each other, materials that allow low contact resistance between the two conductive layers that are in contact with each other and are included in the conductive layer LM1 and the conductive layer LM2 are preferably used in the two conductive layers.

The plurality of conductive layers included in each of the conductive layer LM1 to the conductive layer LM5 can be replaced with each other depending on circumstances. For example, although the conductive layer MS3 is positioned below the conductive layer ME2 in the memory cell MC3 in FIG. 8A to FIG. 8D, the conductive layer MS3 can be positioned above the conductive layer ME2. Although the conductive layer ME3 is positioned below the conductive layer MS4 in the memory cell MC3, for example, the conductive layer ME3 can be positioned above the conductive layer MS4.

Note that this embodiment can be combined with the same embodiment or any of the other embodiments in this specification as appropriate. For example, the configurations, structures, methods, and the like described in this embodiment can be used in an appropriate combination with any of the other configurations, the other structures, the other methods, and the like described in the same embodiment. For another example, the configurations, structures, methods, and the like described in this embodiment can be used in an appropriate combination with any of the configurations, structures, methods, and the like described in the other embodiments and the like.

### Embodiment 2

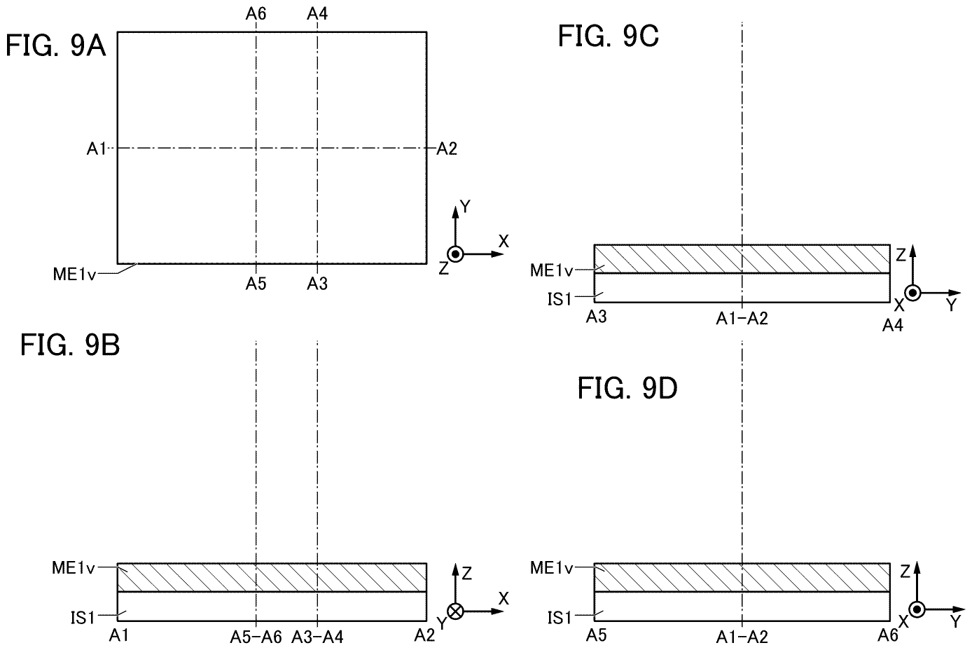

In this embodiment, an example of a method for manufacturing the memory cell MC described in the above embodiment is described. Referring to FIG. 9A to FIG. 22D, the example of the manufacturing method is described.

### Manufacturing Method Example 1

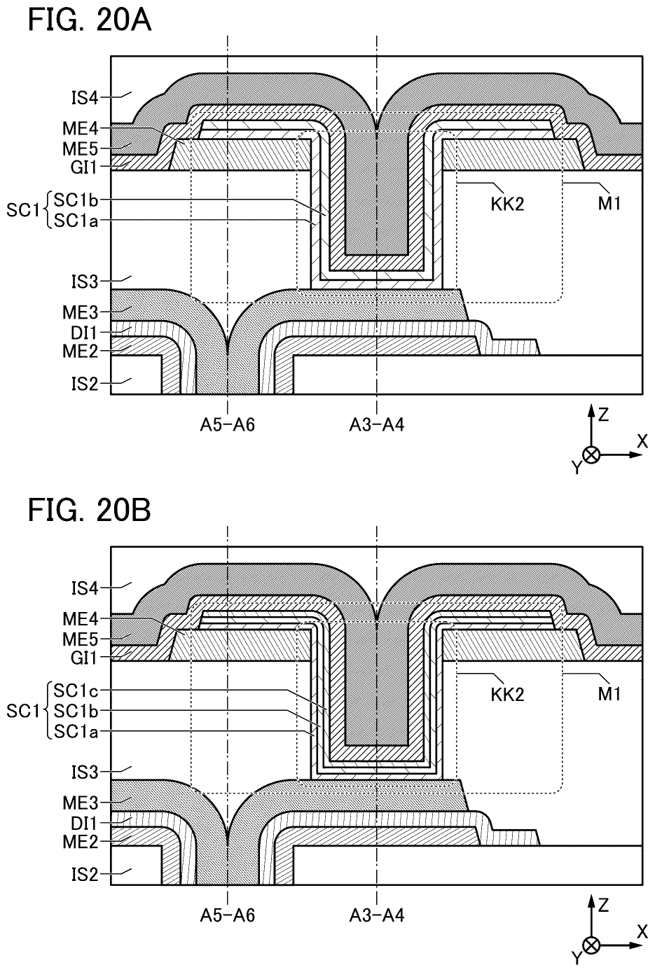

In FIG. 9A to FIG. 19D and FIG. 21A to FIG. 22D, A illustrates a schematic plan view. Moreover, B illustrates a schematic cross-sectional view corresponding to a portion along the dashed-dotted line A1-A2 illustrated in A of the corresponding drawing, and also a schematic cross-sectional view in the ±X direction. Furthermore, C illustrates a schematic cross-sectional view corresponding to a portion along the dashed-dotted line A3-A4 illustrated in A of the corresponding drawing, and also a schematic cross-sectional view in the ±Y direction. Furthermore, D illustrates a schematic cross-sectional view corresponding to a portion along the dashed-dotted line A5-A6 illustrated in A of the corresponding drawing, and also a schematic cross-sectional view in the Y direction. Note that for clarity of the drawing, some components are not illustrated in the schematic plan view of A of each drawing. FIG. 20A and FIG. 20B are each a schematic plan view in which the transistor M1 in FIG. 1B is enlarged.

Hereinafter, a film of an insulating material for forming an insulating layer, a film of a conductive material for forming a conductive layer, or a film of a semiconductor material for forming a semiconductor can be formed by a film formation method such as a sputtering method, a CVD (Chemical Vapor Deposition) method, an MBE (Molecular Beam Epitaxy) method, a PLD (Pulsed Laser Depositon) method, or an ALD (Atomic Layer Deposition) method as appropriate.

First, a substrate (not illustrated) is prepared, and the insulating layer IS1 and a conductive film ME1v are formed in this order over the substrate (see FIG. 9A to FIG. 9D).

As the substrate, a semiconductor substrate (e.g., a single crystal substrate containing silicon or germanium as a material) can be used, for example. Besides the single crystal substrate, for example, an SOI (Silicon On Insulator) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, or paper or a base material film containing a fibrous material can be used as the substrate. Examples of the glass substrate include barium borosilicate glass, aluminoborosilicate glass, and soda lime glass. Examples of materials for the flexible substrate, the attachment film, or the base film include plastic typified by polyethylene terephthalate (PET), polyethylene naphthalate (PEN), polyethersulfone (PES), and polytetrafluoroethylene (PTFE). Another example is a synthetic resin such as an acrylic resin. Other examples are polypropylene, polyester, polyvinyl fluoride, and polyvinyl chloride. Other examples include polyamide, polyimide, aramid, an epoxy resin, an inorganic vapor deposition film, and paper. Note that in the case where this manufacturing method involves heat treatment, a highly heat-resistant substrate is preferably selected as the substrate. Alternatively, any of these substrates provided with a circuit element can be used. Examples of the circuit element include a capacitor, a resistor, a switching element, a light-emitting element, and a storage element.

The insulating layer IS1 has a function of, for example, a base film above which the capacitor C1 and the transistor M1 are to be formed. In the case where a circuit or the like is positioned below the insulating layer IS1, the insulating layer IS1 has a function of an interlayer film that separates the circuit or the like from the memory cell MC above the insulating layer IS1.

For the insulating layer IS1, silicon oxide, silicon oxynitride, silicon nitride oxide, or silicon nitride can be used, for example. Alternatively, for the insulating layer IS1, silicon oxide to which fluorine is added, silicon oxide to which carbon is added, silicon oxide to which carbon and nitrogen are added, or porous silicon oxide can be used, for example. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed. Alternatively, for the insulating layer IS1, a resin can be used, for example. A material used for the insulating layer IS1 can be an appropriate combination of the above-described insulating materials. The insulating layer IS1 can have a single-layer structure or a stacked-layer structure in which two or more films of insulating materials are sequentially formed.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

An insulating material with a low relative permittivity is preferably used for the insulating layer IS1. When an insulating material with a low relative permittivity is used for an interlayer film, parasitic capacitance generated between wirings can be reduced. Specifically, the relative permittivity of the insulating layer IS1 is preferably lower than 4, further preferably lower than 3, for example. Examples of an insulating material with a low relative permittivity include silicon oxide, silicon oxynitride, and silicon nitride oxide.

As described above, the insulating layer IS1 can have a single-layer structure or a stacked-layer structure in which two or more layers of insulating materials are sequentially formed. In the case where the insulating layer IS1 includes two or more layers of insulating materials, at least one of the layers can be a barrier insulating film. Note that the barrier insulating film corresponds to the insulating layer IB1 illustrated in FIG. 7A to FIG. 7D.

For the barrier insulating film, for example, an insulating material having a function of inhibiting diffusion of oxygen (e.g., one or both of an oxygen atom and an oxygen molecule) (an insulating material through which the oxygen is less likely to pass) is preferably used in order to prevent oxidation of the conductive layer ME1 formed later. Alternatively, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), and a copper atom (an insulating material through which the impurities are less likely to pass) is preferably used in order to prevent diffusion of impurities from below the barrier insulating film into the transistor M1 above the barrier insulating film.

A barrier insulating film having a function of inhibiting the passage of oxygen and impurities such as water and hydrogen can be formed to have a single layer or a stacked layer including an insulator containing one or more selected from boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum, for example. Specific examples of the insulator having a function of inhibiting the passage of oxygen and impurities such as water and hydrogen include metal oxides such as aluminum oxide, magnesium oxide, gallium oxide, germanium oxide, yttrium oxide, zirconium oxide, lanthanum oxide, neodymium oxide, hafnium oxide, and tantalum oxide. Other examples of the insulator having a function of inhibiting the passage of oxygen and impurities such as water and hydrogen include oxides containing aluminum and hafnium (hafnium aluminate). Other examples of the insulator having a function of inhibiting the passage of oxygen and impurities such as water and hydrogen include metal nitrides such as aluminum nitride, aluminum titanium nitride, titanium nitride, silicon nitride oxide, and silicon nitride.

In particular, aluminum oxide or silicon nitride is preferably used for the barrier insulating film. Accordingly, it is possible to inhibit diffusion of impurities such as water and hydrogen into the transistor M1 from below the insulating layer IS1, for example.

The conductive film ME1v is a film to be the conductive layer ME1 in a later step. Part of the conductive layer ME1 f has a function of a wiring electrically connected to the other of the pair of electrodes of the capacitor C1. Thus, a material having high conductivity is preferably used for the conductive film ME1v.

For the conductive film Me1v, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing two or more selected from the above metal elements; or an alloy containing a combination of two or more selected from the above metal elements, for example. Alternatively, for the conductive film ME1v, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, or an oxide containing lanthanum and nickel, for example. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. As the conductor, a semiconductor having high electrical conductivity, typified by polycrystalline silicon containing an impurity element (e.g., phosphorus or arsenic), or silicide (e.g., nickel silicide) can be used, for example.

A stack of a plurality of conductive films formed of the above-described materials can be used. For example, a stacked-layer structure combining a material containing the above metal element and a conductive material containing oxygen can be employed. Alternatively, a stacked-layer structure combining a material containing the above metal element and a conductive material containing nitrogen can be employed. A stacked-layer structure combining a material containing the above metal element, a conductive material containing oxygen, and a conductive material containing nitrogen can be employed.

The conductive layer ME1 can include, for example, a first conductor and a second conductor surrounded by the first conductor. Note that the first conductor corresponds to the conductive layer ME1 illustrated in FIG. 8A to FIG. 8D, and the second conductor corresponds to the conductive layer MS1 and the conductive layer MS2 illustrated in FIG. 8A to FIG. 8D.

For the first conductor, any of titanium, titanium nitride, tantalum, tantalum nitride, ruthenium, and ruthenium oxide, which are conductive materials having a function of inhibiting diffusion of oxygen, can be used, and for the second conductor, a conductive material containing any of tungsten, copper, and aluminum, which have high conductivity, as its main component can be used. When the second conductor is surrounded by the first conductor, a reduction in the conductivity of the first conductor due to oxidation can be prevented.

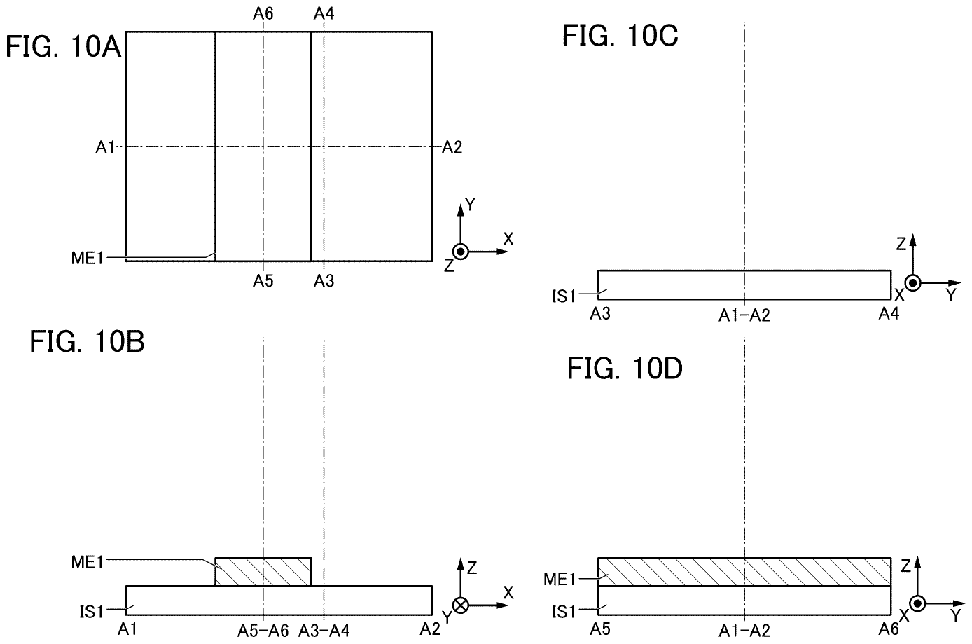

Next, the conductive film Me1v is processed into a band shape by a lithography method so that part of the insulating layer IS1 is exposed, whereby the conductive layer ME1 is formed (see FIG. 10A to FIG. 10D). The conductive layer Me1v is formed to extend in a direction parallel to the dashed-dotted line A5-A6 (±Y direction), in particular. For the processing, a dry etching method or a wet etching method can be employed.

In this specification and the like, examples of the lithography method includes a photolithography method, an ion beam lithography method, an X-ray lithography method, an electron lithography method, a multiphoton lithography method, an interference lithography method, and a nanoimprinting method.

In a lithography method, first, a resist is exposed to light through a mask. Next, a region exposed to light is removed or left using a developing solution, so that a resist mask is formed. Then, etching treatment through the resist mask is performed, whereby a conductor, a semiconductor, an insulator, or the like can be processed into a desired shape. The resist mask can be formed through, for example, exposure of the resist to KrF excimer laser light, ArF excimer laser light, EUV (Extreme Ultraviolet) light, or the like. A liquid immersion technique can also be employed in which a gap between a substrate and a projection lens is filled with a liquid (e.g., water) in light exposure. An electron beam or an ion beam can also be used instead of the light. Particularly in the case of using an electron beam or an ion beam, a mask is not necessary, which can reduce the manufacturing cost of a semiconductor device. Note that the resist mask can be removed by dry etching treatment such as ashing, wet etching treatment, wet etching treatment after dry etching treatment, or dry etching treatment after wet etching treatment.

In addition, a hard mask formed of an insulating film or a conductive film can be used under the resist mask. In the case of using a hard mask, a hard mask with a desired shape can be formed in the following manner: an insulating film or a conductive film that is the hard mask material is formed over the conductive film Me1v, a resist mask is formed thereover, and then the hard mask material is etched. The etching of the conductive film Me1v and the like may be performed after removing the resist mask or with the resist mask remaining. In the latter case, the resist mask sometimes disappears during the etching. The hard mask may be removed by etching after the etching of the conductive film Me1v and the like. Meanwhile, the hard mask is not necessarily removed in the case where the hard mask material does not affect later steps or can be utilized in later steps.

By a dry etching method or a wet etching method, a depressed portion (referred to as a depression in some cases) is sometimes formed in a region not overlapping with the processed insulating layer, conductive layer, or semiconductor layer. For example, in FIG. 10A to FIG. 10D, a depressed portion is sometimes formed in a region of the top surface of the insulating layer IS1 that does not overlap with the conductive layer ME1. Note that in this specification and the like, the formation of the depressed portion by a dry etching method or a wet etching method is not described unless otherwise specified.

The above description can be referred to for the lithography method in the subsequent description of the manufacturing method unless otherwise specified. Similarly, the above description can be referred to for the etching method (including a dry etching method and a wet etching method) in the subsequent description of the manufacturing method unless otherwise specified.

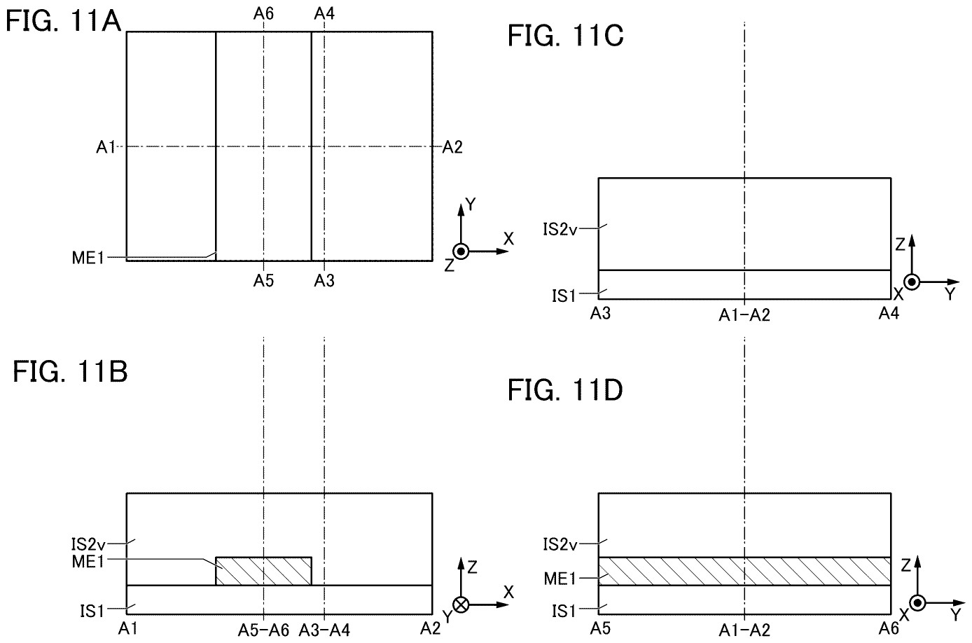

Next, an insulating film to be the insulating layer IS2 is formed over the insulating layer IS1 and the conductive layer ME1. After that, planarization treatment is performed on the insulating film to be the insulating layer IS2 by a chemical mechanical polishing (CMP) method or the like to planarize the top surface of the insulating film to be the insulating layer IS2, and an insulating film IS2v is formed (see FIG. 11A to FIG. 11D).

The insulating film IS2v is a film to be the insulating layer IS2 in a later step. The insulating layer IS2 has a function of an interlayer film, for example. Thus, the insulating layer IS2 preferably contains an insulating material with a low relative permittivity. When an insulating material with a low relative permittivity is used for an interlayer film, parasitic capacitance generated between wirings can be reduced. Thus, a material that can be used for the insulating layer IS1, for example, can be used for the insulating film to be the insulating layer IS2 formed over the insulating layer IS1 and the conductive layer ME1.

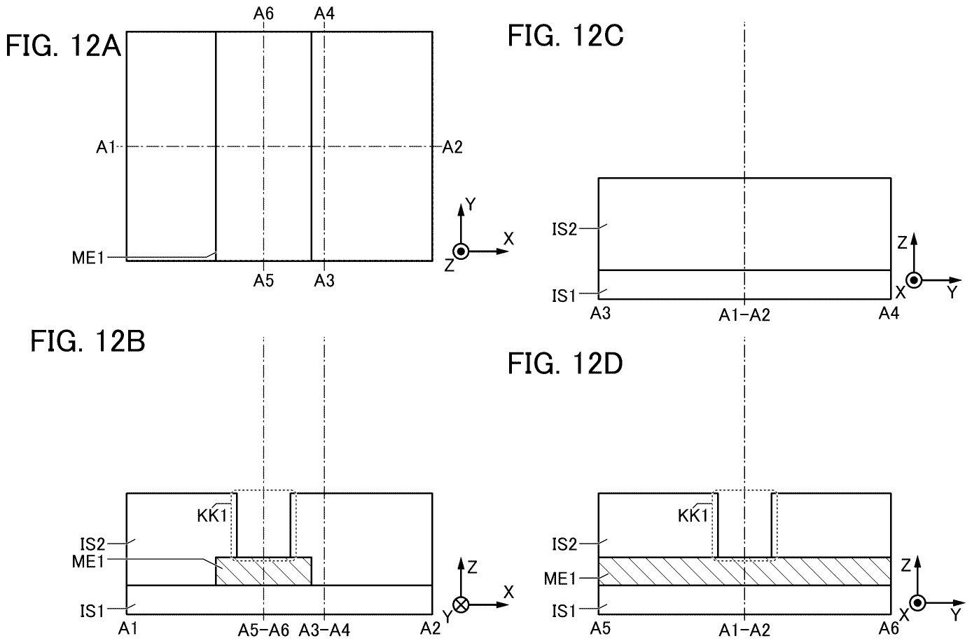

Next, the insulating film IS2v is processed by a lithography method to form the insulating layer IS2 (see FIG. 12A to FIG. 12D). Note that the insulating layer IS2 includes the opening KK1 provided by the lithography method. For the processing, a dry etching method or a wet etching method can be employed, and processing by a dry etching method is particularly suitable for microfabrication. That is, a dry etching method is preferably used for the above processing to form the opening KK1 with a small area in the plan view.

The opening KK1 is formed so that the top surface of the conductive layer ME1 is the bottom portion of the opening KK1, as illustrated in FIG. 12B and FIG. 12D. Note that in some cases, the opening KK1 can be formed so that the bottom portion of the opening KK1 includes the top surface of the insulating layer IS1 in addition to the top surface of the insulating layer IS2 (not illustrated). In this case, the conductive layer ME2 formed later is also in contact with an end portion of the conductive layer ME1, which leads to lower contact resistance between the conductive layer ME1 and the conductive layer ME2.

In FIG. 12A to FIG. 12D, the opening KK1 has a tapered shape with a taper angle to substantially establish perpendicularity (greater than or equal to 70° and less than or equal to 110°) to the X-Y plane, for example. Alternatively, the opening KK1 can have a tapered shape with a taper angle greater than or equal to 30°and less than 70° or a taper angle greater than 0° and less than 30° with respect to the X-Y plane, for example.

Note that in this specification and the like, a tapered shape refers to a shape in which at least part of a side surface of a structure is inclined to a substrate surface. An angle formed between an inclined side surface and a substrate surface is referred to as a taper angle. Specifically, in this specification and the like, a tapered shape having a taper angle greater than 0° and less than or equal to 90° is referred to as a forward tapered shape, and a tapered shape having a taper angle greater than 90° and less than 180° is referred to as an inverse tapered shape.

In FIG. 12A to FIG. 12D, the shape of the opening KK1 in the plan view can be a circle. The shape can be a shape having a curve (e.g., an ellipse, a cloud shape, or a polygon such as a triangle, a quadrangle, or a pentagon with a rounded corner) or a shape having an angle (e.g., a polygon such as a triangle, a quadrangle, or a pentagon).

A by-product generated in the above etching step is sometimes formed in a layered manner on the side surface of the opening KK1 (the side surface of the insulating layer IS2). In this case, the layered by-product is formed between the insulating layer IS2 and the conductive layer ME2 described later. Hence, the layered by-product formed in contact with the side surface of the insulating layer IS2 is preferably removed.

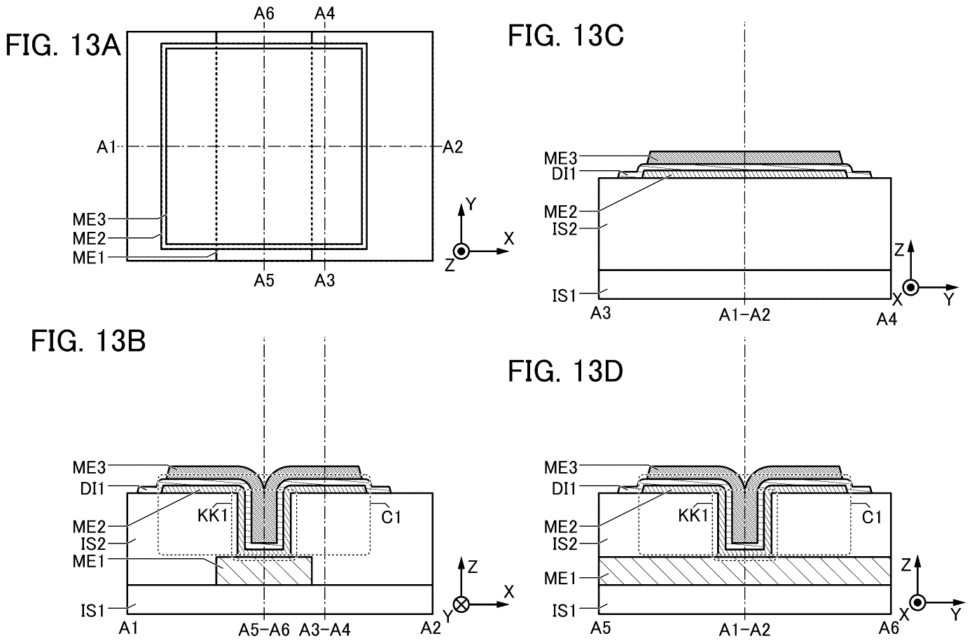

Next, a conductive film to be the conductive layer ME2 is formed over the insulating layer IS2 and the conductive layer ME1. Specifically, the conductive film is formed on the top surface of the conductive layer ME1 and the side surface of the insulating layer IS2 in the opening KK1. Furthermore, the conductive film is formed on the top surface of the insulating layer IS2 outside the opening KK1. That is, the conductive film is formed on the bottom portion and inner side surface of the opening KK1 and the top surface of the insulating layer IS2. The conductive film can be formed by a film formation method such as a sputtering method, a CVD method, an MBE method, a PLD method, or an ALD method. In particular, the conductive film is preferably formed by an ALD method because the conductive film needs to be formed on the bottom portion and inner side surface of the opening KK1 with good coverage as illustrated in FIG. 13B and FIG. 13D. An ALD method is a film formation method in which a precursor and a reactant (e.g., an oxidizer) are alternately introduced, and the thickness can be adjusted depending on the number of repetition times of the sequence of the introduction; thus, accurate control of the thickness is possible. By an ALD method, atomic layers can be deposited one by one on the bottom portion and inner side surface of the opening KK1, whereby the conductive film can be formed on the bottom portion and inner side surface of the opening KK1 with good coverage.

When the taper angle of the side surface of the opening KK1 is less than 90°, not only an ALD method but also, for example, a sputtering method can be used for the formation of the conductive film. Compared with an ALD method, a sputtering method can offer a high deposition rate, reducing the takt time of the semiconductor device.

Since the conductive film is formed as the conductive layer ME2 in a later step, a material that can be used for the conductive layer ME1, for example, can be used for the conductive film. The conductive layer ME2 can have a stacked-layer structure including a plurality of conductive layers as the conductive layer LM2, for example, as in the memory cell MC3 in FIG. 8A to FIG. 8D. For example, when the conductive layer LM2 includes a first conductor having a function of inhibiting diffusion of oxygen and a second conductor having high conductivity and has a stacked-layer structure in which the second conductor is surrounded by the first conductor, a reduction in the conductivity of the first conductor can be prevented. Note that for the stacked-layer structure, the first conductor, and the second conductor, the above description of the case where the conductive layer ME1 has a stacked-layer structure can be referred to.

Next, the conductive film to be the conductive layer ME2 is processed by a lithography method to expose part of the insulating layer IS2, so that the conductive layer ME2 is formed (see FIG. 13A to FIG. 13D).

Next, an insulating film to be the insulating layer DI1 is formed over the insulating layer IS2 and the conductive layer ME2. After that, the insulating film is processed by a lithography method to expose the insulating layer IS2, so that the insulating layer DI1 is formed (see FIG. 13A to FIG. 13D).

The insulating layer DI1 is an insulating layer corresponding to the dielectric of the capacitor C1. For this reason, a high-permittivity (high-k) material is preferably used for the insulating layer DI1. Specifically, for example, a high permittivity material such as aluminum oxide, hafnium oxide, tantalum oxide, zirconium oxide, or hafnium zirconium oxide can be used for the insulating layer DI1. Alternatively, for another example, an oxide that contains one or both of aluminum and hafnium is preferably used, an oxide that has an amorphous structure and contains one or both of aluminum and hafnium is more preferably used, and hafnium oxide that has an amorphous structure is further preferably used. Alternatively, for another example, lead zirconate titanate (PZT), strontium titanate (SrTiO₃), or (Ba, Sr)TiO₃ (BST) can be used. Using a high permittivity-material for the dielectric of the capacitor C1 can increase the capacitance value of the capacitor C1 and extend the data retention time of the memory cell MC.

With the use of a material that can have ferroelectricity for the insulating layer DI1, the capacitor C1 can be a ferroelectric capacitor. In other words, the memory cell MC can have a structure called a ferroelectric random access memory (FeRAM). Unlike a paraelectric, a ferroelectric material keeps its internal dielectric polarization (also referred to as remanent polarization in some cases) even after voltage application is stopped. This allows the data written to the capacitor C1 to be retained even by generation of leakage current through the transistor M1.

Examples of the material that can have ferroelectricity include, besides hafnium oxide, zirconium oxide, zirconium hafnium oxide (sometimes referred to as HfZrO_{X} (X is a real number greater than 0)), a material in which an element J₁ (the element J₁ here is zirconium (Zr), silicon (Si), aluminum (Al), gadolinium (Gd), yttrium (Y), lanthanum (La), strontium (Sr), or the like) is added to hafnium oxide, and a material in which an element J₂ (the element J₂ here is hafnium (Hf), silicon (Si), aluminum (Al), gadolinium (Gd), yttrium (Y), lanthanum (La), strontium (Sr), or the like) is added to zirconium oxide. Alternatively, as the material that can have ferroelectricity, a piezoelectric ceramic having a perovskite structure, such as lead titanate (sometimes referred to as PbTiO_{X}), barium strontium titanate (BST), strontium titanate, lead zirconate titanate (PZT), strontium bismuth tantalate (SBT), bismuth ferrite (BFO), or barium titanate, can be used. The material that can have ferroelectricity can be, for example, a mixture or a compound formed of a plurality of materials selected from the above-listed materials. Since the crystal structures (characteristics) of hafnium oxide, zirconium oxide, hafnium zirconium oxides, the material obtained by adding the element J₁ to hafnium oxide, and the like can be changed depending on a variety of processes as well as the deposition conditions, a material that exhibits ferroelectricity is referred to not only as a ferroelectric but also as a material that can have ferroelectricity or a material that has ferroelectricity in this specification and the like.

Among the materials that can show ferroelectricity, a material containing hafnium oxide or a material containing hafnium oxide and zirconium oxide is preferable because the material can show ferroelectricity even when being processed into a thin film of several nanometers. Note that in this specification and the like, a layer of the material that can have ferroelectricity is referred to as a ferroelectric layer or a metal oxide film, in some cases.

The insulating layer DI1 can have a single-layer structure or a stacked-layer structure. In particular, in the case where the insulating layer DI1 has a stacked-layer structure, one or both of the above-described high permittivity material and the above-described material that can have ferroelectricity can be used for each of the insulating layers included in the insulating layer DI1.

Next, a conductive film to be the conductive layer ME3 is formed over the insulating layer IS2 and the insulating layer DI1. After that, the conductive film is processed by a lithography method to expose part of each of the insulating layer IS2 and the insulating layer DI1, so that the conductive layer ME3 is formed (see FIG. 13A to FIG. 13D).

For the conductive film to be the conductive layer ME3, a material that can be used for the conductor layer ME1 can be used, for example. The conductive layer ME3 can have a stacked-layer structure including a plurality of conductive layers as the conductive layer LM3, for example, as in the memory cell MC3 in FIG. 8A to FIG. 8D. For the stacked-layer structure of the conductive layers, the above description of the case where the conductive layer ME1 or the conductive layer ME2 has a stacked-layer structure can be referred to.

The capacitor C1 can be provided through the formation of the conductive layer ME2, the insulating layer DI1, and the conductive layer ME3.

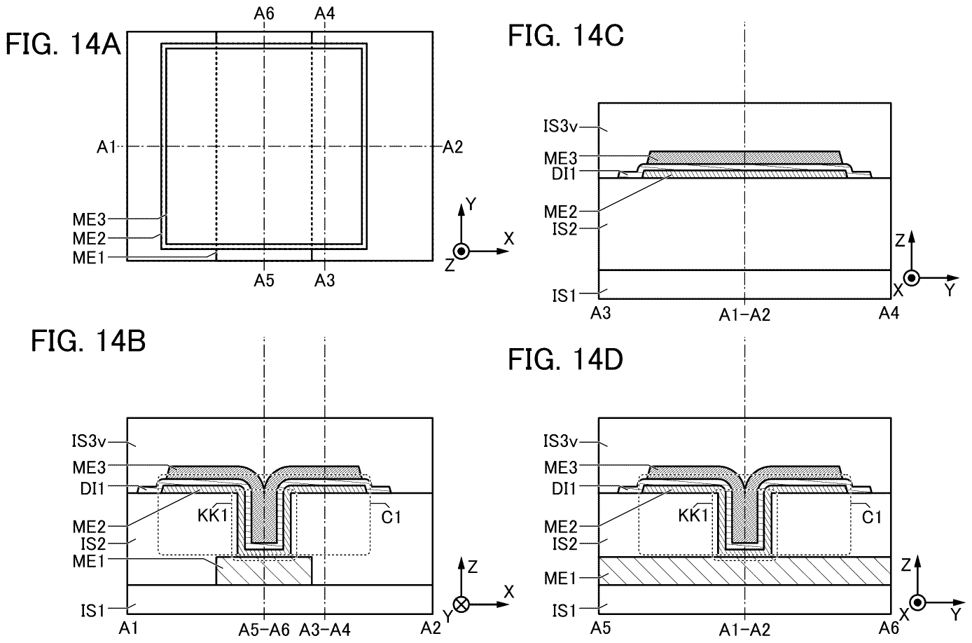

Next, an insulating film to be the insulating layer IS3 is formed over the insulating layer IS2, the insulating layer DI1, and the conductive layer ME3. After that, planarization treatment is performed on the insulating film to be the insulating layer IS3 by a CMP method or the like to planarize the top surface of the insulating film to be the insulating layer IS3, and an insulating film IS3v is formed (see FIG. 14A to FIG. 14D).

The insulating film IS3v is a film to be the insulating layer IS3 in a later step. The insulating layer IS3 has a function of an interlayer film, for example. Thus, the insulating layer IS3 preferably contains an insulating material with a low relative permittivity. When an insulating material with a low relative permittivity is used for an interlayer film, parasitic capacitance generated between wirings can be reduced. Thus, a material that can be used for the insulating layer IS1 or the insulating layer IS2, for example, can be used for the insulating film to be the insulating layer IS3.

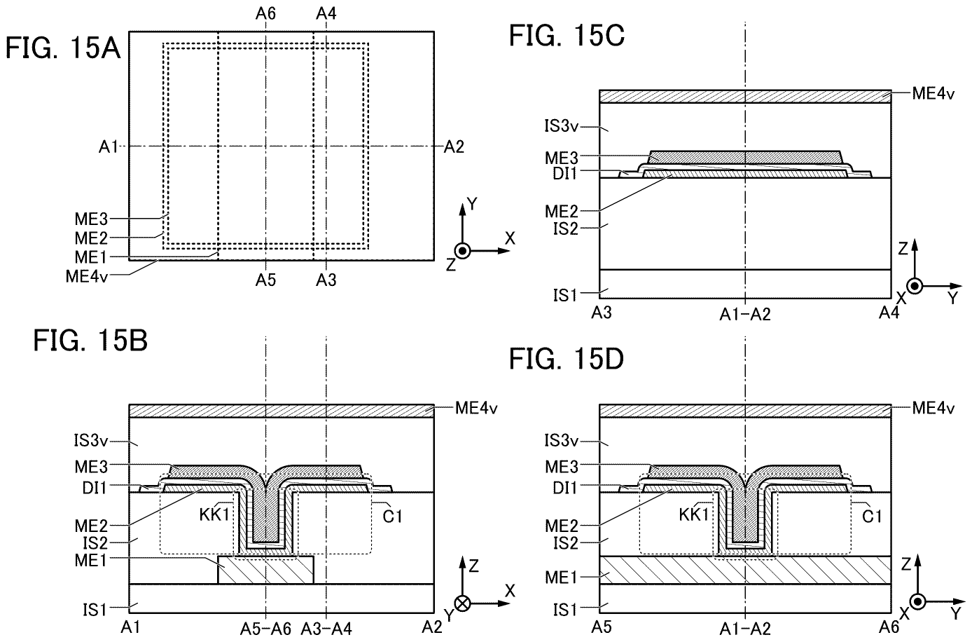

Next, a conductive film ME4v is formed over the insulating film IS3v (see FIG. 15A to FIG. 15D).

The conductive film ME4v is a film to be the conductive layer ME4 in a later step. The conductive layer ME4 has a function of a wiring electrically connected to the other of the source and the drain of the transistor M1. Part of the conductive layer ME4 has a function of the other of the source and the drain of the transistor M1. Thus, a material having high conductivity is preferably used for the conductive film ME4v. A material that can be used for the conductive layer ME1 can be used for the conductive film ME4v, for example.

The conductive layer ME4 can have a stacked-layer structure including a plurality of conductive layers as the conductive layer LM4, for example, as in the memory cell MC3 in FIG. 8A to FIG. 8D. For the stacked-layer structure of the conductive layers, the above description of the case where the conductive layer ME1 or the conductive layer ME2 has a stacked-layer structure can be referred to.

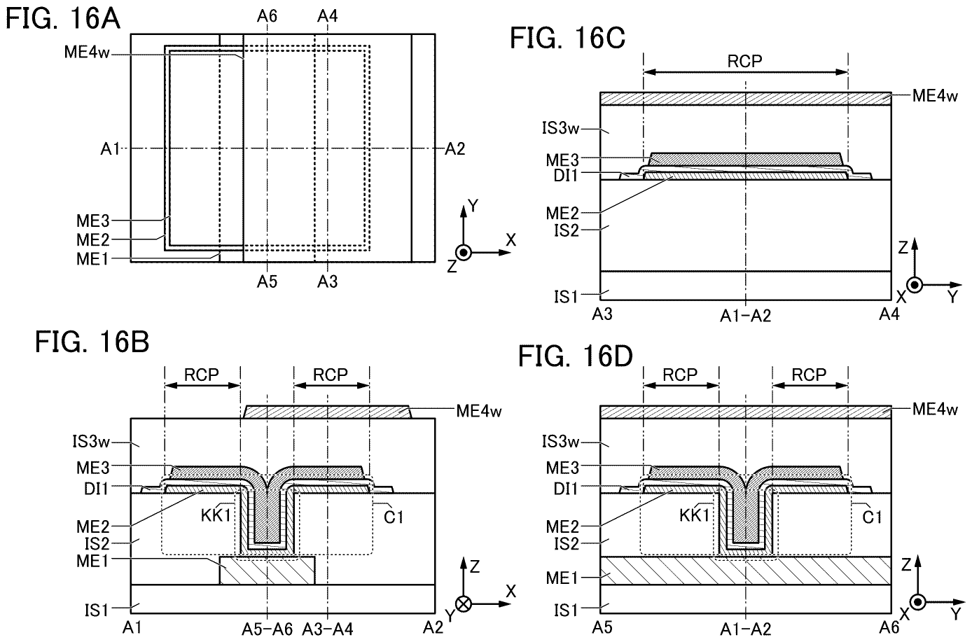

Next, the conductive film ME4v is processed by a lithography method so that part of the insulator IS3 is exposed, whereby a conductive film ME4w is formed (see FIG. 16A to FIG. 16D). The conductive film ME4v is processed so that the conductive film ME4w includes a region overlapping with the capacitor region RCP of the capacitor C1, i.e., the stacked-layer structure of the conductive layer ME2, the insulating layer DI1, and the conductive layer ME3 positioned on the top surface of the insulating layer IS2. Since the conductive layer ME4 has a function of a wiring electrically connected to the other of the source and the drain of the transistor M1 as described above, the conductive film ME4w extends along the LY direction in FIG. 6A to FIG. 6D, for example.

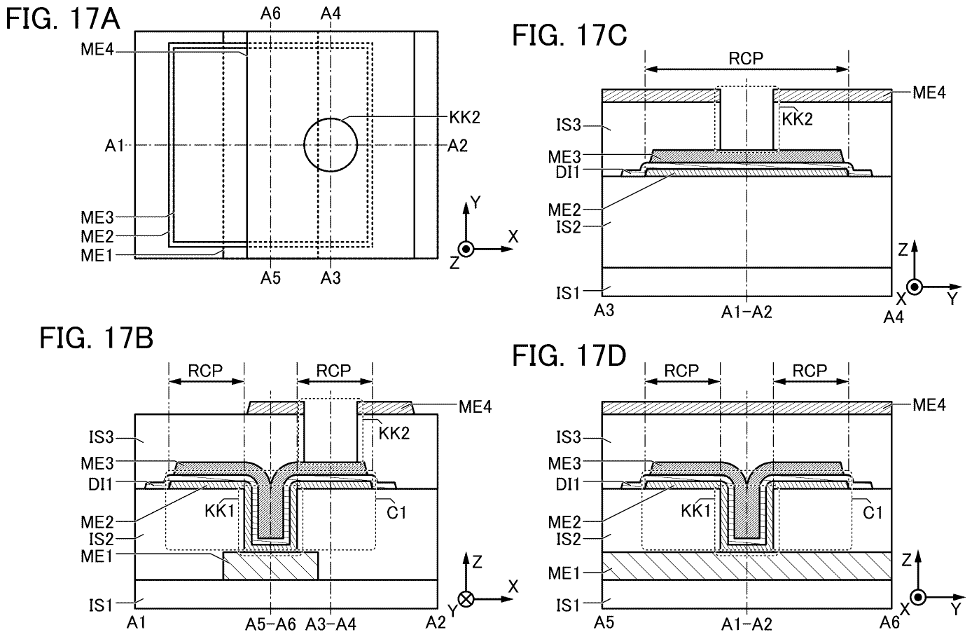

Next, the insulating film IS3w and the conductive film ME4v are processed by a lithography method to form the insulating layer IS3 and the conductive film ME4 (see FIG. 17A to FIG. 17D). Note that the insulating layer IS3 and the conductive layer ME4 each include the opening KK2 provided by the lithography method. A dry etching method or a wet etching method can be employed for the processing, and processing by a dry etching method is particularly suitable for microfabrication. That is, a dry etching method is preferably used for the above processing to form the opening KK2 with a small area in the plan view.

Specifically, the opening KK2 is formed so that the top surface of the conductive layer ME3 is the bottom portion of the opening KK2 as illustrated in FIG. 17B and FIG. 17C. Specifically, the opening KK2 is formed in a region overlapping with at least part of the capacitor region RCP of the capacitor C1.

In FIG. 17A to FIG. 17D, the opening KK2 has a tapered shape with a taper angle to substantially establish perpendicularity (greater than or equal to 70° and less than or equal to 110°) to the X-Y plane, for example, like the opening KK1. Note that the taper angle of the opening KK2 can be the taper angle that the opening KK1 can have.

The opening KK2 has a circular shape in the plan view in FIG. 17A but can have any other shape. For example, the shape can be a plan-view shape that the opening KK1 can have.

A by-product generated in the above etching step is sometimes formed in a layered manner on the side surface of the opening KK2 (the side surfaces of the insulating layer IS3 and the conductive layer ME4). In this case, the layered by-product is formed between the insulating layer IS3 and the conductive layer ME4 and the semiconductor film SC1 described later. Hence, the layered by-product formed in contact with the side surface of each of the insulating layer IS3 and the conductive layer ME4 is preferably removed.

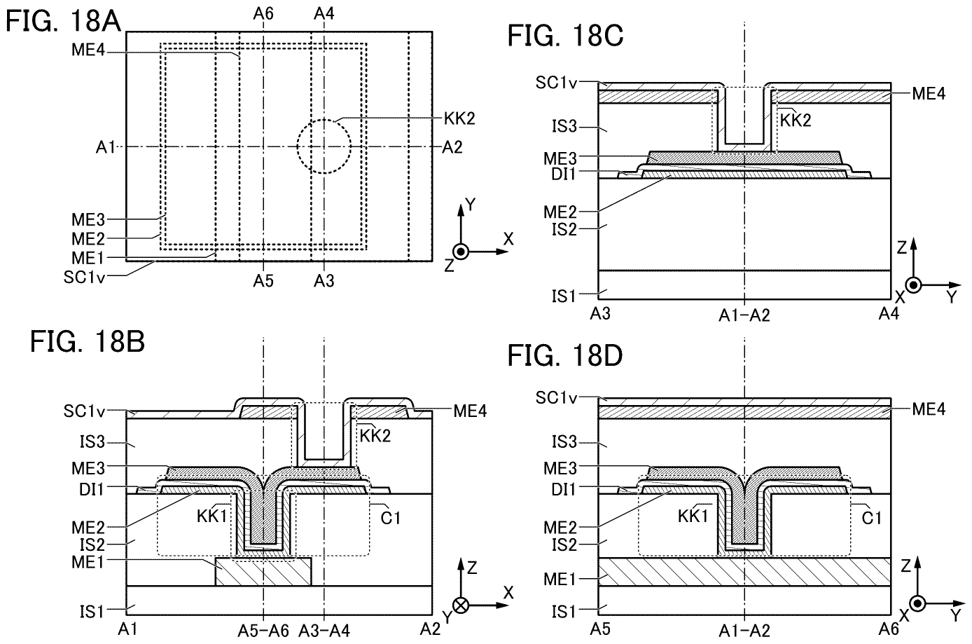

Next, a semiconductor film SC1v is formed over the conductive layer ME3, the conductive layer ME4, and the insulating layer IS3 (see FIG. 18A to FIG. 18D). Specifically, in the opening KK2, the semiconductor film SC1v is formed on the top surface of the conductive layer ME3, the side surface of the insulating layer IS3, and the side surface of the conductive layer ME4. In addition, the semiconductor film SC1v is formed on the top surface of the conductive layer ME4 and the top surface of the insulating layer IS3 outside the opening KK2. That is, the semiconductor film SC1v is formed on the bottom portion and inner side surface of the opening KK2, the top surface of the insulating layer IS3, and the top surface of the conductive layer ME4. The semiconductor film SC1v can be formed by a film formation method such as a sputtering method, a CVD method, an MBE method, a PLD method, or an ALD method. The semiconductor film SC1v is preferably formed by an ALD method, in particular, because the semiconductor film SC1v needs to be formed on the bottom portion and inner side surface of the opening KK2 with good coverage as illustrated in FIG. 18B and FIG. 18C. An ALD method is a film formation method in which a precursor and a reactant (e.g., an oxidizer) are alternately introduced, and the thickness can be adjusted depending on the number of repetition times of the sequence of the introduction; thus, accurate control of the thickness is possible. By an ALD method, atomic layers can be deposited one by one on the bottom portion and inner side surface of the opening KK2, whereby the conductive film can be formed on the bottom portion and the inner side surface of the opening KK2 with good coverage.

When the taper angle of the side surface of the opening KK2 is less than 90°, not only an ALD method but also, for example, a sputtering method can be used for the formation of the conductive film. Compared with an ALD method, a sputtering method can offer a high deposition rate, reducing the takt time of the semiconductor device.

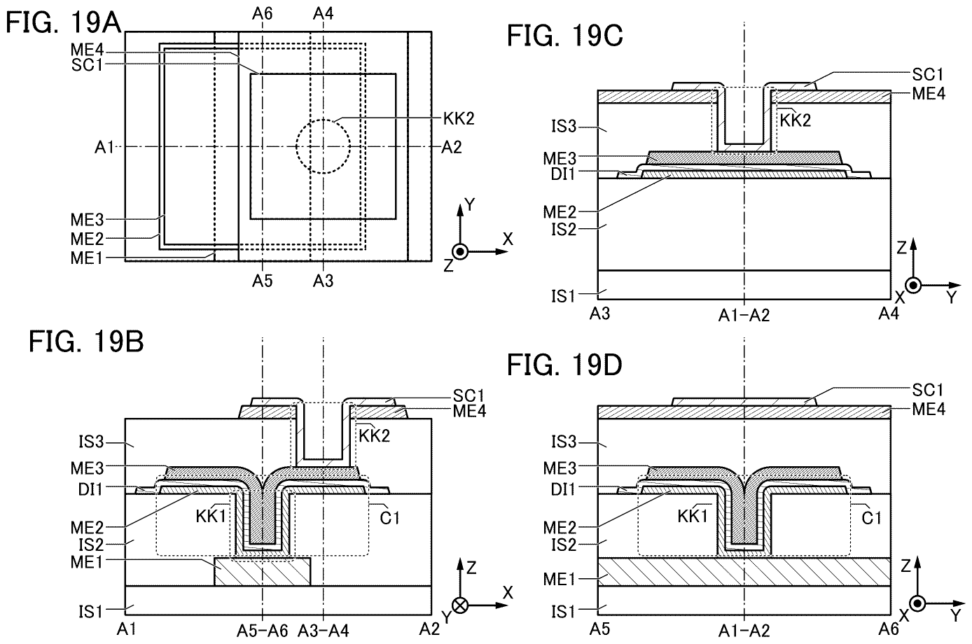

Next, the semiconductor film SC1v is processed by a lithography method to expose part of the insulating layer IS3 and part of the conductive layer ME4, whereby the semiconductor layer SC1 is formed. Specifically, the processing is performed so that part of the semiconductor layer SC1 overlaps with the conductive layer ME4 (see FIG. 19A to FIG. 19D).

In this case, the part of the semiconductor layer SC1 functions as the channel formation region of the transistor M1 formed in a later step. Another part of the semiconductor layer SC1 may function as one of the pair of electrodes of the capacitor C1 formed in a previous step.

The semiconductor layer SC1 can be a metal oxide functioning as an oxide semiconductor, for example. In this case, the transistor M1 formed later is an OS transistor. The metal oxide preferably contains at least indium or zinc, for example. In particular, indium and zinc are preferably contained. In addition to them, an element Mis preferably contained. As the element M, for example, one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, magnesium, cobalt, and antimony can be used. In particular, the element Mis preferably one or more of aluminum, gallium, yttrium, and tin. The element M further preferably contains one or both of gallium and tin.

For the semiconductor layer SC1, indium gallium zinc oxide (hereinafter referred to as In-Ga-Zn oxide) is preferably used, for example. In particular, the In-Ga-Zn oxide is further preferably a metal oxide with a composition of In:Ga:Zn=1:1:1 [atomic ratio] or in the neighborhood thereof, a composition of 4:2:3 [atomic ratio] or in the neighborhood thereof, or a composition of 3:1:2 [atomic ratio] or in the neighborhood thereof. For another example, an In-Zn oxide is preferably used for the semiconductor layer SC1. In particular, the In-Zn oxide is further preferably a metal oxide with a composition of In:Zn=4:1 [atomic ratio] or in the neighborhood thereof.

An oxide semiconductor having a low carrier concentration is particularly preferably used for the semiconductor layer SC1. For example, the carrier concentration in an oxide semiconductor in the channel formation region is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is preferably reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. Thus, a transistor whose channel formation region is formed in an oxide semiconductor having a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film also be reduced. Examples of the impurity include hydrogen and nitrogen. Note that an impurity in an oxide semiconductor refers to, for example, an element other than the main components of the oxide semiconductor. For example, an element with a concentration lower than 0.1 atomic % can be regarded as an impurity.

A transistor including an oxide semiconductor (an OS transistor) is likely to change its electrical characteristics when impurities or oxygen vacancies (hereinafter sometimes referred to as Vo) exist in a channel formation region in the oxide semiconductor, which might degrade the reliability. In the OS transistor, a defect that is Vo in the oxide semiconductor into which hydrogen enters (hereinafter sometimes referred to as VoH) may be formed and may generate an electron serving as a carrier. When VoH is formed in the channel formation region, the donor concentration in the channel formation region increases in some cases. As the donor concentration in the channel formation region increases, the threshold voltage might vary. Accordingly, when the channel formation region in the oxide semiconductor includes Vo, the transistor tends to be normally-on (a state where a channel exists and a current flows through the transistor even when the gate-source voltage is 0 V). Therefore, impurities, oxygen vacancies, and VoH are preferably reduced as much as possible in the channel formation region in the oxide semiconductor.

The semiconductor layer SC1 preferably has a stacked-layer structure of a plurality of oxide layers that differ in the atomic ratio of metal atoms, for example. For example, the semiconductor layer SC1 can have a stacked-layer structure including a semiconductor layer SC1a and a semiconductor layer SC1b, as illustrated in FIG. 20A. Note that FIG. 20A is a schematic cross-sectional view in which the transistor M1 in the memory cell MC illustrated in FIG. 1B is enlarged. As illustrated in FIG. 20A, the semiconductor layer SC1b is positioned on a top surface of the semiconductor layer SC1a.

The conductivity of a material used for the semiconductor layer SC1a is preferably different from the conductivity of a material used for the semiconductor layer SC1b. For example, a material having higher conductivity than the semiconductor layer SC1b can be used for the semiconductor layer SC1a. The semiconductor layer SC1a includes regions in contact with the conductive layer ME3 and the conductive layer ME4, which function as the source and the drain, as illustrated in FIG. 20A; therefore, increasing the conductivity of a material used for the semiconductor layer SC1a can reduce the contact resistance between the semiconductor layer SC1 and the conductive layer ME3 and the contact resistance between the semiconductor layer SC1 and the conductive layer ME4. Accordingly, the transistor M1 can have a higher on-state current.

The carrier concentration of a semiconductor material used for the semiconductor layer SC1a is preferably higher than the carrier concentration of a semiconductor material used for the semiconductor layer SC1b. Increasing the carrier concentration of the semiconductor material used for the semiconductor layer SC1a enables the semiconductor layer SC1a to have higher conductivity.

The band gap of a first oxide semiconductor used for the semiconductor layer SC1a and the band gap of a second oxide semiconductor used for the semiconductor layer SC1b are preferably different from each other. For example, the difference between the band gap of the first semiconductor material and the band gap of the second oxide semiconductor is preferably greater than or equal to 0.1 eV, further preferably greater than or equal to 0.2 eV, still further preferably greater than or equal to 0.3 eV. When the band gap of the first oxide semiconductor is less than that of the second oxide semiconductor, the contact resistance between the semiconductor layer SC1 and the conductive layer ME3 and the contact resistance between the semiconductor layer SC1 and the conductive layer ME4 can be reduced. Note that depending on circumstances, the band gap of the first oxide semiconductor can be greater than the band gap of the second oxide semiconductor.

As described above, the band gap of the first oxide semiconductor used for the semiconductor layer SC1a can be smaller than the band gap of the second oxide semiconductor used for the semiconductor layer SC1b. The composition of the first oxide semiconductor is preferably different from that of the second oxide semiconductor. When the compositions of the first oxide semiconductor and the second oxide semiconductor are different from each other, the band gap can be controlled. For example, the content percentage of the element M in the first oxide semiconductor is preferably lower than that of the element M in the second oxide semiconductor. Specifically, when the first oxide semiconductor and the second oxide semiconductor are each an In-M-Zn oxide, a first metal oxide can have a composition of In:M:Zn=1:1:1 [atomic ratio] or in the neighborhood thereof, a composition of In:M:Zn=4:2:3 [atomic ratio] or in the neighborhood thereof, or a composition of In:M:Zn=3:1:2 [atomic ratio] or in the neighborhood thereof, and the second oxide semiconductor can have a composition of In:M:Zn=1:3:2 [atomic ratio] or in the neighborhood thereof, a composition of In:Ga:Zn=1:3:4 [atomic ratio] or in the neighborhood thereof, or a composition of In:M:Zn=1:1:0.5 [atomic ratio] or in the neighborhood thereof. Note that a composition in the neighborhood includes the range of ±30% of an intended atomic ratio.

The semiconductor layer SC1a can have a structure in which the first oxide semiconductor does not contain the element M. For example, the first oxide semiconductor used for the semiconductor layer SC1a can be In-Zn oxide, and the second oxide semiconductor used for the semiconductor layer SC1b can be an In-M-Zn oxide. Specifically, the first oxide semiconductor can be an In-Zn oxide, and the second oxide semiconductor can be an In-Ga-Zn oxide. More specifically, the first oxide semiconductor can have a composition of In:Zn=1:1 [atomic ratio] or in the neighborhood thereof or a composition of In:Zn=4:1 [atomic ratio] or in the neighborhood thereof, and the second oxide semiconductor can have a composition of In:Ga:Zn=1:1:1 [atomic ratio] or in the neighborhood thereof.

One embodiment of the present invention is not limited to the example described here in which the content percentage of the element M in the first oxide semiconductor is lower than that of the element M in the second oxide semiconductor. The content percentage of the element M in the first oxide semiconductor can be higher than that of the element M in the second oxide semiconductor. The first oxide semiconductor and the second oxide semiconductor can have different compositions and can differ in the content percentage of an element other than the element M, for example.

With the use of a material having high conductivity for the semiconductor layer SC1b, which is closer to the conductive layer ME5 having a function of a gate than the semiconductor layer SC1a in FIG. 20A, the transistor M1 tends to be normally on (in a state where a channel is present when a voltage of 0 V is applied between the gate electrode and the source electrode and current flows through the transistor) in some cases. In other words, when the gate-source voltage is 0 V, the drain current flowing between the source and the drain (also referred to as a cut-off current in some cases) might increase. In this case, when the transistor MI is an n-channel transistor, the threshold voltage might be low. Thus, the conductivity of a material used for the semiconductor layer SC1b is preferably lower than at least the conductivity of a material used for the semiconductor layer SC1a.

The thickness of the semiconductor layer SC1 is preferably greater than or equal to 1 nm, greater than or equal to 3 nm, or greater than or equal to 5 nm and less than or equal to 20 nm, less than or equal to 15 nm, less than or equal to 12 nm, or less than or equal to 10 nm.

The thickness of the semiconductor layer (here, the semiconductor layer SC1a and the semiconductor layer SC1b) included in the semiconductor layer SC1 can be determined so that the thickness of the semiconductor layer SC1 is within the above range. The thickness of the semiconductor layer SC1a can be determined so that the contact resistance between the semiconductor layer SC1 and the conductor ME3 and the contact resistance between the semiconductor layer SC1 and the conductor ME4 are within the required range. The thickness of the semiconductor layer SC1b can be determined so that the threshold voltage of the transistor is within the required range. Note that the thickness of the semiconductor layer SC1a can be equal to or different from the thickness of the semiconductor layer SC1b.

The semiconductor layer SC1a and the semiconductor layer SC1b differ in the ratio of the thickness of a portion formed on the top surface of the conductive layer ME4 to the thickness of a portion formed on the side surface of the conductive layer ME4 and the side surface of the insulating layer IS3 in some cases.

The structure example in which the semiconductor layer SC1 has a single-layer structure and the structure example in which the semiconductor layer SC1 has a stacked-layer structure of two layers including the semiconductor layer SC1a and the semiconductor layer SC1b are described above; however, one embodiment of the present invention is not limited thereto. For example, the semiconductor layer SC1 can have a stacked-layer structure of three or more layers.

FIG. 20B is a schematic cross-sectional view of the memory cell MC in which the semiconductor layer SC1 has a stacked-layer structure including the semiconductor layer SC1a, the semiconductor layer SC1b, and a semiconductor layer SC1c. Note that FIG. 20B is a schematic cross-sectional view in which the transistor M1 in the memory cell MC illustrated in FIG. 1B is enlarged, as in FIG. 20A. As illustrated in FIG. 20B, the semiconductor layer SC1b is positioned on the top surface of the semiconductor layer SC1a, and the semiconductor layer SC1c is positioned on the top surface of the semiconductor layer SC1b.

The atomic ratio of the element M to In in the oxide semiconductor used for the semiconductor layer SC1a is preferably higher than that in the metal oxide used for the semiconductor layer SC1b. With such a structure, impurities and oxygen can be inhibited from diffusing into the semiconductor layer SC1b from the components formed outside the semiconductor layer SC1a. In addition, elements contained in the insulating layer IS3, the conductive layer ME3, or the conductive layer ME4 can be inhibited from diffusing into the semiconductor layer SC1b.

Since the semiconductor layer SC1c is closer to the conductive layer ME5 having a function of a gate than the semiconductor layer SC1a and the semiconductor layer SC1b in FIG. 20B, a material used for the semiconductor layer SC1c preferably has lower conductivity than the materials used for the semiconductor layer SC1a and the semiconductor layer SC1b. This enables the transistor M1 to have a high threshold voltage and a low cut-off current in the case where the transistor M1 is an n-channel transistor.

The carrier concentration of the second oxide semiconductor included in the semiconductor layer SC1b is preferably higher than the carrier concentration of a third oxide semiconductor included in the semiconductor layer SC1c. Increasing the carrier concentration of the second oxide semiconductor included in the semiconductor layer SC1b results in higher conductivity thereof, which enables the transistor to have a high on-state current. When the carrier concentration of the third oxide semiconductor included in the semiconductor layer SC1c is reduced, the conductivity is reduced, and thus the transistor can have normally-off characteristics.

Although a material having higher conductivity than the semiconductor layer SC1c is used for the semiconductor layer SC1b in the example described here, one embodiment of the present invention is not limited thereto. For the semiconductor layer SC1b, a material having lower conductivity than the semiconductor layer SC1c can be used. Furthermore, the carrier concentration of the second oxide semiconductor included in the semiconductor layer SC1b can be lower than the carrier concentration of the third oxide semiconductor included in the semiconductor layer SC1c.

The band gap of the second oxide semiconductor used for the semiconductor layer SC1b and the band gap of the third oxide semiconductor used for the semiconductor layer SC1c are preferably different from each other. For example, the difference between the band gap of the second oxide semiconductor and the band gap of the third oxide semiconductor is preferably greater than or equal to 0.1 eV, further preferably greater than or equal to 0.2 eV, still further preferably greater than or equal to 0.3 eV.

The band gap of the second oxide semiconductor used for the semiconductor layer SC1b can be smaller than the band gap of the third oxide semiconductor used for the semiconductor layer SC1c. This enables the transistor M1 to have a high on-state current. In addition, the transistor M1 can have a high threshold voltage in the case of being an n-channel transistor, and can be a normally-off transistor.

Although the example in which the band gap of the second oxide semiconductor is smaller than the band gap of the third oxide semiconductor is described here, one embodiment of the present invention is not limited thereto. The band gap of the second oxide semiconductor can be larger than that of the third oxide semiconductor.

The first oxide semiconductor used for the semiconductor layer SC1a and the third oxide semiconductor used for the semiconductor layer SC1c can have the same composition or different compositions.

For example, the structure can be employed in which a metal oxide with a composition of In:Ga:Zn=1:1:1 [atomic ratio] or in the neighborhood thereof is used for the semiconductor layer SC1a, a metal oxide with a composition of In:Zn=1:1 [atomic ratio] or in the neighborhood thereof, a metal oxide with a composition of In:Zn=4:1 [atomic ratio] or in the neighborhood thereof, or indium oxide is used for the semiconductor layer SC1b, and a metal oxide with a composition of In:Ga:Zn=1:1:1 [atomic ratio] or in the neighborhood thereof is used for the semiconductor layer SC1c. With this structure, the transistor M1 can have high on-state current and high reliability with small variations.

Using the oxide semiconductor for the semiconductor film SC1v may reduce the oxygen concentration in the semiconductor layer SC1 in the vicinity of the conductor, which is the conductive layer (corresponding to the conductive layer ME3 and the conductive layer ME4 in FIG. 19A to FIG. 19D) provided in contact with the semiconductor layer SC1. In addition, a metal compound layer, which contains a metal contained in the conductor and a component of the semiconductor layer SC1, may be formed in the semiconductor layer SC1 in the vicinity of the conductor. In such cases, a region of the semiconductor layer SC1 in the vicinity of the conductor has a higher carrier density, thereby becoming a low-resistance region.

Besides a metal oxide, for example, a material containing silicon can be used for the semiconductor layer SC1. Examples of the silicon include amorphous silicon, microcrystalline silicon, polycrystalline silicon (including low-temperature polysilicon (LTPS)), and single crystal silicon. During formation of the semiconductor film SC1v in the opening KK2, a semiconductor region where the semiconductor film SC1v is formed is preferably changed into a low-resistance region at the interface between the semiconductor region and the conductive layer ME3 in contact with each other and the vicinity thereof and at the interface between the semiconductor region and the conductive layer ME4 in contact with each other and the vicinity thereof. In this case, the low-resistance region and the semiconductor region are formed in the semiconductor layer SC1; thus, the transistor M1 can be a Si transistor.

Note that in the description in this embodiment, the semiconductor layer SC1 includes a metal oxide functioning as an oxide semiconductor.

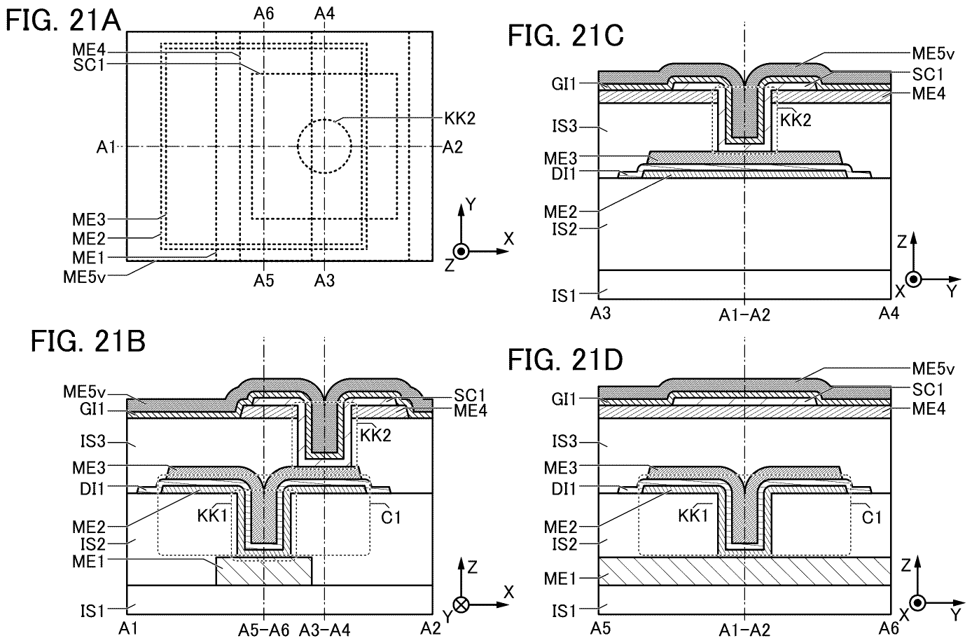

Next, the insulating layer GI1 is formed over the insulating layer IS3, the conductive layer ME4, and the semiconductor layer SC1 (see FIG. 21A to FIG. 21D).

The insulating layer GI1 has a function of the gate insulating film of the transistor M1.

For the insulating layer GI1, a single layer or stacked layers of an insulator containing what is called a high permittivity (high-k) material such as aluminum oxide, hafnium oxide, tantalum oxide, zirconium oxide, lead zirconate titanate (PZT), strontium titanate (SrTiO₃), or (Ba,Sr)TiO₃ (BST) is preferably used, for example. Alternatively, for the insulating layer GI1, as an insulator with a high relative permittivity, an oxide containing aluminum and hafnium, an oxynitride containing aluminum and hafnium, an oxide containing silicon and hafnium, an oxynitride containing silicon and hafnium, or a nitride containing silicon and hafnium can be used.

With further miniaturization and higher integration of a transistor, a problem such as generation of a leakage current can arise because of a thinned gate insulating film. When a high-k material is used for the insulating layer functioning as a gate insulating film, a gate potential at the time of the operation of the transistor can be reduced while the physical thickness is maintained.

For the insulating layer GI1 an insulating layer in which the above-described high-k material and silicon oxide or silicon oxynitride are stacked can be used. In this case, the insulating layer having high thermal stability in addition to a high relative permittivity can be used as the gate insulating film of the transistor M1.

Note that the insulating layer GI1 can have a single-layer structure or a stacked-layer structure in which two or more insulating layers of insulating materials are sequentially formed. In the case where the insulating layer GI1 has a single-layer structure, the conductive layer ME5 having a function of a gate and the semiconductor layer SC1 are brought closer together, which enables an electric field generated from the conductive layer ME5 to easily act on the channel formation region in the semiconductor layer SC1. In this case, the transistor M1 can have an increased on-state current and improved frequency characteristics. Alternatively, in the case where the insulating layer GI1 has a stacked-layer structure, there is a small gate capacitance formed between the conductive layer ME5 having a function of a gate and the conductive layer ME4 having a function of a source or a drain in a region where the conductive layer ME5 and the conductive layer ME4 overlap with each other, which can prevent degradation of switching characteristics of the transistor M1.

Note that in the case where the semiconductor layer SC1 contains a metal oxide functioning as an oxide semiconductor, after the insulating layer GI1 is formed (before a conductive film ME3A is formed at the latest), microwave treatment is preferably performed in an oxygen-containing atmosphere. Here, the microwave treatment refers to, for example, treatment using an apparatus including a power source that generates high-density plasma with use of a microwave. In this specification and the like, a microwave refers to an electromagnetic wave having a frequency greater than or equal to 300 MHz and less than or equal to 300 GHz. Note that in the case where the insulating layer GI1 has a stacked-layer structure, the microwave treatment is preferably performed at the time when the insulating layer GI1 is partially formed. For example, in the case where the insulating layer GI1 includes a silicon oxide film or a silicon oxynitride film, the microwave treatment is preferably performed at the time when the silicon oxide film or the silicon oxynitride film is formed.

For the microwave treatment, high-frequency waves such as microwaves or RF, oxygen plasma, oxygen radicals, or the like can be used. In the case of performing the microwave treatment, a microwave treatment apparatus including a power source for generating high-density plasma using microwaves is preferably used, for example. Here, the frequency of the microwave treatment apparatus is preferably set higher than or equal to 300 MHz and lower than or equal to 300 GHz, further preferably higher than or equal to 2.4 GHz and lower than or equal to 2.5 GHZ, and can be set to 2.45 GHz. Specifically, the frequency of the microwave treatment apparatus can be set to 2.45 GHz, for example. Oxygen radicals at a high density can be generated with high-density plasma. The electric power of the power source that applies microwaves of the microwave treatment apparatus is preferably set to higher than or equal to 1000 W and lower than or equal to 10000 W, further preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be efficiently introduced into the semiconductor SC1, which is a metal oxide. The effect of plasma, microwaves, and the like enables VoH included in a region of the semiconductor layer SC1 to be cut off, and hydrogen to be removed from the region. That is, VoH included in the region can be reduced. As a result, oxygen vacancies and VoH in the region can be reduced to lower the carrier concentration. In addition, oxygen radicals generated by the oxygen plasma can be supplied to oxygen vacancies formed in the region, thereby further reducing oxygen vacancies in the region and lowering the carrier concentration.

Next, a conductive film ME5v is formed over the insulating layer GI1 (see FIG. 21A to FIG. 21D).

The conductive film ME5v is a film to be the conductive layer ME5 in a later step. Part of the conductive layer ME5 has a function of the gate electrode of the transistor M1. Thus, a material having high conductivity is preferably used for the conductive film ME5v.

For the conductive layer ME5v, a material or a structure that can be used for the conductive layer ME1, the conductive layer ME2, the conductive layer ME3, or the conductive layer ME4 can be used, for example.

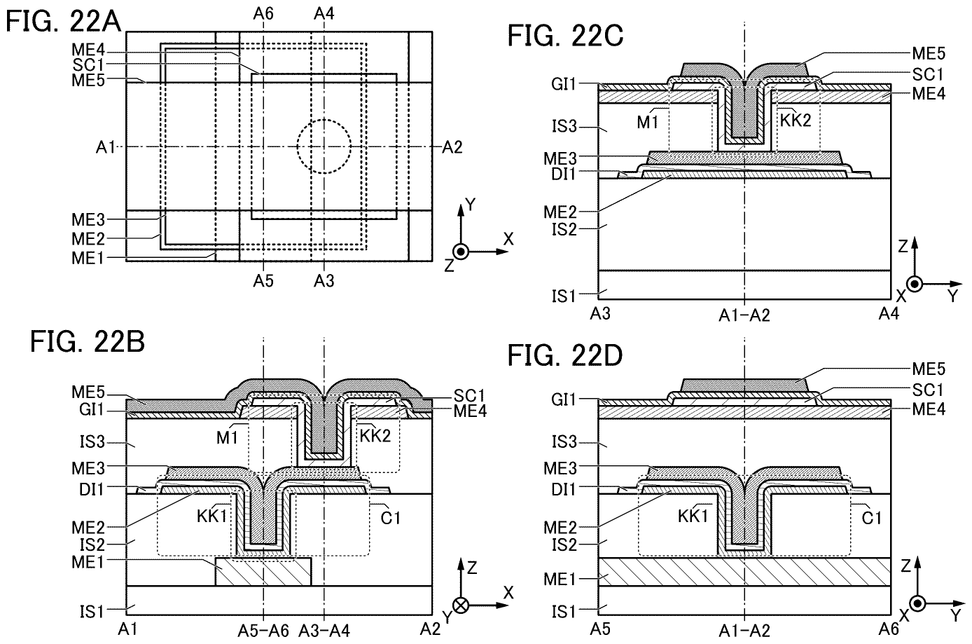

Next, the conductive film ME5v is processed into a band shape by a lithography method so that part of the insulating layer GI1 is exposed, whereby the conductive layer ME5 is formed (see FIG. 22A to FIG. 22D). Since the conductive layer ME5 has a function of a wiring electrically connected to the gate of the transistor M1 as described above, the conductive layer ME5 extends along the ±X direction in FIG. 22A to FIG. 22D, for example.

Next, the insulating layer IS4 is formed in this order over the insulating layer GI1 and the conductive layer ME5 (see FIG. 1A to FIG. 1D).

The insulating layer IS4 has a function of an interlayer film, for example. Thus, the insulating layer IS4 preferably contains an insulating material with a low relative permittivity. When an insulating material with a low relative permittivity is used for an interlayer film, parasitic capacitance generated between wirings can be reduced. Thus, a material that can be used for the insulating layer IS1, the insulating layer IS2, or the insulating layer IS3, for example, can be used for the insulating layer IS4.

Through the above manufacturing method, the memory cell MC illustrated in FIG. 1A to FIG. 1D described in Embodiment 1 can be manufactured.

### Manufacturing Method Example 2

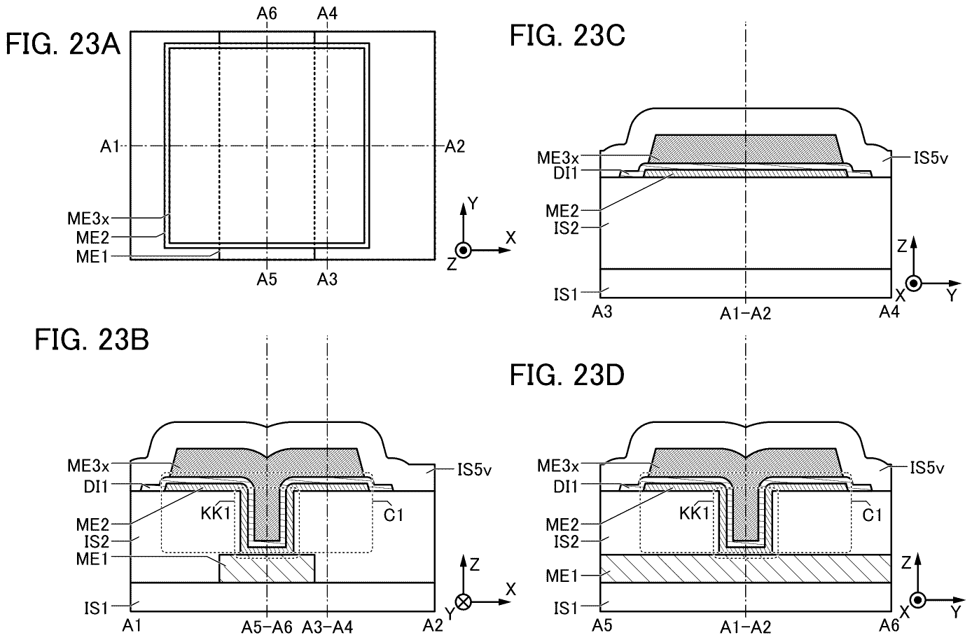

Note that the method for manufacturing the semiconductor device of one embodiment of the present invention is not limited to the above manufacturing method example. The method for manufacturing the semiconductor device of one embodiment of the present invention can be modified from that in the above manufacturing method example. Note that FIG. 23A to FIG. 25D are used for describing this manufacturing method example.

In FIG. 23A to FIG. 25D, A illustrates a schematic plan view. Moreover, B illustrates a schematic cross-sectional view corresponding to a portion along the dashed-dotted line A1-A2 illustrated in A of the corresponding drawing, and also a schematic cross-sectional view in the X direction. Furthermore, C illustrates a schematic cross-sectional view corresponding to a portion along the dashed-dotted line A3-A4 illustrated in A of the corresponding drawing, and also a schematic cross-sectional view in the Y direction. Furthermore, D illustrates a schematic cross-sectional view corresponding to a portion along the dashed-dotted line A5-A6 illustrated in A of the corresponding drawing, and also a schematic cross-sectional view in the Y direction. Note that for clarity of the drawing, some components are not illustrated in the schematic plan view of A of each drawing.

Since the manufacturing method example described below is a modification example of Manufacturing method example 1 described above, description of the portions common to the manufacturing method example 1 may be omitted. Manufacturing method example 1 described above can be referred to for part of the manufacturing method example described below.

FIG. 23A to FIG. 23D are diagrams illustrating a structure of the memory cell during manufacture, in which the conductive layer ME2 and the insulating layer DI1 are formed, a conductive film ME3x is formed over the insulating layer DI1, and an insulating film IS5v is formed over the insulating layer IS2, the insulating layer DI1, and the conductive film ME3x after the steps in FIG. 9A to FIG. 12D according to the above manufacturing method 1.

For the formation of the conductive layer ME2 and the insulating layer DI1, the description referring to FIG. 13A to FIG. 13D can be referred to.

The conductive film ME3x formed over the insulating layer DI1 is a conductive film to be the conductive layer ME3 in a later step, and differs from the conductive layer ME3 illustrated in FIG. 13A to FIG. 13D in thickness, for example. Specifically, the thickness of the conductive film ME3x is formed so that the level of a curved surface of a depressed portion in a region of the conductive film ME3x that overlaps with the opening KK1 is higher than the level of the top surface of the insulating layer DI1.

The conductive film ME3x can be formed in a manner similar to that of the conductive layer ME3 illustrated in FIG. 13A to FIG. 13D except for the thickness.

The insulating film IS5v is an insulating film to be the insulating layer IS5 in a later step. The insulating layer IS5 functions as an interlayer film positioned between the insulating layer IS2 and the insulating layer IS4 to be formed later. Thus, the insulating film IS5v preferably contains an insulating material with a low relative permittivity. When an insulating material with a low relative permittivity is used for an interlayer film, parasitic capacitance generated between wirings can be reduced. Thus, a material that can be used for the insulating layer IS1, the insulating layer IS2, the insulating layer IS3, or the insulating layer IS4, for example, can be used for the insulating layer IS5.

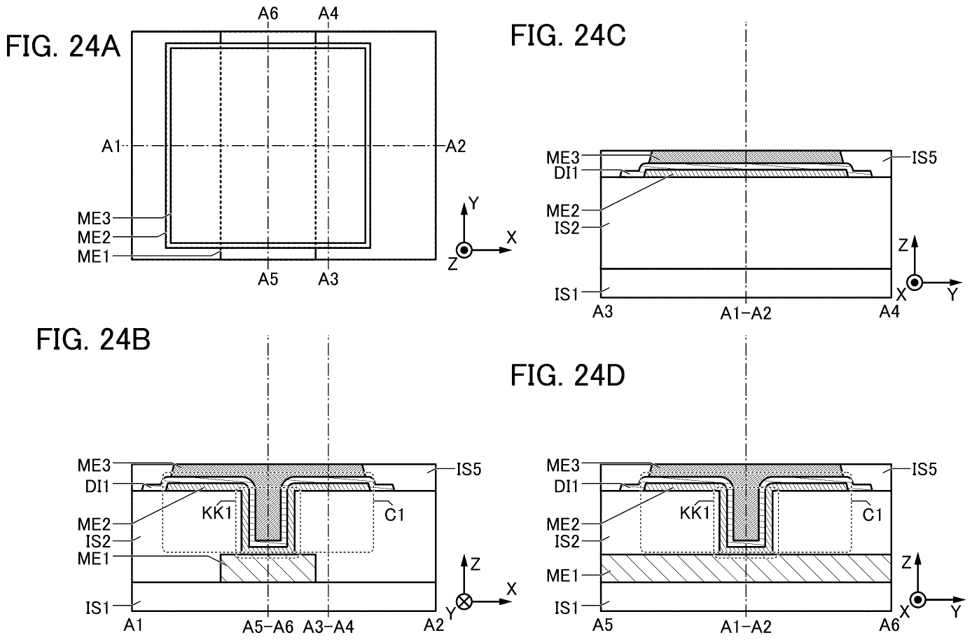

Next, planarization treatment is performed on the insulating film IS5v and the conductive film ME3x by a CMP method or the like to planarize top surfaces of the insulating film IS5v and the conductive film ME3x, whereby the insulating layer IS5 and the conductive layer ME5 are formed (see FIG. 24A to FIG. 24D).

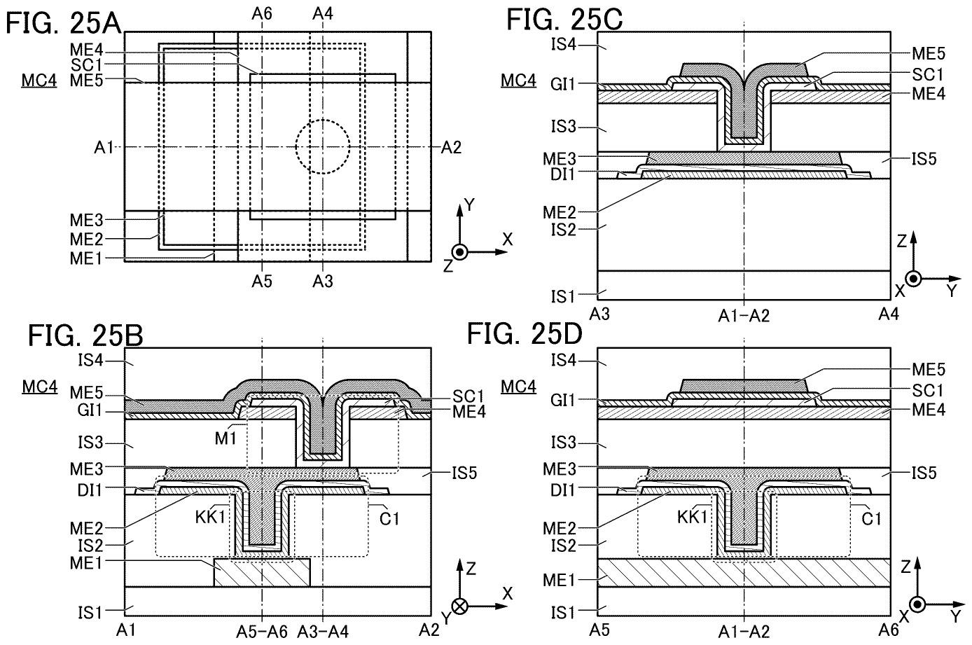

Next, steps similar to those illustrated in FIG. 14A to FIG. 19D, FIG. 21A to FIG. 22D, and FIG. 1A to FIG. 1D are performed to form the transistor M1 above the insulating layer IS5 and the conductive layer ME5, whereby a memory cell MC4 illustrated in FIG. 25A to FIG. 25D can be manufactured.

The memory cell MC4 in FIG. 25A to FIG. 25D is a modification example of the memory cell MC1 in FIG. 1A to FIG. 1D and is different from the memory cell MC1 in FIG. 1A to FIG. 1D in that the insulating layer IS5 is included and the top surface of the conductive layer ME3 is planarized.

Planarization treatment on the conductive layer ME3 can eliminate the form of the depressed portion in the region of the conductive layer ME3 in the memory cell MC in FIG. 1A to FIG. 1D overlapping with the opening KK1, as illustrated in the memory cell MC4 in FIG. 25A to FIG. 25D. This enables the opening KK2 of the insulating layer IS3 to be provided in a region overlapping with the opening KK 1 so that the opening KK1 can overlap with a region where the semiconductor layer SC1 is in contact with the top surface of the conductive layer ME3. Accordingly, the circuit area of the memory cell MC can be smaller than that of the memory cell MC in FIG. 1A to FIG. 1D.

Meanwhile, unlike the method for manufacturing the memory cell MC4 in FIG. 25A to FIG. 25D, the method for manufacturing the memory cell MC in FIG. 1A to FIG. 1D does not include the step of forming the insulating layer IS5 and the step of performing planarization treatment for forming the conductive layer ME3, and the takt time can be reduced accordingly. It can also be said that the method for manufacturing the memory cell MC in FIG. 1A to FIG. 1D requires fewer steps than the method for manufacturing the memory cell MC4 in FIG. 25A to FIG. 25D and has higher yield and lower manufacturing cost.

Thus, in the case where a plurality of memory cells are stacked, for example, it is sometimes preferable to employ the memory cell MC1, which requires fewer steps (shorter takt time, higher yield, and lower manufacturing cost) to form one memory cell.

Note that this embodiment can be combined with the same embodiment or any of the other embodiments in this specification as appropriate. For example, the configurations, structures, methods, and the like described in this embodiment can be used in an appropriate combination with any of the other configurations, the other structures, the other methods, and the like described in the same embodiment. For another example, the configurations, structures, methods, and the like described in this embodiment can be used in an appropriate combination with any of the configurations, structures, methods, and the like described in the other embodiments and the like.

### Embodiment 3

In this embodiment, a memory device including the memory cell MC described in the above embodiment will be described.

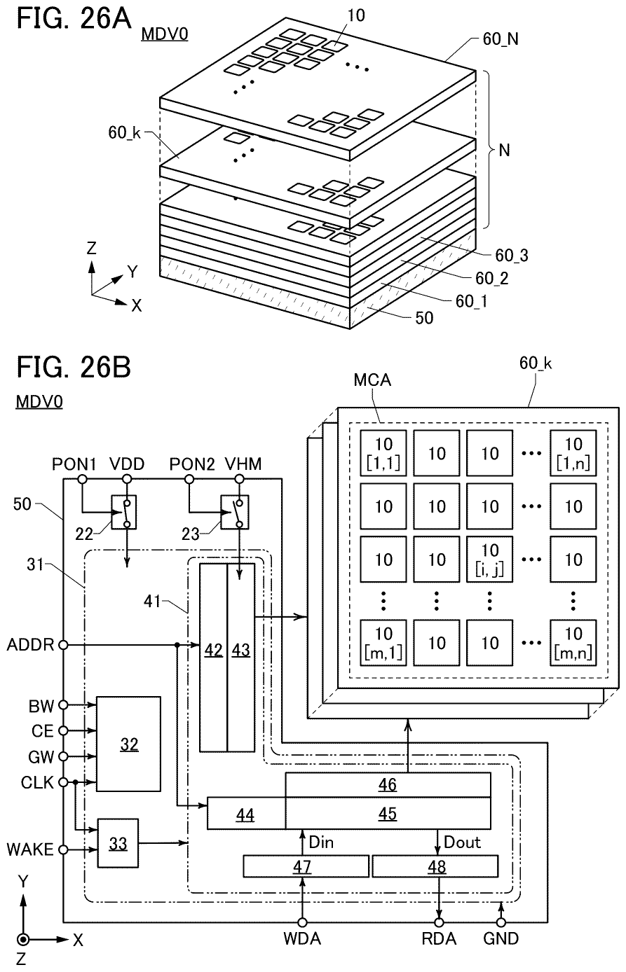

FIG. 26A is a schematic perspective view showing a structure example of a memory device MDV0. FIG. 26B is a block diagram showing the structure example of the memory device MDV0. The memory device MDV0 includes a driver circuit layer 50 and N (Nis an integer greater than or equal to 1) memory layers 60. One memory layer 60 includes a memory cell array MCA, and a plurality of memory cells 10 are arranged in a matrix of m rows and n columns in the memory cell array MCA. Note that FIG. 26B shows an example in which a memory cell 10[1,1], a memory cell 10[m,1] (here, m is an integer greater than or equal to 1), a memory cell 10[1,n] (here, nis an integer greater than or equal to 1), a memory cell 10[m,n], and a memory cell 10[i,j] (here, i is an integer greater than or equal to 1 and less than or equal to m, and j is an integer greater than or equal to 1 and less than or equal to n) are provided in a memory layer 60 k.

The memory cell 10 included in the memory layer 60 corresponds to the memory cell MC described in Embodiment 1.

The N memory layers 60 are provided over the driver circuit layer 50. In other words, N layers of the memory cell arrays MCA are provided to overlap with each other over the driver circuit layer 50. Provision of the N memory layers 60 over the driver circuit layer 50 can reduce the area occupied by the memory device MDV0. Furthermore, the memory capacity per unit area can be increased.

In this embodiment and the like, the first memory layer 60 is denoted by a memory layer 60_1, the second memory layer 60 is denoted by a memory layer 60_2, and the third memory layer 60 is denoted by a memory layer 60_3. Furthermore, the k-th memory layer 60 (k is an integer greater than or equal to 1 and less than or equal to N) is denoted by a memory layer 60_k, and the N-th memory layer 60 is denoted by a memory layer 60_N. Note that in this embodiment and the like, the simple term “memory layer 60” is sometimes used in the case of describing a matter related to all the N memory layers 60 or showing a matter common to the N memory layers 60.

Providing the memory layers 60 to overlap with each other above the driver circuit layer 50 can shorten a signal transmission distance. Note that the driver circuit layer 50 and the memory cell 10 can be provided on the same plane.

### Structure Example of Driver Circuit Layer 50

The driver circuit layer 50 includes a PSW 22 (power switch), a PSW 23, and a peripheral circuit 31. The peripheral circuit 31 includes a peripheral circuit 41, a control circuit 32, and a voltage generation circuit 33.

In the memory device MDV0, each circuit, each signal, and each voltage can be appropriately selected as needed. Another circuit or another signal can be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 can be generated in the control circuit 32.

The control circuit 32 is a logic circuit having a function of controlling the entire operation of the memory device MDV0. For example, the control circuit performs a logical operation on the signal CE, the signal GW, and the signal BW to determine an operation mode (e.g., a writing operation or a reading operation) of the memory device MDV0. The control circuit 32 generates a control signal for the peripheral circuit 41 so that the operation mode can be executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for writing and reading data to/from the memory cells 10. The peripheral circuit 41 includes a row decoder 42, a column decoder 44, a row driver 43, a column driver 45, an input circuit 47, an output circuit 48, and a sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed. That is, the row decoder 42 and the column decoder 44 are also referred to as selection circuits selecting the memory cells 10 to be written or read in some cases.

The row driver 43 has a function of selecting a write and read word line specified by the row decoder 42.

The column driver 45 has a function of writing data to the memory cells 10, a function of reading data from the memory cells 10, and a function of retaining the read data. The column driver 45 has a function of selecting a write and read bit line specified by the column decoder 44. Since the column driver 45 contributes to the writing operation to the memory cells 10, as described above, it is also referred to as a write circuit that transmits writing data to the memory cells 10 in some cases. Since the column driver 45 also contributes to the reading operation for the memory cells 10, it is also referred to as a read circuit that reads reading data from the memory cells 10 in some cases.

The input circuit 47 has a function of retaining the signal WDA. Data retained by the input circuit 47 is output to the column driver 45. Data output from the input circuit 47 is data (Din) to be written to the memory cells 10. Data (Dout) read from the memory cells 10 by the column driver 45 is amplified by the sense amplifier 46 and output to the output circuit 48. The output circuit 48 has a function of retaining Dout. In addition, the output circuit 48 has a function of outputting Dout to the outside of the memory device MDV0. Data output from the output circuit 48 is the signal RDA.

The PSW 22 has a function of controlling supply of VDD to the peripheral circuit 31. The PSW 23 has a function of controlling supply of VHM to the row driver 43. Here, in the memory device MDV0, a high power supply voltage is VDD and a low power supply voltage is GND (a ground potential). In addition, VHM is a high power supply voltage used to set a word line at a high level and is higher than VDD. The on state and the off state of the PSW 22 are switched by the signal PON1, and the on state and the off state of the PSW 23 is switched by the signal PON2. The number of power domains to which VDD is supplied is one in the peripheral circuit 31 in FIG. 26B but can be more than one. In that case, a power switch is preferably provided for each power domain.

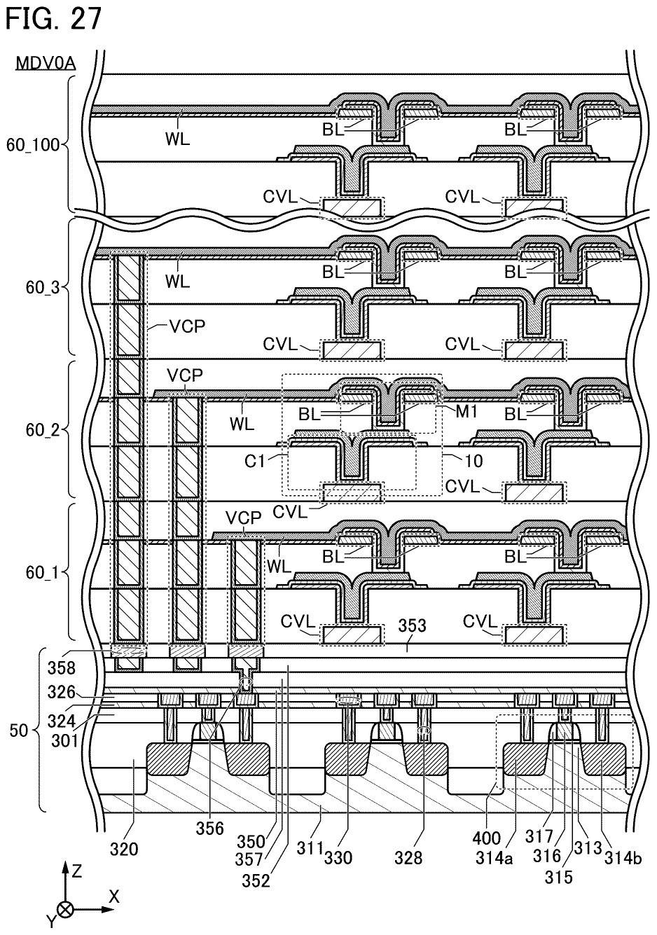

Next, FIG. 27 illustrates a cross-sectional structure example of the memory device MDV0 of one embodiment of the present invention. The memory device MDV0A illustrated in FIG. 27 has a structure in which the memory cell MC described in Embodiment 1 is used as the memory cell 10 in the memory layer 60. The memory device MDV0A in FIG. 27 includes a plurality of memory layers 60 above the driver circuit layer 50. As the plurality of memory layers 60 in the memory device MDV0A, the memory layer 60_1 to the memory layer 60_100 are illustrated in FIG. 27. In other words, the memory device MDV0A in FIG. 27 has a structure in which Nis 100 in the memory layer 60_W illustrated in FIG. 26A.

FIG. 27 illustrates a transistor 400 included in the driver circuit layer 50 as an example. The transistor 400 is provided on a substrate 311 and includes a conductive layer 316 having a function of a gate, an insulating layer 315 having a function of a gate insulating film, an insulating layer 317 formed on a side surface of the gate, a semiconductor region 313 including part of the substrate 311, and a low-resistance region 314a and a low-resistance region 314b having functions of a source region and a drain region. As the transistor 400, either a p-channel transistor or an n-channel transistor can be used. As the substrate 311, a single crystal silicon substrate can be used, for example.

Here, in the transistor 400 shown in FIG. 27, the semiconductor region 313 (part of the substrate 311) in which the channel is formed has a projecting shape. The conductive layer 316 is provided to cover a side surface and a top surface of the semiconductor region 313 with the insulating layer 315 therebetween. A material adjusting the work function can be used for the conductive layer 316. Such a transistor 400 is also referred to as a FIN-type transistor because it utilizes a protruding portion of a semiconductor substrate. An insulating layer having a function of a mask for forming a projecting portion may be provided in contact with an upper portion of the projecting portion. Furthermore, although the case where the projecting portion is formed by processing part of the semiconductor substrate is described here, a semiconductor film having a projecting shape can be formed by processing an SOI (Silicon On Insulator) substrate.

Note that the transistor 400 illustrated in FIG. 27 is an example and the structure is not limited thereto; an appropriate transistor is preferably used in accordance with a circuit structure or a driving method.

Wiring layers including an interlayer film, a wiring, and a plug are preferably provided between the structure bodies. A plurality of wiring layers can be provided in accordance with the design. Furthermore, in this specification and the like, a wiring and a plug electrically connected to the wiring can be a single component. That is, part of a conductor has a function of a wiring in some cases and part of a conductor has a function of a plug in other cases.

For example, an insulating layer 320, an insulating layer 301, an insulating layer 324, and an insulating layer 326 are provided to be sequentially stacked over the transistor 400 as interlayer films. A conductive layer 328 or the like is embedded in the insulating layer 320 and the insulating layer 301. A conductive layer 330 and the like are embedded in the insulating layer 324 and the insulating layer 326. Note that the conductive layer 328 and the conductive layer 330 function as contact plugs or wirings.

The insulating film having a function of an interlayer film can have a function of a planarization film that covers an uneven shape therebelow. For example, a top surface of the insulating layer 301 is preferably planarized by planarization treatment using a chemical mechanical polishing (CMP) method or the like to improve planarity.

A wiring layer can be provided over the insulating layer 326 and the conductive layer 330. For example, in FIG. 27, an insulating layer 350, an insulating layer 357, an insulating layer 352, and an insulating layer 353 are stacked sequentially over the insulating layer 326 and the conductive layer 330. A conductive layer 356 is formed in the insulating layer 350, the insulating layer 357, and the insulating layer 352, and a conductive layer 358 is formed in the insulating layer 353. The conductive layer 356 and the conductive layer 358 each have a function of a contact plug or a wiring. For example, the transistor 400 is electrically connected to the memory cell 10 of the memory layer 60 through a wiring VCP described later with the conductive layer 358, the conductive layer 356, the conductive layer 330, or the like therebetween. Although FIG. 27 illustrates the structure in which the transistor 400 is electrically connected to the wiring VCP, the transistor 400 can be electrically connected to another wiring.

### Structure Example of Memory Layer 60

Next, the memory layer 60_1 to the memory layer 60_100 are described.

In FIG. 27, the memory layer 60_1 to the memory layer 60_100 each include the memory cell MC in FIG. 1A to FIG. 1D described in Embodiment 1 as the memory cell 10 illustrated in FIG. 26A and FIG. 26B. Thus, the memory cell 10 in FIG. 27 includes the transistor M1 and the capacitor C1 illustrated in FIG. 1A to FIG. 1D. For specific structure examples and manufacturing methods of the transistor M1 and the capacitor C1, Embodiment 1 and Embodiment 2 can be referred to.

In FIG. 27, a plurality of wirings WL, a plurality of wirings BL, and a plurality of wirings CVL extend in each of the memory layer 60_1 to the memory layer 60_100. Specifically, the wiring WL in FIG. 27 is formed of the conductive layer ME5 illustrated in FIG. 1A to FIG. 1D. The wiring BL in FIG. 27 is formed using the conductive layer ME4 illustrated in FIG. 1 to FIG. 1D. The wiring CVL in FIG. 27 is formed using the conductive layer ME1 illustrated in FIG. 1 to FIG. 1D.

In each of the memory layer 60_1 to the memory layer 60_100, a wiring VCP is provided to be electrically connected to a circuit included in the driver circuit layer 50. The wiring VCP is formed of a conductive layer embedded in an opening provided in an interlayer film of each of the memory layer 60_1 to the memory layer 60_100. Although FIG. 27 illustrates an example in which the wiring WL included in the memory layer 60 is connected through the wiring VCP to the conductive layer 358 having a function of a wiring, the wiring BL or the wiring CVL can be connected through the wiring VCP to the conductive layer 358 having a function of a wiring.

The wiring WL has a function of a word line for the memory cell 10, for example. In other words, the wiring WL has a function of a wiring that supplies a selection signal (referred to as a variable potential (including a pulse signal and a pulse voltage, for example) in some cases). Note that depending on circumstances, the wiring WL can have a function of a wiring supplying a fixed potential, for example.

The wiring BL has a function of a bit line for the memory cell 10, for example. That is, the wiring BL has a function of a wiring that supplies a selection signal (referred to as a variable potential (including a pulse signal and a pulse voltage, for example) in some cases). Note that depending on circumstances, the wiring BL can have a function of a wiring supplying a fixed potential, for example.

The wiring CVL has a function of a wiring supplying a fixed potential to the memory cell 10, for example. The fixed potential can be, for example, a high-level potential, a low-level potential, a positive potential, a ground potential, or a negative potential. Note that depending on circumstances, the wiring CVL can have a function of a wiring supplying a variable potential to the memory cell 10, for example. Specifically, for example, when the capacitor C1 is a ferroelectric capacitor, the wiring CVL is a wiring supplying a variable potential (also referred to as a plate line in some cases), so that data can be written to or erased from the capacitor C1.

Next, a structure example of the memory layer 60 in a plan view is described.

FIG. 28 is a schematic plan view (also referred to as a layout diagram in some cases) illustrating an example of the memory cell array MCA in which the memory cells 10 are arranged in a matrix in the memory layer 60. FIG. 28 selectively illustrates the memory cells 10 in the i-th row (here, i is an integer greater than or equal to 1 and less than or equal to m-2) to the i+2-th row and the j-th row (here, j is an integer greater than or equal to 1 and less than or equal to n-2) to the j+2-th row, among the memory cells 10 included in the memory cell array MCA. As a reference numeral of the memory cells 10, only 10[i, j] is selectively shown.

Thus, FIG. 28 selectively illustrates a wiring WL[i], a wiring WL[i+1], and a wiring WL[i+2] among the plurality of wirings WL extending in the memory cell array MCA. FIG. 28 selectively also illustrates a wiring BL[j], a wiring BL[j+1], and a wiring BL[j+2] among the plurality of wirings BL extending in the memory cell array MCA.

In the memory cell array MCA illustrated in FIG. 28, the wiring BL and the wiring CVL extend in the LY direction so as to be parallel or substantially parallel to each other. The wiring WL and the wiring BL are provided to be orthogonal or substantially orthogonal to each other, and the wiring WL extends along the ±X direction.

The conductive layer MES that forms the wiring WL is provided to be shared by the plurality of memory cells 10 arranged in the row. Similarly, the conductive layer ME4 that forms the wiring BL is provided to be shared by the plurality of memory cells 10 arranged in the column. The conductive layer ME1 that forms the wiring CVL is provided to be shared by the plurality of memory cells 10 in the column.

The structure of the memory cell array MCA in the semiconductor device of one embodiment of the present invention is not limited to that in FIG. 28. For example, the directions in which the wiring WL, the wiring BL, and the wiring CVL extend are not limited to those in FIG.

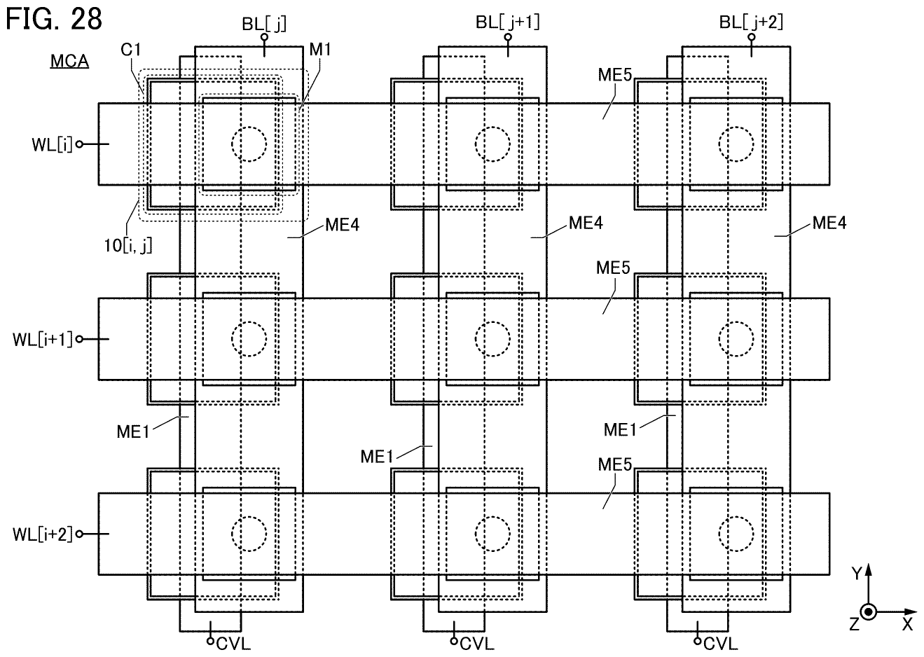

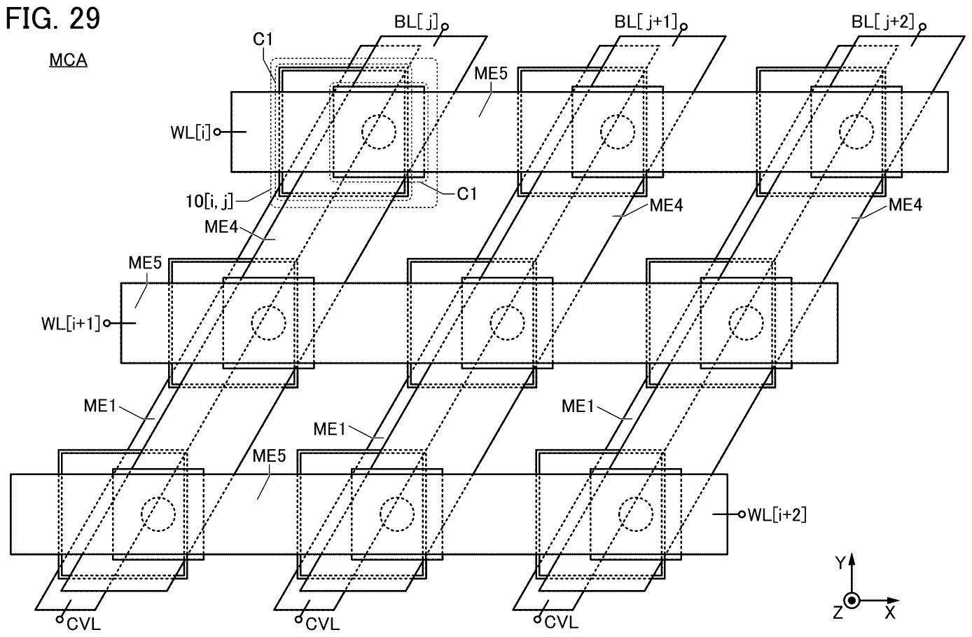

For example, the memory cell array MCA in the semiconductor device of one embodiment of the present invention can have a structure in which the wiring WL and the wiring BL are not orthogonal or not substantially orthogonal to each other. As an example, FIG. 29 illustrates a structure in which the wiring BL and the wiring CVL are provided to be parallel or substantially parallel to each other, and the wiring WL and the wiring BL are not orthogonal or substantially orthogonal to each other.

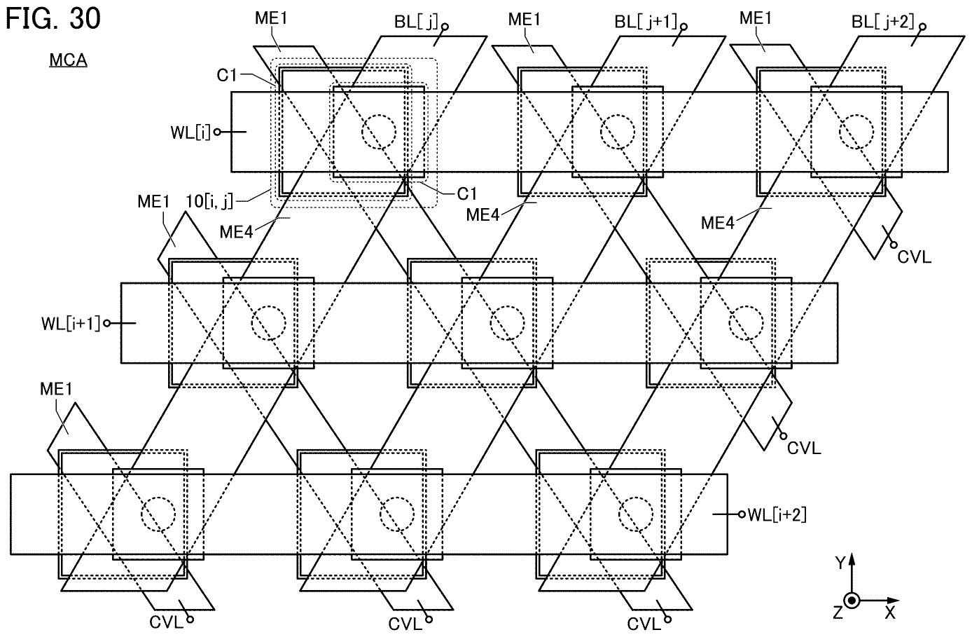

For example, the memory cell array MCA in the semiconductor device of one embodiment of the present invention can have a structure in which the wiring WL, the wiring BL, and the wiring CVL are not orthogonal or not substantially orthogonal to each other. As an example, FIG. 30 illustrates a structure in which the wiring WL, the wiring BL, and the wiring CVL are not orthogonal or substantially orthogonal to each other.

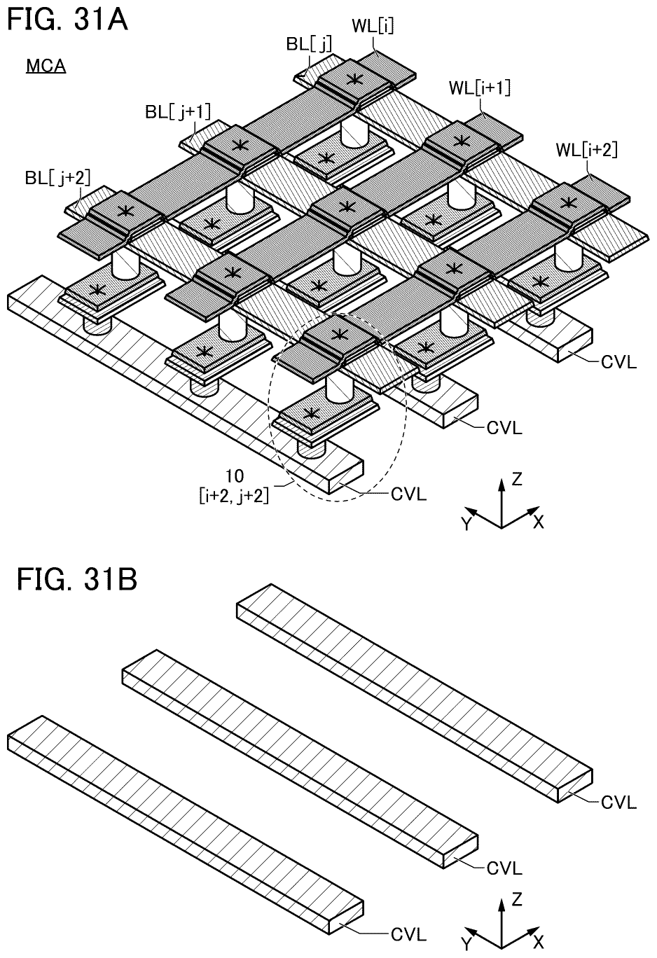

FIG. 31A is a schematic perspective view illustrating an example of the memory cell array MCA included in the memory layer 60 in FIG. 27, in which the memory cells 10 are arranged in a matrix. In other words, FIG. 31A is a schematic perspective view of the memory cell array MCA illustrated in FIG. 28. Note that FIG. 31A illustrates no insulating layers to clearly show the conductive layers and the semiconductor layers. FIG. 31B is a schematic perspective view in which the conductive layers and the semiconductor layers positioned above the wirings CVL are removed from the schematic perspective view of FIG. 31A to clearly show the wirings CVL.

FIG. 31A selectively illustrates the memory cells 10 in the i-th row to the i+2-th row and the j-th row to the j+2-th row among the memory cells 10 included in the memory cell array MCA. As a reference numeral of the memory cells 10, only 10[i+2, j+2] is selectively shown.

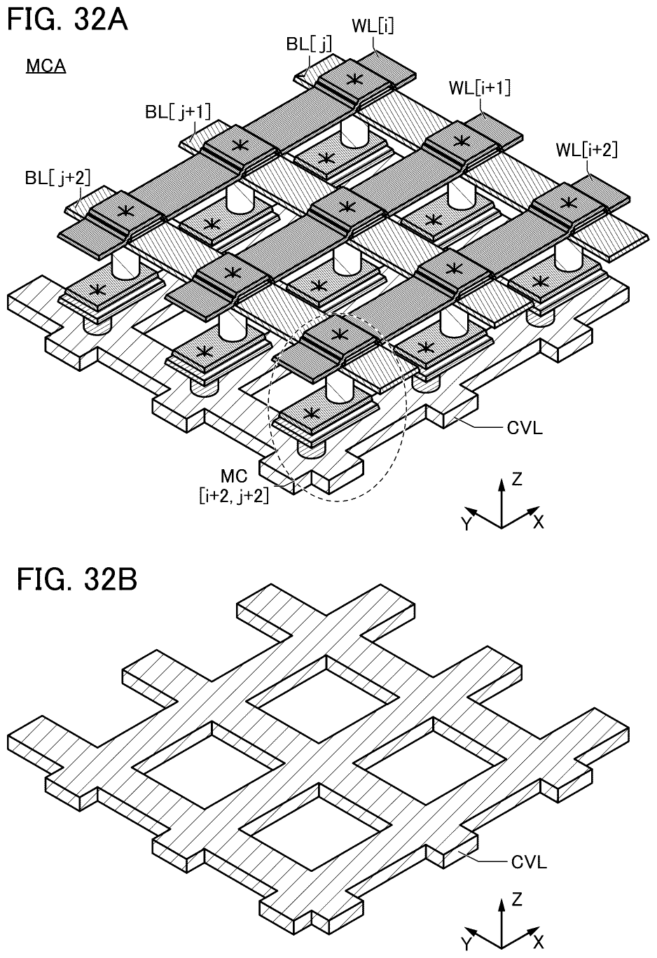

The memory cell array MCA in the semiconductor device of one embodiment of the present invention is not limited to the structure example illustrated in FIG. 31A and FIG. 31B. For example, the wirings CVL illustrated in FIG. 31A and FIG. 31B can be modified to have the shape illustrated in FIG. 32A and FIG. 32B. The wiring CVL illustrated in FIG. 32A and FIG. 32B is different from the wirings CVL illustrated in FIG. 31A and FIG. 31B in being formed in a lattice pattern.

In the memory layer 60 of the memory device MDV0A, when the potentials supplied to the plurality of wirings CVL are the same (when the potentials supplied to the plurality of wirings CVL are common potentials), the plurality of wirings CVL can be formed as the same wiring, as illustrated in FIG. 32A and FIG. 32B.

For example, the wiring CVL illustrated in FIG. 31A and FIG. 31B can be modified to have the shape illustrated in FIG. 33A and FIG. 33B. The wiring CVL illustrated in FIG. 33A and FIG. 33B is different from the wirings CVL illustrated in FIG. 31A and FIG. 31B in being formed along a plane. This structure is also effective when the potentials supplied to the plurality of wirings CVL are the same (when the potentials supplied to the plurality of wirings CVL are common potentials), as in FIG. 32A and FIG. 32B. Furthermore, since there is no step of forming a lattice pattern, the structure in FIG. 33A and FIG. 33B can be less affected by disconnection, dust, or the like due to a patterning defect or the like that occurs in the process than that in FIG. 32A and FIG. 32B.

In the memory cell array MCA in FIG. 32A and FIG. 32B, the area where the wiring CVL is formed is smaller than the area where the wiring CVL is formed in the memory cell array MCA in FIG. 33A and FIG. 33B; accordingly, the effect of parasitic capacitance and the like in the memory cell array MCA in FIG. 32A and FIG. 32B is smaller. That is, the operation of the memory cell array MCA in FIG. 32A and FIG. 32B is more stable than that of the memory cell array MCA in FIG. 33A and FIG. 33B in some cases.

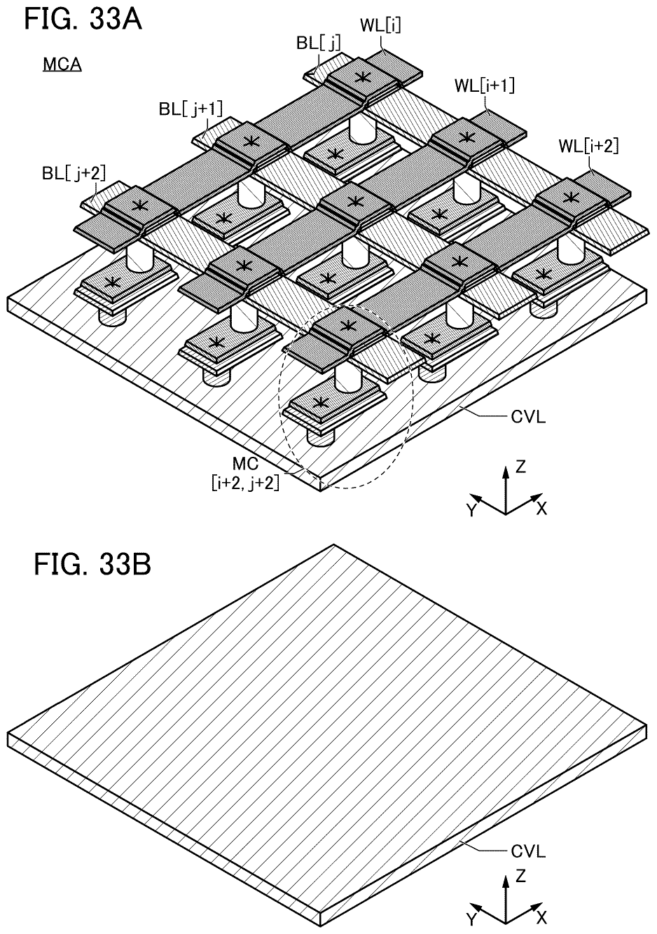

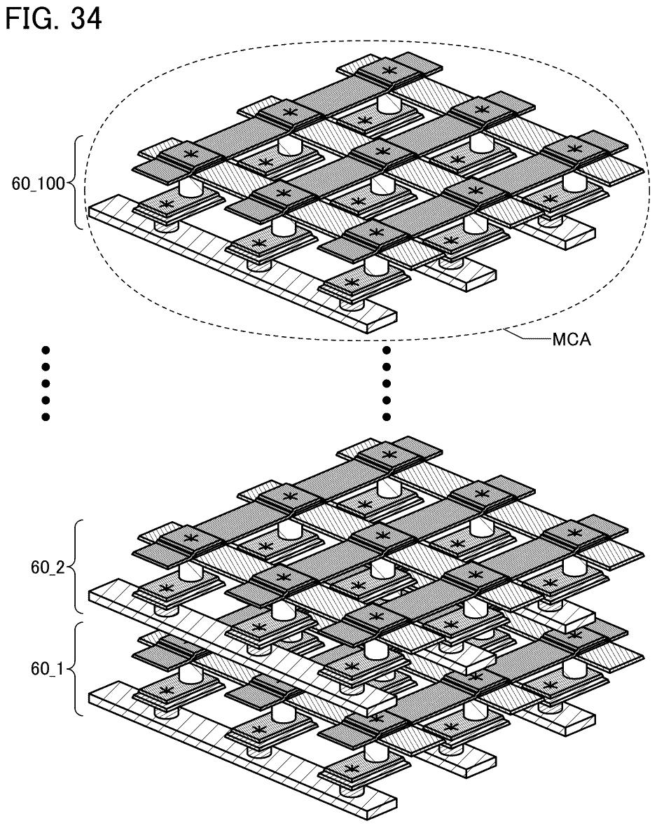

FIG. 34 is a schematic perspective view of a stacked-layer structure of the memory layer 60_1 to the memory layer 60_100 in the memory device MDV0A in FIG. 27. In other words, FIG. 34 has a structure in which 100 layers of the memory cell arrays MCA in FIG. 31A and FIG. 31B are stacked. When the plurality of memory layers 60 are stacked, the recording capacity of the memory device MDV0A can be increased. The number of layers in the memory device of one embodiment of the present invention is not limited to the number of memory layer 60, and can be greater than or equal to 1 and less than or equal to 99 or greater than 100. Since the wirings overlap with each other in the height direction, they are electrically connected through vias easily and can be supplied with signal potentials collectively. When a plurality of word lines (wirings WL) or a plurality of bit lines (wirings BL) are electrically connected to each other through vias, a driver circuit can be shared.

### Memory Cell Array and Peripheral Circuit

Next, electrical connection between the memory cell array MCA and the peripheral circuit 41 is described.

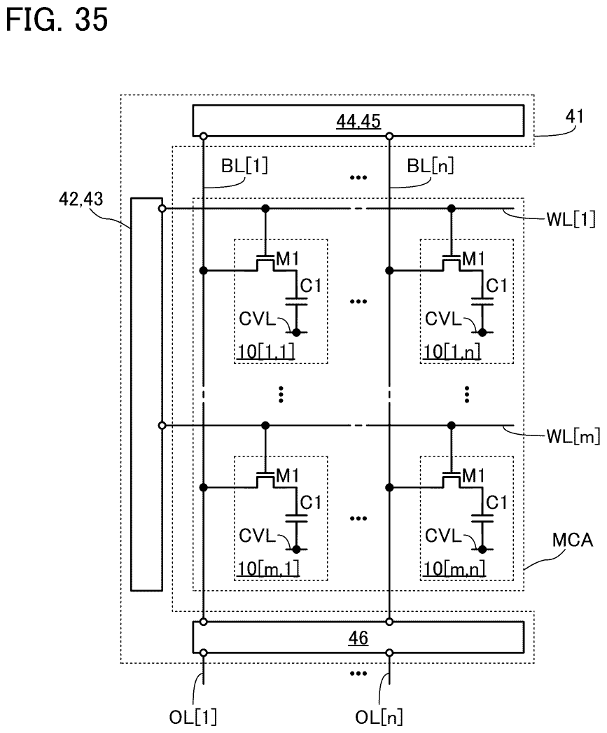

FIG. 35 is a block diagram illustrating a structure example of the peripheral circuit 41 and the memory cell array MCA. In FIG. 35, the row decoder 42 and the row driver 43 are electrically connected to each of the wiring WL[1] to the wiring WL[m], and the column decoder 44, the column driver 45, and the sense amplifier 46 are electrically connected to each of the wiring BL[1] to the wiring BL[n]. Note that the column decoder 44 and the column driver 45 are separated from the sense amplifier 46 in FIG. 35 for convenience.

Note that the wiring WL[1] to the wiring WL[m] can have a function of a word line and be formed using the conductive layer ME5 described in Embodiment 1, for example. The wiring BL[1] to the wiring BL[n] can have a function of a bit line and be formed using the conductive layer ME4 described in Embodiment 1, for example.

The memory cell 10[i,j] positioned at the i-th row and the j-th column is electrically connected to the wiring WL[i] and the wiring BL[j]. FIG. 35 selectively illustrates the memory cell 10[1,1], the memory cell 10[m,1], 10 memory cells [1,n], the memory cell 10[m,n], the wiring WL[1], the wiring WL[m], the wiring BL[1], and the wiring BL[n].

In each memory cell 10, a first terminal of the transistor MI is electrically connected to a first terminal of the capacitor C1, a second terminal of the transistor M1 is electrically connected to the wiring BL, and the gate of the transistor MI is electrically connected to the wiring WL. The second terminal of the capacitor C1 is electrically connected to the wiring CVL.

Note that the transistor M1 can include a back gate as well as a gate (also referred to as a front gate in some cases). In this case, the back gate is preferably connected to a wiring to which a fixed potential or a variable potential is supplied, and the gate and the back gate are also preferably electrically connected to each other.

The sense amplifier 46 is electrically connected to a wiring OL[1] to a wiring OL[n]. The wiring OL[1] to the wiring OL[n] can be electrically connected to the output circuit 48 illustrated in FIG. 26.

The wiring OL[1] to the wiring OL[n] each have a function of a wiring through which data read from the memory cell 10 is output from the sense amplifier 46.

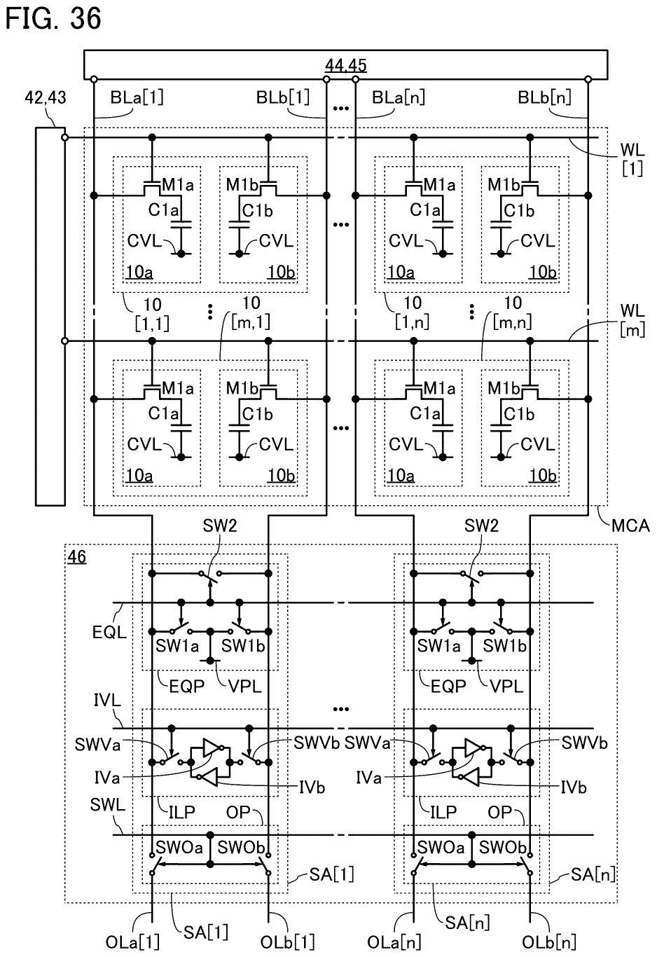

The memory cell array MCA can be modified to have a structure in which complementary data is retained. FIG. 36 illustrates a structure example in which the memory cell array MCA and the peripheral circuit 41 in FIG. 35 can be modified to retain complementary data.

The memory cell array MCA and the peripheral circuit 41 illustrated in FIG. 36 are different from those in FIG. 35 in, for example, having a circuit structure where complementary data can be written and read and the memory cell 10 includes a circuit 10a and a circuit 10b.

FIG. 36 also illustrates a structure example of the sense amplifier 46 for convenience.

Each of the memory cell 10[1,1] to the memory cell 10[m,n] includes the circuit 10a and the circuit 10b. Each of the circuit 10a and the circuit 10b includes one transistor and one capacitor. In FIG. 36, the circuit 10a includes a transistor M1a and a capacitor C1a, and the circuit 10b includes a transistor M1b and a capacitor C1b. The circuit 10a and the circuit 10b each correspond to the memory cell MC in FIG. 1A to FIG. 1D described in Embodiment 1. Thus, for the electrical connection in each of the circuit 10a and the circuit 10b, the description in Embodiment 1 of the memory cell MC in FIG. 1A to FIG. 1D and the description of the memory cell 10 in FIG. 35 can be referred to.

In the memory cell 10, the wiring WL is electrically connected to a gate of the transistor M1a and a gate of the transistor M1b. A wiring BLa is electrically connected to a second terminal of the transistor M1a, and a wiring BLb is electrically connected to a second terminal of the transistor M1b.

The wiring BLa and the wiring BLb correspond to the wiring BL in FIG. 35 and have a function of a bit line also in the circuit structure in FIG. 36. Specifically, in the circuit structure in FIG. 36, the wiring BLa and the wiring BLb are a pair of bit lines for transmitting complementary data, and the wiring BLb is a bit line to which data obtained by inverting the logic of the wiring BLa is input and is referred to as a complementary bit line or an inverted bit line in some cases.

Next, an example of a circuit structure of the sense amplifier 46 illustrated in FIG. 36 is described.

The sense amplifier 46 includes a circuit SA[1] to a circuit SA[n]. Note that each of the circuit SA[1] to the circuit SA[n] is independently referred to as a sense amplifier in some cases.

Each of the circuit SA[1] to the circuit SA[n] includes a circuit EQP, a circuit ILP, and a circuit OP.

The circuit EQP includes a switch SW1a, a switch SW1b, and a switch SW2, for example. The circuit ILP includes an inverter IVa, an inverter IVb, a switch SWVa, and a switch SWVb, for example. The circuit OP includes a switch SWOa and a switch SWOb.

An electrical switch (e.g., an analog switch or a transistor) can be used as each of the switch SW1a, the switch SW1b, the switch SW2, the switch SWVa, the switch SWVb, the switch SWOa, and the switch SWOb. In particular, as each of the above-described switches, an OS transistor or a Si transistor can be used as an electrical switch. As each of the above-described switches, a mechanical switch can be used, for example.

In this specification and the like, each of the switch SW1a, the switch SW1b, the switch SW2, the switch SWVa, the switch SWVb, the switch SWOa, and the switch SWOb is turned on when a high-level potential is applied to a control terminal, and each switch is turned off when a low-level potential is applied to the control terminal.

A first terminal of the switch SW1a is electrically connected to the wiring BLa, and a first terminal of the switch SW1b is electrically connected to the wiring BLb. A second terminal of the switch SW1a is electrically connected to a second terminal of a switch SW1b and the wiring VPL. A first terminal of the switch SW2 is electrically connected to the wiring BLa, and a second terminal of the switch SW2 is electrically connected to the wiring BLb. Each of the control terminals of the switch SW1a, the switch SW1b, and the switch SW2 is electrically connected to a wiring EQL.

A first terminal of the switch SWVa is electrically connected to the wiring BLa, and a first terminal of the switch SWVb is electrically connected to the wiring BLb. A second terminal of the switch SWVa is electrically connected to an input terminal of the inverter IVa and an output terminal of the inverter IVb, and a second terminal of the switch SWVb is electrically connected to an output terminal of the inverter IVa and an input terminal of the inverter IVb. That is, the inverter IVa and the inverter IVb form an inverter loop in the circuit ILP. A control terminal of each of the switch SWVa and the switch SWVb is electrically connected to a wiring IVL.

A first terminal of the switch SWOa is electrically connected to the wiring BLa, and a second terminal of the switch SWOa is electrically connected to the wiring OLa. A first terminal of the switch SWOb is electrically connected to the wiring BLb, and a second terminal of the switch SWOb is electrically connected to a wiring OLb. A control terminal of each of the switch SWOa and the switch SWOb are electrically connected to the wiring SWL.

The wiring OLa and the wiring OLb correspond to the wirings OL in FIG. 35. In particular, in the circuit structure in FIG. 36, the wiring OLa and the wiring OLb have a function of a pair of output wirings (bit line pair) for transmitting complementary data read from the memory cell 10.

The circuit EQP has a function of equalizing the potentials of the wiring BLa and the wiring BLb. Thus, the circuit EQP is referred to as a precharge circuit in some cases. Specifically, the circuit EQP has a function of supplying an equalizing potential to each of the wiring BLa and the wiring BLb when a high-level potential is supplied to the wiring EQL. Thus, the wiring EQL preferably has a function of a signal line for controlling switching between the on state and off state of each of the switch SW1a, the switch SW1b, and the switch SW2. The wiring VPL preferably has a function of a wiring for supplying the equalizing potential.

The circuit ILP has a function of obtaining the potentials of the wiring BLa and the wiring BLb and, in accordance with the levels of the potentials, amplifying the potentials of the wiring BLa and the wiring BLb. Specifically, the circuit ILP has a function of obtaining the potentials of the wiring BLa and the wiring BLb and, when the potential of the wiring BLa is higher than the potential of the wiring BLb, increasing the potential of the wiring BLa to the high-level potential while decreasing the wiring BLb to the low-level potential. When the potential of the wiring BLb is higher than the potential of the wiring BLa, the circuit ILP increases the potential of the wiring BLb to the high-level potential while decreasing the potential of the wiring BLa to the low-level potential.

The wiring IVL preferably has a function of a signal line for controlling switching between the on state and off state of each of the switch SWVa and the switch SWVb. The circuit ILP obtains the potentials of the wiring BLa and the wiring BLb respectively when the switch SWVa and the switch SWVb are in an on state.

The circuit OP has a function of a circuit that outputs complementary data read from the memory cell 10 to the wiring OLa and the wiring OLb. Specifically, when a high-level potential is supplied to the wiring SWL to turn on the switch SWOa and the switch SWOb, the circuit OP outputs the potentials of the wiring BLa and the wiring BLb to the wiring OLa and the wiring OLb, respectively.

Thus, the wiring SWL preferably has a function of a signal line for controlling switching between the on state and off state of each of the switch SWOa and the switch SWOb.

### Operation Method Example of Memory Device

Next, an operation method of the memory device in FIG. 36 is described.

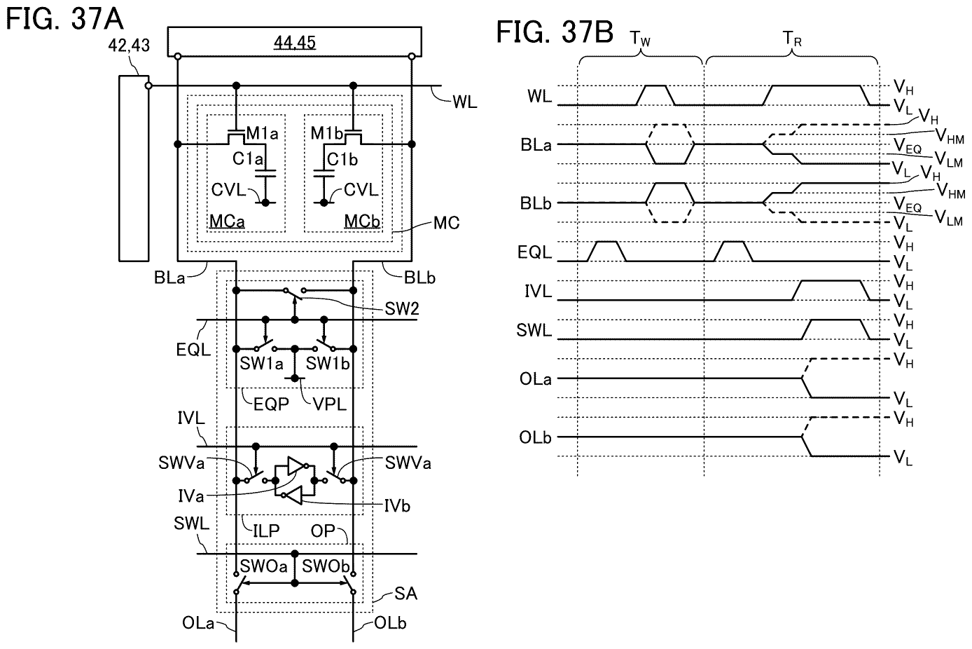

FIG. 37A is a circuit diagram illustrating the memory cell MC, the row decoder 42, the row driver 43, the column decoder 44, the column driver 45, the circuit SA, and the like, which are extracted from the memory device in FIG. 36, in order to show the writing operation and the reading operation of the memory device.

FIG. 37B is a timing chart showing an example of the writing operation and the reading operation of the memory device illustrated in FIG. 37A. Note that the timing chart in FIG. 37B shows potential changes of the wiring WL, the wiring BLa, the wiring BLb, the wiring EQL, the wiring IVL, the wiring SWL, the wiring OLa, and the wiring OLb.

In FIG. 37B, a low-level potential or a ground potential is supplied to the wiring CVL as the fixed potential in the memory device.

In a writing period T_{W}, first, a high-level potential is supplied to the wiring EQL. Accordingly, in the circuit EQP, the high-level potential (denoted by V_{H} in FIG. 37B) is supplied to the control terminals of the switch SW1a, the switch SW1b, and the switch SW2 to turn on the switch SW1a, the switch SW1b, and the switch SW2, respectively. Thus, the equalizing potential supplied to the wiring VPL is applied to the wiring BLa and the wiring BLb. Note that the equalizing potential is denoted by V_{EQ}. Thus, the potentials of the wiring BLa and the wiring BLb each become V_{EQ}.

After the potentials of the wiring BLa and the wiring BLb are each set to V_{EQ}, the low-level potential is supplied to the wiring EQL to turn off each of the switch SW1a, the switch SW1b, and the switch SW2. Thus, the wiring BLa and the wiring BLb are each brought into a floating state.

Since the circuit ILP does not operate in the writing period T_{W}, the low-level potential (denoted by V_{L} in FIG. 37B) is supplied to the wiring IVL. Thus, the low-level potential is supplied to each of control terminals of the switch SWVa and the switch SWVb, so that the switch SWVa and the switch SWVb are turned off.

In the writing period T_{W}, electrical continuity is not established between the wiring BLa and the wiring OLa, and electrical continuity is not established between the wiring BLb and the wiring OLb. Consequently, the low-level potential is supplied to the wiring SWL. Thus, a low-level potential is supplied to each of control terminals of the switch SWOa and the switch SWOb, so that the switch SWOa and the switch SWOb are turned off.

Next, the high-level potential is supplied to the wiring WL. Accordingly, the high-level potential is supplied to each of the gates of the transistor M1a and the transistor M1b included in the memory cell MC, whereby the transistor M1a and the transistor M1b are turned on.

Next, from the column driver 45, potentials corresponding to data written to the memory cell MC are input to the wiring BLa and the wiring BLb. Note that the potentials transmitted to the wiring BLa and the wiring BLb are complementary data, and the logic of data input to the wiring BLb is inverted from the logic of data input to the wiring BLb. For example, in the case where “0” is written to the memory cell MC, the low-level potential is supplied to the wiring BLa and the high-level potential is supplied to the wiring BLb. For example, in the case where “1” is written to the memory cell MC, the high-level potential is supplied to the wiring BLa and the low-level potential is supplied to the wiring BLb.

Note that in the potential changes of the wiring BLa, the wiring BLb, the wiring OLa, and the wiring OLb illustrated in FIG. 37B, each solid line represents the case where “0” is written to the memory cell MC and each dotted line represents the case where “1” is written to the memory cell MC.

Since the transistor M1a and the transistor M1b are each in an on state, the potential of the wiring BLa (one of the high-level potential and the low-level potential) is written to a first terminal of the capacitor C1a, and the potential of the wiring BLb (the other of the high-level potential and the low-level potential) is written to a first terminal of the capacitor C1b.

After that, the low-level potential is supplied to the wiring WL and the low-level potential is supplied to the gates of the transistor M1a and the transistor M1b included in the memory cell MC, whereby the transistor M1a and the transistor M1b are turned off. Accordingly, the potential of the wiring BLa (one of the high-level potential and the low-level potential) is retained in the capacitor C1a, and the potential of the wiring BLb (the other of the high-level potential and the low-level potential) is retained in the capacitor C1b.

After that, supply of potentials corresponding to data to be written from the column driver 45 to the wiring BLa and the wiring BLb is stopped. Note that although the potentials of the wiring BLa and the wiring BLb are VEQ in FIG. 37B, the potentials of the wiring BLa and the wiring BLb are not limited thereto and may be potentials other than VEQ in the operation example of the memory device of one embodiment of the present invention.

Next, reading operation of the memory device in FIG. 37A will be described.

In the timing chart in FIG. 37B, first, the high-level potential is supplied to the wiring EQL in the reading period T_{R}. Accordingly, in the circuit EQP, the high-level potential is supplied to each of the control terminals of the switch SW1a, the switch SW1b, and the switch SW2, so that the switch SW1a, the switch SW1b, and the switch SW2 are each turned on. Thus, the equalizing potential V_{EQ} supplied to the wiring VPL is applied to the wiring BLa and the wiring BLb.

After the potentials of the wiring BLa and the wiring BLb are set to V_{EQ}, the low-level potential is supplied to the wiring EQL to turn off each of the switch SW1a, the switch SW1b, and the switch SW2. Thus, the wiring BLa and the wiring BLb are each brought into a floating state.

Next, the high-level potential is supplied to the wiring WL. Accordingly, the high-level potential is supplied to the gates of the transistor M1a and the transistor M1b included in the memory cell MC, whereby the transistor M1a and the transistor M1b are turned on. As a result, charges are redistributed between the first terminal of the capacitor Cla and the wiring BLa, making each of the potentials of the first terminal of the capacitor Cla and the wiring BLa become one of V_{HM} and V_{LM}. Charges are redistributed also between the first terminal of the capacitor C1b and the wiring BLb, making each of the potentials of the first terminal of the capacitor C1b and the wiring BLb become the other of V_{HM} and V_{LM}. Note that V_{HM} is a potential higher than V_{EQ} and lower than the high-level potential, and V_{LM} is a potential higher than the low-level potential and lower than V_{EQ}.

Specifically, in the case where “0” is retained in the memory cell MC, the potential of the wiring BLa becomes V_{LM} and the potential of the wiring BLb becomes V_{HM}. In the case where “1” is retained in the memory cell MC, the potential of the wiring BLa becomes V_{HM} and the potential of the wiring BLb becomes V_{LM}.

Next, to operate the circuit ILP, the high-level potential is supplied to the wiring IVL. Thus, the high-level potential is supplied to each of the control terminal of the switch SWVa and a control terminal of the switch SWVb, so that the switch SWVa and the switch SWVb are turned on.

At this time, the potentials of the wiring BLa and the wiring BLb are increased or decreased to a predetermined potential by the inverter loop of the inverter IVa and the inverter IVb included in the circuit ILP. Specifically, when the potential of the wiring BLa is V_{LM} and the potential of the wiring BLb is V_{HM}, the potential of the wiring BLa decreases to the low-level potential and the potential of the wiring BLb increases to the high-level potential. When the potential of the wiring BLa is V_{HM} and the potential of the wiring BLb is V_{LM}, the potential of the wiring BLa increases to the high-level potential and the potential of the wiring BLb decreases to the low-level potential.

In other words, in the case where “0” is retained in the memory cell MC, the potential of the wiring BLa becomes the low-level potential and the potential of the wiring BLb becomes the high-level potential. In the case where “1” is retained in the memory cell MC, the potential of the wiring BLa becomes the high-level potential and the potential of the wiring BLb becomes the low-level potential.

After that, the high-level potential is supplied to the wiring SWL, and the high-level potential is supplied to each of the control terminals of the switch SWOa and the switch SWOb. This turns on the switch SWOa and the switch SWOb, establishing electrical continuity between the wiring BLa and the wiring OLa and electrical continuity between the wiring BLb and the wiring OLb; accordingly, the potentials of the wiring BLa and the wiring BLb are output to the wiring OLa and the wiring OLb, respectively.

For example, in the case where “0” is retained in the memory cell MC, the low-level potential is output to the wiring OLa and the high-level potential is output to the wiring BLb. In the case where “1” is retained in the memory cell MC, the high-level potential is output as the potential of the wiring BLa, and the low-level potential is output as the potential of the wiring BLb.

By the above operation method, the writing operation and the reading operation can be performed in the memory device in FIG. 36 and FIG. 37A. Note that the operation method of the memory device of one embodiment of the present invention is not limited thereto, and can be modified as appropriate. For example, complementary data can be input to the wiring BLa and the wiring BLb before the supply of the high-level potential to the wiring WL in the writing operation in FIG. 37B.

Note that this embodiment can be combined with the same embodiment or any of the other embodiments in this specification as appropriate. For example, the configurations, structures, methods, and the like described in this embodiment can be used in an appropriate combination with any of the other configurations, the other structures, the other methods, and the like described in the same embodiment. For another example, the configurations, structures, methods, and the like described in this embodiment can be used in an appropriate combination with any of the configurations, structures, methods, and the like described in the other embodiments and the like.

### Embodiment 4

An arithmetic device and a processing device that can include the semiconductor device or the memory device described in the above embodiment are described in this embodiment.

### Arithmetic Device

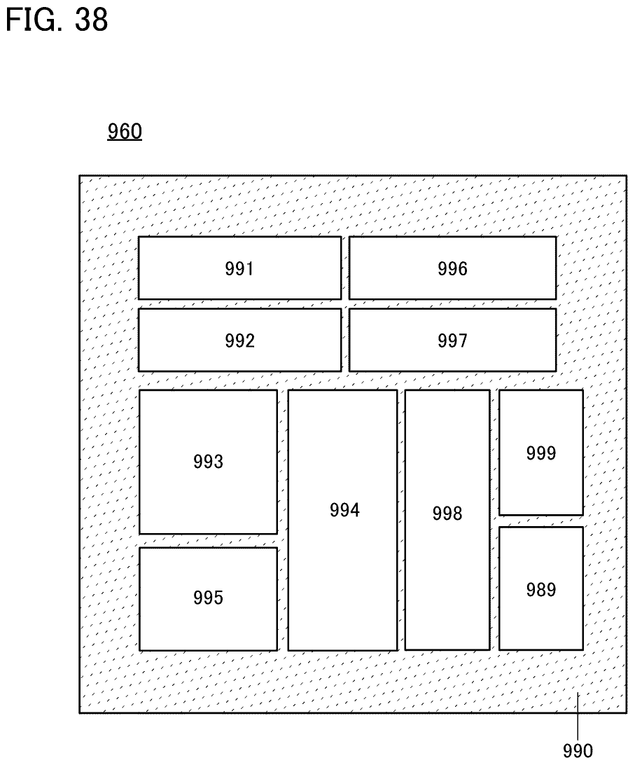

FIG. 38 illustrates a block diagram of an arithmetic device 960. The arithmetic device 960 illustrated in FIG. 38 can be used for a CPU, for example. The arithmetic device 960 can also be used for a processor including a larger number of (several tens to several hundreds of) processor cores capable of parallel processing than a CPU, such as a GPU (Graphics Processing Unit), a TPU (Tensor Processing Unit), or an NPU(Neural Processing Unit).

The arithmetic device 960 illustrated in FIG. 38 includes, over a substrate 990, an ALU 991 (Arithmetic logic unit, an arithmetic logic device), an ALU controller 992, an instruction decoder 993, an interrupt controller 994, a timing controller 995, a register 996, a register controller 997, a bus interface 998), a cache 999, and a cache interface 989. A semiconductor substrate, an SOI substrate, a glass substrate, or the like is used as the substrate 990. The arithmetic device 960 can also include a rewritable ROM and a ROM interface. The cache 999 and the cache interface 989 can be provided in a separate chip.

The cache 999 is connected via the cache interface 989 to a main memory provided in another chip. The cache interface 989 has a function of supplying part of data retained in the main memory to the cache 999. The cache interface 989 also has a function of outputting part of data retained in the cache 999 to the ALU 991, the register 996, or the like through the bus interface 998.

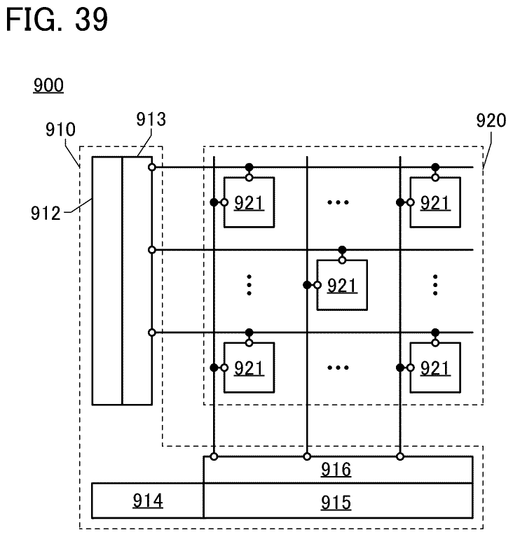

As detailed later, the memory cell array 920 illustrated in FIG. 39 can be stacked over the arithmetic device 960. FIG. 39 illustrates a structure example of a memory circuit 900, which includes memory cells having a function of a cache and includes, in addition to the memory cell array 920, a driver circuit 910 that drives the memory cell array 920.

A plurality of memory cells 921, for example, are arranged in a matrix in the memory cell array 920. The structure of the memory cell 921 can be determined as appropriate, for example, depending on the level of the cache. An SRAM (Static Random Access Memory), which is a kind of volatile memory, can be used as the memory cell 921 in the case where high-speed writing and reading are needed (the cache is at a relatively higher level), for example.

The driver circuit 910 includes, for example, a row decoder 912, a row driver 913, a column decoder 914, a column driver 915, and a sense amplifier 916, like the memory circuit MDV0 described in Embodiment 3. The driver circuit 910 can further include a PSW, a control circuit, a voltage generation circuit, an input circuit, an output circuit, and the like, like the memory circuit MDV0 described in Embodiment 3.

The memory cell array 920 illustrated in FIG. 39 can be used as a cache. Here, the cache interface 989 can have a function of supplying data retained in the memory cell array 920 to the cache 999. Moreover, in this case, the driver circuit 910 is preferably included in part of the cache interface 989.

Note that it is also possible that the cache 999 is not provided and only the memory cell array 920 is used as a cache.

The arithmetic processing device 960 illustrated in FIG. 38 is only an example with a simplified structure, and the actual arithmetic processing device 960 has a variety of structures depending on the application. For example, what is called a multicore structure is preferably employed in which a plurality of cores each including the arithmetic device 960 in FIG. 38 operate in parallel. The larger number of cores can further enhance the arithmetic performance. The number of cores is preferably larger; for example, the number is preferably 2, further preferably 4, still further preferably 8, yet still further preferably 12, yet still further preferably 16 or larger. For application requiring extremely high arithmetic performance, e.g., a server, it is preferable to employ the multicore structure including 16 or more, preferably 32 or more, further preferably 64 or more cores. The number of bits that the arithmetic device 960 can process in an internal arithmetic circuit or in a data bus can be 8, 16, 32, 64, or 128, for example.

An instruction that is input to the arithmetic device 960 through the bus interface 998 is input to the instruction decoder 993 and decoded therein, and then, input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. While the arithmetic device 960 is executing a program, the interrupt controller 994 judges an interrupt request from an external input/output device, a peripheral circuit, or the like on the basis of its priority or a mask state, and processes the request. The register controller 997 generates an address of the register 996, and reads or writes data from/to the register 996 in accordance with the state of the arithmetic device 960.

The timing controller 995 generates signals controlling operation timings of the ALU 991, the ALU controller 992, the instruction decoder 993, the interrupt controller 994, and the register controller 997. For example, the timing controller 995 includes an internal clock generator generating an internal clock signal on the basis of a reference clock signal, and supplies the internal clock signal to the above various circuits.

In the arithmetic device 960 illustrated in FIG. 38, the register controller 997 selects a retention operation in the register 996 in accordance with an instruction from the ALU 991. That is, the arithmetic device 960 selects whether data is stored by a flip-flop or by a capacitor in the memory cell included in the register 996. When data storing by the flip-flop is selected, a power supply voltage is supplied to the memory cell in the register 996. When data retention by the capacitor is selected, the data is rewritten into the capacitor, and supply of power supply voltage to the memory cell in the register 996 can be stopped.

### Arithmetic Device

Next, a processing device in which an arithmetic device and a memory cell array overlap with each other is described.

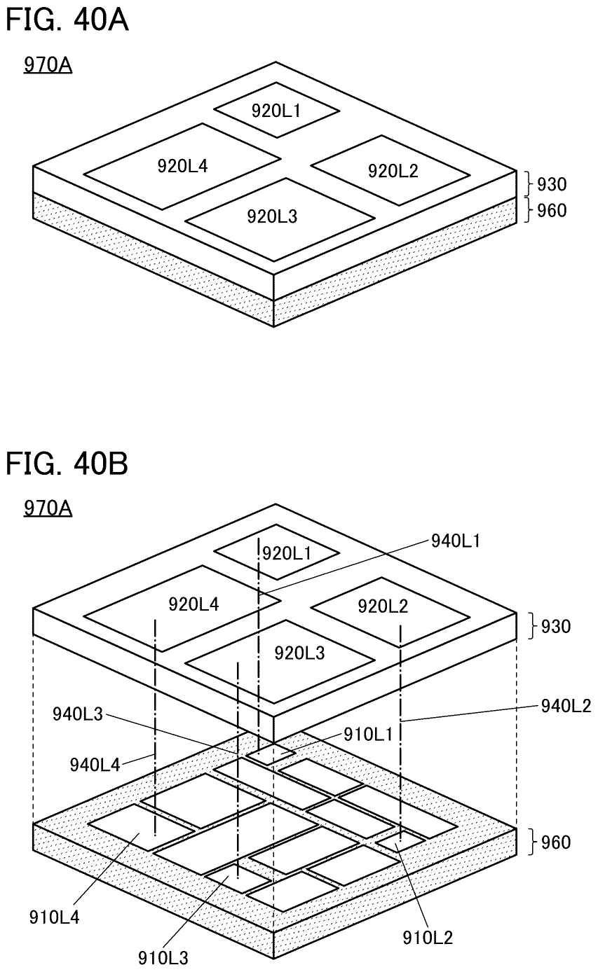

The above memory cell array 920 and the arithmetic device 960 can be provided to overlap with each other. FIG. 40A and FIG. 40B are perspective views of a processing device 970A. The processing device 970A includes a layer 930, in which the memory cell arrays 920 (a memory cell array 920L1 to a memory cell array 920L4) are provided over the arithmetic device 960. The memory cell array 920L1, the memory cell array 920L2, the memory cell array 920L3, and the memory cell array 920L4 are provided in the layer 930. The arithmetic device 960 and each of the memory cell arrays 920 include a region where they overlap with each other. For easy understanding of the structure of the processing device 970A, the arithmetic device 960 and the layer 930 are separated from each other in FIG. 40B.

Providing the layer 930 including the memory arrays 920 and the arithmetic device 960 to overlap with each other can shorten the connection distance therebetween. Accordingly, the communication speed therebetween can be increased. Moreover, since the connection distance is short, power consumption can be reduced.

As a method for stacking the layer 930 including the memory arrays 920 and the arithmetic device 960, a method in which the layer 930 including the memory arrays 920 is stacked directly on the arithmetic device 960 (also referred to as monolithic stacking) is preferably employed, or a method in which the arithmetic device 960 and the layer 930 are formed over different substrates, the two substrates are bonded to each other, and the arithmetic device 960 and the layer 930 are connected to each other with a through via or by a technique for bonding conductive films (e.g., Cu-Cu bonding) is further preferably employed. The former method does not require consideration of misalignment in bonding; thus, not only the chip size but also the manufacturing cost can be reduced.

Here, it is possible that the arithmetic device 960 does not include the cache 999 and the memory cell array 920L1, the memory cell array 920L2, the memory cell array 920L3, and the memory cell array 920L4 provided in the layer 930 are each used as a cache. In this case, for example, the memory cell array 920L1, the memory cell array 920L2, the memory cell array 920L3, and the memory cell array 920L4 can be used as an L1 cache (also referred to as a level 1 cache), an L2 cache (also referred to as a level 2 cache), an L3 cache (also referred to as a level 3 cache), and an L4 cache (also referred to as a level 3 cache), respectively. Among the four memory cell arrays, the memory cell array 920L4 has the highest capacity and the lowest access frequency. The memory array 920L1 has the lowest capacity and the highest access frequency.

Note that in the case where the cache 999 provided in the arithmetic device 960 is used as the L1 cache, the memory cell arrays 920 provided in the layer 930 can each be used as the lower-level cache or the main memory. The main memory has higher capacity and lower access frequency than the cache.

As illustrated in FIG. 40B, in the arithmetic device 960, a driver circuit 910L1, a driver circuit 910L2, a driver circuit 910L3, and a driver circuit 910L4 that correspond to the driver circuit 910 in FIG. 39 are provided. The driver circuit 910L1 is connected to the memory cell array 920L1 through a connection electrode 940L1. Similarly, the driver circuit 910L2 is connected to the memory cell array 920L2 through a connection electrode 940L2, the driver circuit 910L3 is connected to the memory cell array 920L3 through a connection electrode 940L3, and the driver circuit 910L4 is connected to the memory cell array 920L4 through a connection electrode 940L4.

Although the four memory cell arrays 920 functioning as a cache are described here, the number of memory cell arrays 920 can be one, two, or three or can be five or more.

In the case where the memory cell array 920L1 is used as a cache, the driver circuit 910L1 can have a function of part of the cache interface 989 or the driver circuit 910L1 can be connected to the cache interface 989. Similarly, the driver circuit 910L2, the driver circuit 910L3, and the driver circuit 910L4 can each function as part of the cache interface 989 or be connected to the cache interface 989.

Whether the memory cell arrays 920 (the memory cell array 920L1 to the memory cell array 920L4) function as a cache or function as a main memory is determined by a control circuit included in each of driver circuits 910 (the driver circuit 910L1 to the driver circuit 910L4). For example, the control circuit can make some of the plurality of memory cells 921 function as RAM in accordance with a signal supplied from the arithmetic device 960.

At this time, in the memory circuit 900, some of the memory cells 921 can function as the cache and the other memory cells 921 can function as the main memory. That is, the memory circuit 900 can have both the function of the cache and the function of the main memory. The memory circuit 900 can function as a universal memory, for example.

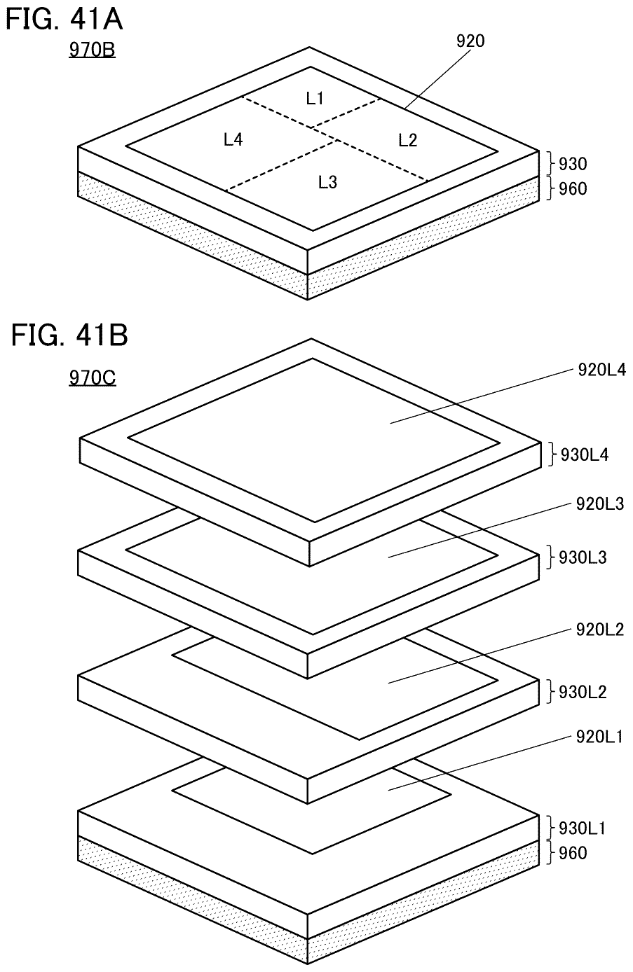

The layer 930 including one memory cell array 920 can be provided to overlap with the arithmetic device 960. FIG. 41A is a perspective view of a processing device 970B having the structure.

In the processing device 970B, one memory cell array 920 can be divided into a plurality of areas having different functions. FIG. 41A illustrates an example in which a region L1, a region L2, a region L3, and a region L3 are used as the L1 cache, the L2 cache, the L3 cache, and the L3 cache, respectively.

In the processing device 970B, the memory capacity of each of the region L1 to the region L4 can be changed depending on circumstances. For example, the memory capacity of the L1 cache can be increased by increasing the area of the region L1. With such a structure, the arithmetic processing efficiency can be improved and the processing speed can be improved.

Furthermore, a plurality of memory cell arrays can be stacked. FIG. 41B is a perspective view of a processing device 970C having the structure.

In the processing device 970C, a layer 930L1 including the memory cell array 920L1, a layer 930L2 including the memory cell array 920L2 over the layer 930L1, a layer 930L3 including the memory cell array 920L3 over the layer 930L2, and a layer 930L4 including the memory cell array 920L4 over the layer 930L3 are stacked. The memory cell array 920L1 physically closest to the arithmetic device 960 can be used as a high-level cache, and the memory cell array 920L3 physically farthest from the arithmetic device 960 can be used as a low-level cache or a main memory. Such a structure can increase the capacity of each memory cell array, leading to higher processing capability.

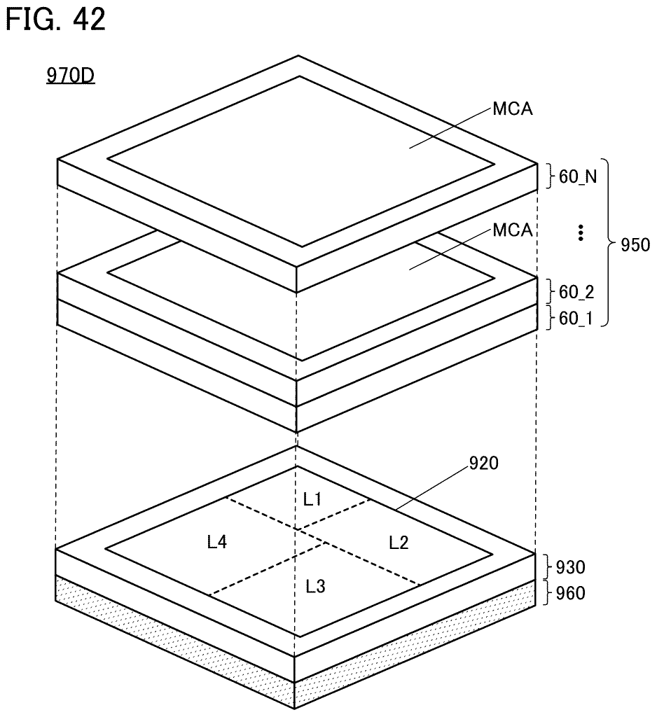

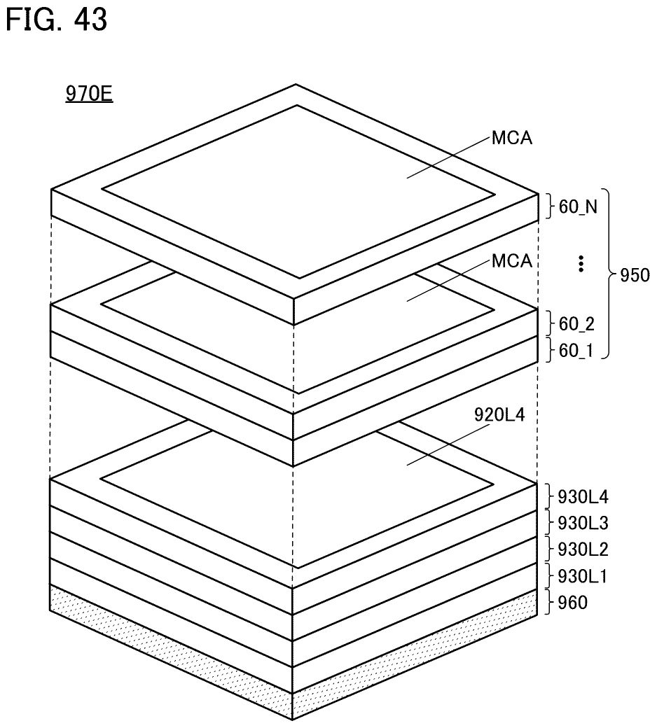

The main memory can be stacked above the memory cell array 920L1 to the memory cell array 920L4 used as the cache. A processing device 970D and a processing device 970E each having such a structure are illustrated in perspective views of FIG. 42 and FIG. 43, respectively.

In the processing device 970D, a layer 950 functioning as the main memory is stacked over the layer 930 of the processing device 970B illustrated in FIG. 41A. Note that FIG. 42 illustrates an example in which the layer 950 has a structure in which the plurality of memory layers 60 described in Embodiment 3 are stacked. In other words, the memory cell arrays MCA of the memory device (DRAM) described in Embodiment 3 can be stacked above the layer 930 including the memory cell array 920L1 to the memory cell array 920L4 used as the caches. With such a structure, the main memory can be provided in the arithmetic device; thus, the communication speed between the arithmetic circuit and the main memory can be increased, resulting in higher processing speed. Moreover, since the connection distance is short, power consumption can be reduced.

In the processing device 970E, the layer 950 functioning as the main memory is stacked over the layer 930L4 in the processing device 970C illustrated in FIG. 41B. In other words, the memory cell array MCA of the memory device (DRAM) described in Embodiment 3 can be stacked above the memory cell array 920L1 to the memory cell array 920L4 used as the caches. With such a structure, the main memory can be provided in the arithmetic device as in the processing device 970D; thus, the communication speed between the arithmetic circuit and the main memory can be increased, resulting in higher processing speed. Moreover, since the connection distance is short, power consumption can be reduced.

<<Memory Cell>>Next, structure examples of a memory cell that can be used as the memory cell 921 in the memory circuit 900, that is, a memory cell that can be used as a cache, are described.

### [DOSRAM]

As the memory cell 921, the memory cell 10 illustrated in FIG. 35, which has the structure of a DRAM (a DOSRAM particularly when the transistor M1 is an OS transistor), can be used, for example. Note that in the case where the memory cell 10 is used as the memory cell 921, the memory circuit 900 is preferably treated as a lower-level cache, for example.

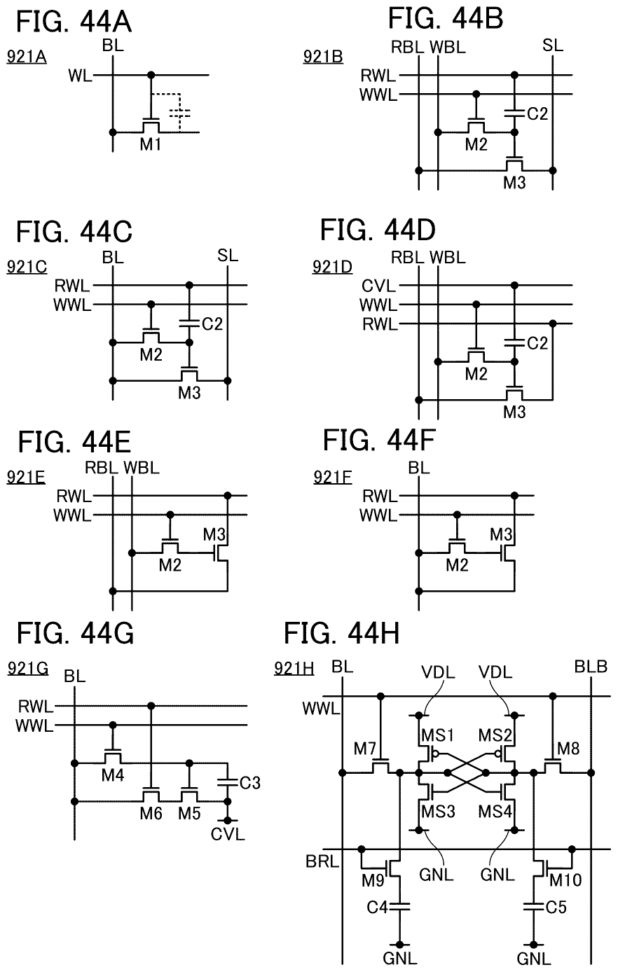

The structure of the memory cell 10 used as the memory cell 921 can be modified to the structure of a memory cell 921A illustrated in FIG. 44A, for example. The memory cell 921A is an example including neither the capacitor C1 nor the wiring CVL. The first terminal of the transistor M1 is in an electrically floating state.

In the memory cell 921A, a potential written through the transistor MI is retained in a capacitor (also referred to as parasitic capacitance) indicated by a dashed line, between the first terminal and the gate. Such a structure can greatly simplify the structure of the memory cell ..

### [NOSRAM]

FIG. 44B illustrates a circuit structure example of a gain-cell memory cell including two transistors and one capacitor. A memory cell 921B includes a transistor M2, a transistor M3, and a capacitor C2. In this specification and the like, a memory device including a gain-cell memory cell using an OS transistor as the transistor M2 is referred to as NOSRAM (registered trademark) (Nonvolatile Oxide Semiconductor RAM).

A first terminal of the transistor M2 is electrically connected to a first terminal of the capacitor C2, a second terminal of the transistor M2 is electrically connected to a wiring WBL, and a gate of the transistor M2 is electrically connected to a wiring WWL. The second terminal of the capacitor C2 is electrically connected to a wiring RWL. A first terminal of the transistor M3 is electrically connected to a wiring RBL, a second terminal of the transistor M3 is electrically connected to a wiring SL, and a gate of the transistor M3 is electrically connected to the first terminal of the capacitor C2.

The wiring WBL functions as a write bit line, the wiring RBL functions as a read bit line, and the wiring WWL and the wiring RWL each have a function of a word line. A high-level potential is preferably applied to the wiring RWL particularly at the time of data writing and data reading.

Data writing is performed in such a manner that a high-level potential is applied to the wiring WWL to turn on the transistor M2, so that electrical continuity is established between the wiring WBL and the first terminal of the capacitor C2. Specifically, when the transistor M2 is in an on state, a potential corresponding to data to be stored is applied to the wiring WBL, and the potential is written to the first terminal of the capacitor C2 and the gate of the transistor M3. Then, a low-level potential is applied to the wiring WWL to turn off the transistor M2, whereby the potential is retained in the first terminal of the capacitor C2 and the gate of the transistor M3.

Data reading is performed by applying a predetermined potential to the wiring SL. Current flowing between a source and a drain of the transistor M3 and the potential of the first terminal of the transistor M3 are determined by the potential of the gate of the transistor M3 and the potential of the second terminal of the transistor M3. Thus, by reading the potential of the wiring RBL connected to the first terminal of the transistor M3, the potential retained in the first terminal of the capacitor C2 (or the gate of the transistor M3) can be read. That is, data written to the memory cell 921B can be read on the basis of the potential retained in the first terminal of the capacitor C2 (or the gate of the transistor M3).

As a memory cell that can be used as the memory cell 921, for example, the memory cell 921B can have a structure in which the wiring WBL and the wiring RBL can be combined into one wiring BL. A circuit structure example of the memory cell is illustrated in FIG. 44C. In a memory cell 921C, one wiring BL serves as the wiring WBL and the wiring RBL of the memory cell 921B, and thus the second terminal of the transistor M2 and the first terminal of the transistor M3 are connected to the wiring BL. That is, in the memory cell 921C, one wiring BL operates as the write bit line and the read bit line.

A memory cell 921D illustrated in FIG. 44D is a modification example of the memory cell 921B and is different from the memory cell 921B in that the second terminal of the capacitor C2 is electrically connected not to the wiring RWL but to the wiring CVL and that the second terminal of the transistor M3 is electrically connected not to the wiring SL but to the wiring RWL.

The memory cell 921D has a structure in which a potential is supplied to the second terminal of the transistor M3 through the wiring RWL extending in the column direction. In this case, the wiring RWL has a function of a read word line, as in the memory cell 921B and the memory cell 921C.

The wiring CVL has a function of a wiring supplying a fixed potential, for example. Examples of the fixed potential are a low-level potential, a ground potential, and a negative potential. Note that depending on circumstances, the wiring CVL can have a function of a wiring supplying a variable potential (e.g., a pulse signal or a pulse potential).

In the memory cell 921D, data writing is performed in such a manner that a high-level potential is applied to the wiring WWL to turn on the transistor M2, so that electrical continuity is established between the wiring WBL and the first terminal of the capacitor C2. Specifically, when the transistor M2 is in an on state, a potential corresponding to data recorded in the wiring WBL is applied, whereby the potential is written to the first terminal of the capacitor C2 and the gate of the transistor M3. Then, a low-level potential is applied to the wiring WWL to turn off the transistor M2, whereby the potential of the first terminal of the capacitor C2 and the potential of the gate of the transistor M3 are retained. At this time, the wiring CVL supplies a fixed potential such as a low-level potential, a ground potential, or a negative potential to the second terminal of the capacitor C2. In addition, the wiring RBL and the wiring RWL are preferably supplied with the same potential, and for example, preferably supplied with a fixed potential such as a low-level potential or a ground potential.

Data reading is performed in such a manner that the wiring RBL is brought into a floating state and a predetermined potential is applied to the wiring RWL, for example. A current flowing between a source and a drain of the transistor M3 and the potential of the first terminal of the transistor M3 are determined by the potential of the gate of the transistor M3 and the potential of the second terminal of the transistor M3. Thus, by reading the potential of the wiring RBL connected to the first terminal of the transistor M3, the potential retained in the first terminal of the capacitor C2 (or the gate of the transistor M3) can be read. In other words, data written to the memory cell 921B can be read by using the potential retained at the first terminal of the capacitor C2 (or the gate of the transistor M3).

In the memory cell array including the memory cell 921D, random access can be performed owing to the wiring that is electrically connected to the second terminal of the transistor M3 and extends in the column direction (the wiring RWL in the memory cell 921D in FIG. 44D).

A memory cell 921E illustrated in FIG. 44E is an example where the capacitor C2 and the wiring CVL in the memory cell 921D are eliminated. A memory cell 921F illustrated in FIG. 44F is an example where the wiring WBL and the wiring RBL in the memory cell 921E are combined into one wiring BL. Such structures can increase the integration degree of the memory cells. Like the memory cell 921D, the memory cell 921E and the memory cell 921F each enable random access.

Note that also in each of the memory cell 921B to the memory cell 921F, an OS transistor is preferably used at least as the transistor M2. It is particularly preferable to use OS transistors as the transistor M2 and the transistor M3.

Since the OS transistor has a characteristic of an extremely low off-state current, written data can be retained for a long time with the use of the transistor M2, and thus the frequency of refresh for the memory cell can be decreased. Alternatively, refresh operation for the memory cell can be unnecessary. Furthermore, extremely low leakage current enables multi-level data or analog data to be retained in the memory cell 10 described in Embodiment 3 and the memory cell 921A to the memory cell 921F.

The memory cell 921B to the memory cell 921F each using the OS transistor as the transistor M2 are embodiments of a NOSRAM.

In each of the memory cell 921B to the memory cell 921F, a Si transistor can be used as the transistor M3. The Si transistor can have high field-effect mobility and can be formed as a p-channel transistor, so that circuit design flexibility can be increased.

In the case where the memory cell 921B to the memory cell 921F each employ the OS transistors as the transistor M3, the memory cells can each be composed of a single-polarity circuit (a circuit composed of transistors having the same polarity, i.e., a circuit composed of n-channel transistors without using a p-channel transistor or a circuit composed of p-channel transistors without using an n-channel transistor).

FIG. 44G illustrates a gain-cell memory cell 921G including three transistors and one capacitor. The memory cell 921G includes a transistor M4 to a transistor M6 and a capacitor C3.

A first terminal of the transistor M4 is electrically connected to a first terminal of the capacitor C3, a second terminal of the transistor M4 is electrically connected to the wiring BL, and a gate of the transistor M4 is electrically connected to the wiring WWL. A second terminal of the capacitor C3 is electrically connected to a first terminal of a transistor M5 and a wiring GNL. A second terminal of the transistor M5 is electrically connected to a first terminal of the transistor M6 and a gate of the transistor M5 is electrically connected to the first terminal of the capacitor C3. A second terminal of the transistor M6 is electrically connected to the wiring BL, and a gate of the transistor M6 is electrically connected to the wiring RWL.

The wiring BL has a function of a bit line, the wiring WWL has a function of a write word line, and the wiring RWL has a function of a read word line. The wiring CVL has a function of a wiring supplying a fixed potential. The fixed potential can be, for example, a low-level potential or the ground potential.

Data writing is performed in such a manner that a high-level potential is applied to the wiring WWL to turn on the transistor M4, so that electrical continuity is established between the wiring BL and the first terminal of the capacitor C3. Specifically, when the transistor M4 is in an on state, a potential corresponding to data to be stored is applied to the wiring BL, and the potential is written to the first terminal of the capacitor C3 and the gate of the transistor M5. Then, a low-level potential is applied to the wiring WWL to turn off the transistor M4, whereby the potential is retained in the first terminal of the capacitor C3 and the gate of the transistor M5.

Data reading is performed by precharging the wiring BL with a predetermined potential, and then making the wiring BL in a floating state and applying a high-level potential to the wiring RWL. Since the wiring RWL has the high-level potential, the transistor M6 is turned on, so that electrical continuity is established between the wiring BL and the second terminal of the transistor M5. At this time, the potential of the wiring BL is applied to the second terminal of the transistor M5; the potential of the second terminal of the transistor M5 and the potential of the wiring BL change depending on the potential retained in the first terminal of the capacitor C3 (or the gate of the transistor M5). In this situation, by reading the potential of the wiring BL, the potential held at the first terminal of the capacitor C3 (or the gate of the transistor M5) can be read. In other words, data written to the memory cell 921G can be read on the basis of the potential retained in the first terminal of the capacitor C3 (or the gate of the transistor M5).

Note that also in the memory cell 921G, an OS transistor is preferably used at least as the transistor M4.

In the memory cell 921G, Si transistors can be used as the transistor M5 and the transistor M6. As described above, a Si transistor may have higher field-effect mobility than an OS transistor depending on the crystal state of silicon used in a semiconductor layer, for example.

In the case where OS transistors are used as the transistor M5 and the transistor M6, the memory cell can be composed of a single-polarity circuit.

### [OS-SRAM]

FIG. 44H illustrates an example of an SRAM using an OS transistor. In this specification and the like, an SRAM using an OS transistor is referred to as an OS-SRAM (Oxide Semiconductor-SRAM). Note that a memory cell 921H illustrated in FIG. 44H is a memory cell of an SRAM capable of backup.

The memory cell 921H includes a transistor M7 to a transistor M10, a transistor MS1 to a transistor MS4, a capacitor C4, and a capacitor C5. Note that the transistor MS1 and a transistor MS2 are p-channel transistors, and a transistor MS3 and the transistor MS4 are n-channel transistors.

A first terminal of the transistor M7 is electrically connected to the wiring BL, and a second terminal of the transistor M7 is electrically connected to a first terminal of the transistor MS1, a first terminal of the transistor MS3, a gate of the transistor MS2, a gate of the transistor MS4, and a first terminal of a transistor M9. A gate of the transistor M7 is electrically connected to the wiring WWL. A first terminal of a transistor M8 is electrically connected to a wiring BLB, and a second terminal of the transistor M8 is electrically connected to a first terminal of the transistor MS2, a first terminal of the transistor MS4, a gate of the transistor MS1, a gate of the transistor MS3, and a first terminal of the transistor M10. A gate of the transistor M8 is electrically connected to the wiring WWL.

A second terminal of the transistor MS1 is electrically connected to a wiring VDL. A second terminal of the transistor MS2 is electrically connected to the wiring VDL. A second terminal of the transistor MS3 is electrically connected to the wiring GNL. A second terminal of the transistor MS4 is electrically connected to the wiring GNL.

A second terminal of the transistor M9 is electrically connected to a first terminal of the capacitor C4. A gate of the transistor M9 is connected to a wiring BRL. A second terminal of the transistor M10 is electrically connected to a first terminal of the capacitor C5, and a gate of the transistor M10 is electrically connected to the wiring BRL.

A second terminal of the capacitor C4 is electrically connected to the wiring GNL, and a second terminal of the capacitor C5 is electrically connected to the wiring GNL.

The wiring BL and the wiring BLB each have a function of a bit line, the wiring WWL has a function of a word line, and the wiring BRL has a function of a wiring that controls switching between the on state and the off state of each of the transistor M9 and the transistor M10.

The wiring VDL has a function of a wiring that supplies a high-level potential as the fixed potential, and the wiring GNL has a function of a wiring that supplies a low-level potential as the fixed potential.

Data writing is performed by applying a high-level potential to the wiring WWL and applying a high-level potential to the wiring BRL. Specifically, when the transistor M9 is in an on state, a potential corresponding to data to be stored is applied to the wiring BL, whereby the potential is written to the second terminal side of the transistor M9.

In the memory cell 921H, the transistor MS1 to the transistor MS4 form an inverter loop; thus, an inverted signal of a data signal corresponding to the potential is input to the second terminal side of the transistor M8. Since the transistor M8 is in an on state, an inverted signal of a signal input to the wiring BL is output to the wiring BLB. I addition, since the transistor M9 and the transistor M10 are in an on state, the potential of the second terminal of the transistor M7 and the potential of the second terminal of the transistor M8 are respectively retained in the first terminal of the capacitor C5 and the first terminal of the capacitor C4. Then, a low-level potential is applied to the wiring WWL and a low-level potential is applied to the wiring BRL to turn off the transistor M7 to the transistor M10, so that the potentials of the first terminal of the capacitor C4 and the first terminal of the capacitor C5 are retained.

Data reading is performed in such a manner that the wiring BL and the wiring BLB are precharged with a predetermined potential, and then a high-level potential is applied to the wiring WWL and the wiring BRL, whereby the potential of the first terminal of the capacitor C4 is refreshed by the inverter loop in the memory cell 921H and output to the wiring BL. Furthermore, the potential of the first terminal of the capacitor C5 is refreshed by the inverter loop in the memory cell 921H and output to the wiring BLB. Since the potentials of the wiring BL and the wiring BLB are changed from the precharged potentials to the potentials of the first terminal of the capacitor C5 and the first terminal of the capacitor C4, the potential retained in the memory cell can be read on the basis of the potentials of the wiring BL and the wiring BLB.

In the memory cell 921H, the transistor M7 to the transistor M10 are preferably OS transistors. In this case, with the use of the transistor M7 to the transistor M10, written data can be retained for a long time, and thus the frequency of refresh operation for the memory cell can be decreased. Alternatively, refresh operation for the memory cell can be omitted.

Note that in the memory cell 921H, Si transistors can be used as the transistor MS1 to the transistor MS4.

Note that this embodiment can be combined with the same embodiment or any of the other embodiments in this specification as appropriate. For example, the configurations, structures, methods, and the like described in this embodiment can be used in an appropriate combination with any of the other configurations, the other structures, the other methods, and the like described in the same embodiment. For another example, the configurations, structures, methods, and the like described in this embodiment can be used in an appropriate combination with any of the configurations, structures, methods, and the like described in the other embodiments and the like.

### Embodiment 5

In this embodiment, application examples of the memory device of one embodiment of the present invention will be described.

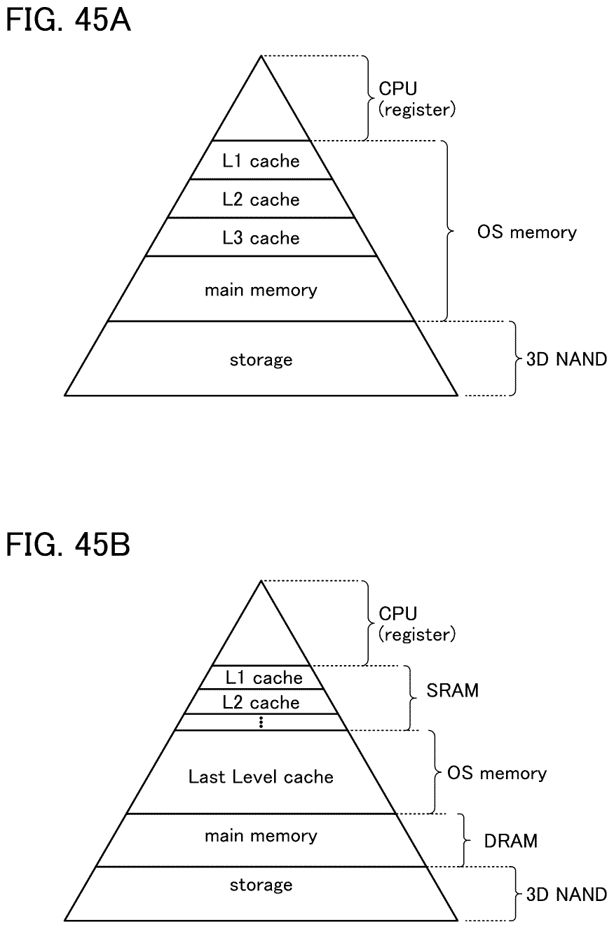

In general, a variety of memory devices are used in electronic computers or electronic devices such as computers in accordance with the intended use. FIG. 45A illustrates a hierarchy of various memory devices used in electronic computers or electronic devices. The memory devices at the upper levels require a higher operating speed, whereas the memory devices at the lower levels require larger memory capacity and higher recording density. FIG. 45A illustrates, for example, a memory included as a register in an arithmetic processing device such as a CPU, an L1 cache, an L2 cache, an L3 cache, a main memory, and a storage in this order from the uppermost layer. Although the caches up to the L3 cache are included in this example, a lower-level cache can further be included.

A memory included as a register in an arithmetic device such as a CPU is used for temporary storage of arithmetic operation results, for example, and thus is frequently accessed by the arithmetic device. Accordingly, high operation speed is required rather than memory capacity. In addition, the register also has a function of retaining settings information of the arithmetic device, for example.

The cache has a function of duplicating and retaining part of data held in a main memory. Duplicating frequently used data and holding the duplicated data in the cache facilitates rapid data access. The cache requires a smaller memory capacity than the main memory but a higher operating speed than the main memory. Data that is rewritten in the cache is duplicated, and the duplicated data is supplied to the main memory.

The main memory has a function of retaining a program, data, and the like that are read from the storage.

The storage has a function of retaining data that needs to be retained for a long time and programs used in an arithmetic device, for example. Therefore, a storage needs to have high memory capacity and high recording density rather than operating speed. For example, a high-capacity nonvolatile memory device such as a 3D NAND memory can be used.

The memory device including an oxide semiconductor (OS memory) of one embodiment of the present invention operates at high speed and can retain data for a long time. Thus, as illustrated in FIG. 45A, the memory device of one embodiment of the present invention can be favorably used at both the level including the cache and the level including the main memory. The memory device of one embodiment of the present invention can also be used at the level including the storage.

FIG. 45B illustrates an example in which an SRAM is used as at least one of the caches and the OS memory of one embodiment of the present invention is used as the other cache.

Among the caches, the lowest-level cache can be referred to as an LLC (Last Level cache). The LLC does not require a higher operating speed than a higher-level cache, but desirably has a large memory capacity. The OS memory of one embodiment of the present invention operates at high speed and can retain data for a long time, and thus can be suitably used as the LLC. Note that the OS memory of one embodiment of the present invention can also be used as an FLC (Final Level cache).

For example, as illustrated in FIG. 45B, an SRAM can be used as the higher-level caches (the L1 cache, the L2 cache, and the like), and the OS memory of one embodiment of the present invention can be used as the LLC. Moreover, in addition to the OS memory, a DRAM can also be used as the main memory as illustrated in FIG. 45B.

Note that this embodiment can be combined with the same embodiment or any of the other embodiments in this specification as appropriate. For example, the configurations, structures, methods, and the like described in this embodiment can be used in an appropriate combination with any of the other configurations, the other structures, the other methods, and the like described in the same embodiment. For another example, the configurations, structures, methods, and the like described in this embodiment can be used in an appropriate combination with any of the configurations, structures, methods, and the like described in the other embodiments and the like.

### Embodiment 6

In this embodiment, the processing device of one embodiment of the present invention will be described.

### Structural Example of Processing Device

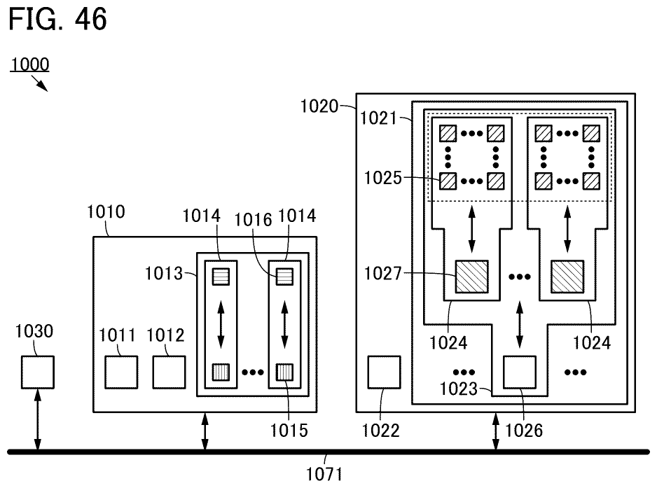

FIG. 46 is a block diagram illustrating a structure example of a processing device 1000 of one embodiment of the present invention.

At least part of the processing device 1000 can be used in an electronic computer (also referred to as a computer in some cases). Examples of the electronic computer include a microcomputer, a personal computer, a workstation, a mainframe, and a supercomputer.

As illustrated in FIG. 46, the processing device 1000 includes a processing portion 1010, a memory portion 1020 (also referred to as a memory in some cases), and a control portion 1030. The processing portion 1010, the memory portion 1020, and the control portion 1030 are electrically connected to each other through a bus line 1071.

Although not illustrated, an input/output portion (also referred to as an interface in some cases), for example, can be included in the processing device 1000. The input/output portion has a function of, for example, exchanging data or the like with a functional device (e.g., an input device, an output device, or a memory device) provided outside the processing device 1000.

The processing portion 1010 has a function of executing processes (tasks) corresponding to a program, for example. The processing portion 1010 has a function of executing a series of processes by sequentially executing processes according to a program, for example. In addition, the processing portion 1010 has a function of executing a plurality of tasks, for example. At least part of the processing portion 1010 can be used for a CPU, an MPU (Micro Processing Unit), a GPU, and the like, for example.

The processing portion 1010 includes an arithmetic portion 1011 (also referred to as a core in some cases), a control portion 1012, and a register portion 1013. The register portion 1013 includes one or more register units 1014.

The register unit 1014 includes a scan flip-flop 1015 and a backup memory 1016. At least part of the register unit 1014 can be used for a general-purpose register and a dedicated register (e.g., a program counter (PC), an instruction register (IR), or a status register (SR)), for example.

The arithmetic portion 1011 can include, for example, an arithmetic logic unit (ALU) and a floating point unit (FPU).

The control portion 1012 has a function of controlling the operation of the processing portion 1010. For example, the control portion 1012 has a function of controlling processing which is performed with switching between a plurality of tasks. The control portion 1012 can include an instruction decoder (ID), for example.

A specific structure example of the register unit 1014 will be described later.

The memory portion 1020 has a function of storing a program and data, for example. At least part of the memory portion 1020 can be used as a main memory, for example. The memory portion 1020 can be provided in the processing portion 1010. In this case, the memory portion 1020 can be used not only as a main memory but also as a cache memory in the processing portion 1010.

The memory portion 1020 includes a memory array portion 1021 and a control portion 1022.

The memory array portion 1021 includes one or more memory blocks 1023. The memory block 1023 includes one or more memory units 1024 and a sense amplifier 1026. The memory unit 1024 includes one or more of memory cells 1025 and a sub-sense amplifier 1027. Note that the memory unit 1024 can have a structure not provided with the sub-sense amplifier 1027 depending on the structure of the memory cell 1025.

Here, a group of a plurality of memory cells 1025 enclosed by the dotted line in FIG. 46 is referred to as a memory cell array in some cases.

The memory cell 1025 illustrated in FIG. 46 can employ the structure of a memory cell (a DRAM or a DOSRAM) including one transistor and one capacitor, for example. As the memory cell including one transistor and one capacitor, the memory cell MC or the memory cell MC1 to the memory cell MC3 described in Embodiment 1 can be used, for example. The memory cell MC4 described in Embodiment 2 can be used, for example. When the memory cell MC or the memory cell MC1 to the memory cell MC4 are used as the memory cell 1025, the memory portion 1020 can have increased recording density and a reduced circuit area.

In particular, in the case where the structure of the memory cell including one transistor and one capacitor (a DRAM or a DOSRAM) is employed for the memory cell 1025 illustrated in FIG. 46, the memory device MDV0 or the memory device MDV0A described in Embodiment 3 can be used for the memory portion 1020, for example.

Other than the above examples, the memory cell 921A to the memory cell 921H in FIG. 44A to FIG. 44H described in Embodiment 4, for example, can be used as the memory cell 1025 illustrated in FIG. 46.

The memory circuit 900 in FIG. 39 described in Embodiment 4, for example, can be used as at least part of the memory portion 1020. In this case, the memory cell array that is the group of memory cells 1025 corresponds to the memory cell array 920 included in the memory circuit 900 in FIG. 39. Thus, the memory cell array is capable of functioning as the cache memory or the main memory, as described above. In this case, for example, the memory cells 1025 included in the memory cell array 920 each have a function of retaining data related to the task processed in the processing portion 1010.

The control portion 1022 has a function of controlling the operation of the memory portion 1020. For example, the control portion 1022 has a function of controlling writing and reading of data to/from the memory array portion 1021. The control portion 1022 can include, for example, driver circuits such as the row driver 43, the row decoder 42, the column driver 45, and the column decoder 44 described in Embodiment 3.

A specific structure example of the memory block 1023 will be described later.

The control portion 1030 has a function of controlling the operation of the processing device 1000. The control portion 1030 can include a power management unit (PMU), for example. The PMU has a function of controlling a power gating operation, for example. For example, the PMU has a function of controlling power supply to each component included in the processing device 1000 by bringing a power switch (not illustrated) into a conduction state or a non-conduction state.

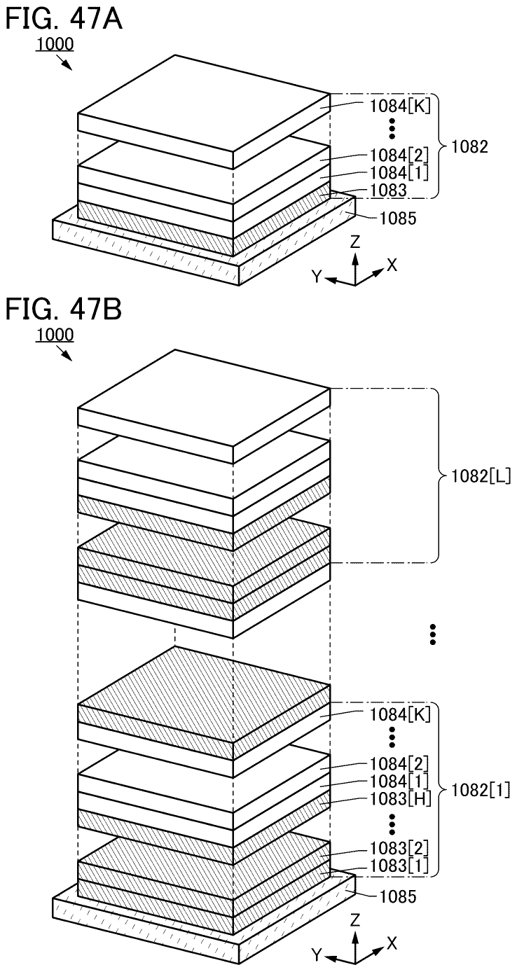

FIG. 47A and FIG. 47B are schematic diagrams each illustrating an example of a layer structure of the processing device 1000.

As illustrated in FIG. 47A, the processing device 1000 includes a layer 1085 and a layer 1082. The layer 1082 includes a layer 1083 and a plurality of layers 1084 (a layer 1084[1] to a layer 1084[K] (K is an integer greater than or equal to 2)). Note that a structure where the layer 1082 includes one layer 1084 can be employed.

The layer 1083 is stacked over the layer 1085. The layer 1084[1] to the layer 1084[K] are stacked over the layer 1083.

In the following description, the X direction, the Y direction, and the Z direction are defined for easy understanding of the positional relationship between components. The X direction, the Y direction, and the Z direction are perpendicular or substantially perpendicular to each other. Note that “substantially perpendicular” indicates a state where the angle formed by two targeted elements is greater than or equal to 85° s and less than or equal to 95°. The +Z direction is the direction in which the layer 1083 and the layer 1084[1] to the layer 1084[K] are stacked over the layer 1085. Thus, the X direction and the Y direction correspond to directions along the surfaces of the layer 1085, the layer 1083, and the layer 1084[1] to the layer 1084[K].

The layer 1085 can be provided in an insulating substrate or a semiconductor substrate containing any of a variety of materials.

In one embodiment of the present invention, a structure can be employed in which the layer 1085 is provided in a substrate containing silicon, for example. That is, a structure can be employed in which a Si transistor (a transistor containing silicon in a channel formation region) is provided in the layer 1085. Thus, in one embodiment of the present invention, a structure can be employed in which a gate of an n-channel Si transistor and a gate of a p-channel Si transistor are electrically connected to each other in the layer 1085, for example, to form a CMOS circuit (e.g., a circuit that operates complementarily, a CMOS logic gate, a CMOS logic circuit, or the like).

Each of the layer 1083 and the layer 1084[1] to the layer 1084[K] can contain any of a variety of materials such as a conductor, a semiconductor, and an insulator, for example. Any of a variety of elements such as a capacitor and a transistor can be provided in each of the layer 1083 and the layer 1084[1] to the layer 1084[K], for example.

Note that a semiconductor layer including a channel formation region of a transistor provided in the layer 1083 and semiconductor layers including channel formation regions of transistors provided in the layer 1084[1] to the layer 1084[K] can contain the same material or different materials. The transistor provided in the layer 1083 and the transistors provided in the layer 1084[1] to the layer 1084[K] can have the same structure or different structures.

In one embodiment of the present invention, a structure can be employed in which OS transistors (transistors each containing an oxide semiconductor in a channel formation region) are provided in the layer 1083 and the layer 1084[1] to the layer 1084[K].

The OS transistor has a feature of extremely low off-state current. In addition, the OS transistor has a feature in that the off-state current hardly increases and the on-state current is unlikely to decrease even in a high-temperature environment. Thus, for example, in the case where a wiring electrically connected to one of a source and a drain of the OS transistor is in a floating state (also referred to as floating in some cases), charges accumulated in the wiring can be retained for a long period. Accordingly, in one embodiment of the present invention, for example, a memory cell formed using the OS transistor can retain data written to the memory cell for a long period.

In one embodiment of the present invention, as the OS transistor, for example, a planar transistor can be provided in the layer 1083, and vertical transistors (transistors in which at least part of a semiconductor layer including a channel formation region is provided in an opening formed in an insulating layer and the channel length direction includes a component of the height direction) can be provided in the layer 1084[1] to the layer 1084[K].

A vertical transistor has a structure in which the occupied area (a footprint) can be easily smaller than that of a planar transistor. Furthermore, a vertical transistor has a structure in which the channel width is easily increased while the channel length is small; thus, a reduction in on-state resistance (an increase in on-state current) can be easily achieved. Thus, in one embodiment of the present invention, when a memory cell is formed using vertical transistors, for example, the cell area (cell size) of the memory cell can be reduced.

A planar transistor has a structure in which the channel length can be easily larger than that of a vertical transistor; thus, for example, a short-channel effect such as drain-induced barrier lowering (DIBL) can be easily reduced. That is, a transistor with the structure can easily have favorable saturation (the change in drain current with respect to drain voltage is small in a saturation region of the transistor). Thus, in one embodiment of the present invention, for example, a sense amplifier is formed using planar transistors, whereby the characteristics of the sense amplifier can be improved.

In the layer 1083, for example, a vertical transistor can be provided. In the layer 1084[1] to the layer 1084[K], for example, planar transistors can be provided.

Although not illustrated, a wiring layer can be provided as appropriate between the layer 1085, the layer 1083, and the layer 1084[1] to the layer 1084[K] in the processing device 1000. In the wiring layer, for example, a wiring for electrically connecting various elements can be provided.

As illustrated in FIG. 47B, the processing device 1000 can include a plurality of layers 1083 (a layer 1083[1] to a layer 1083[H] (H is an integer greater than or equal to 2)), and the layer 1083[1] to the layer 1083[H] can be stacked. The processing device 1000 can also include a plurality of layers 1082 (a layer 1082[1] to a layer 1082[L] (L is an integer greater than or equal to 2)), and the layer 1082[1] to the layer 1082[L] can be stacked.

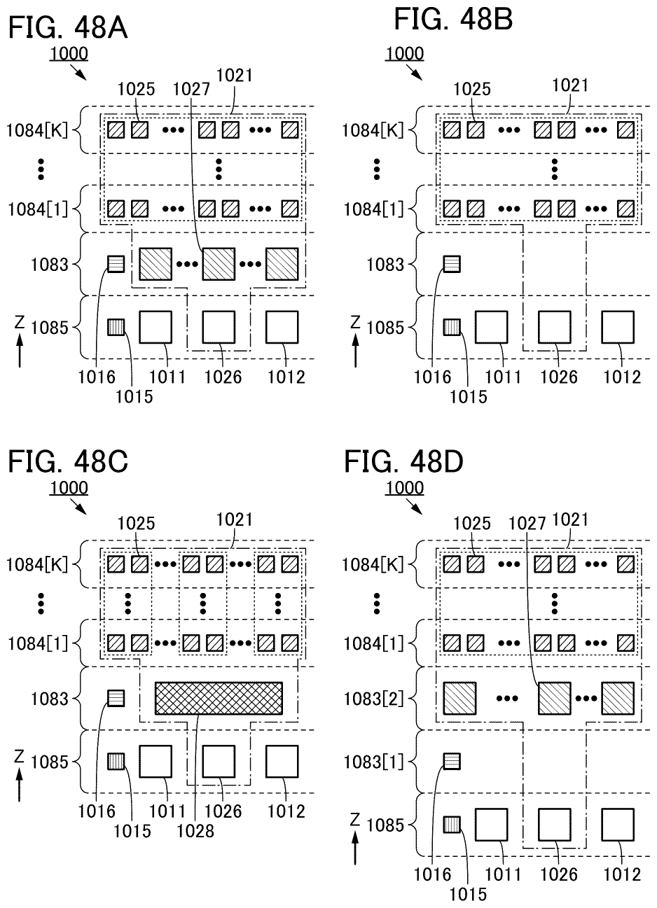

FIG. 48A to FIG. 48D are schematic diagrams each illustrating an example of arrangement of components included in the processing device 1000. In the processing device 1000, the components illustrated in FIG. 46 can be placed as appropriate in the layers illustrated in FIG. 47A, for example. Note that FIG. 48A to FIG. 48D each illustrate the arithmetic portion 1011, the control portion 1012, the scan flip-flop circuit 1015, and the backup memory 1016 included in the processing portion 1010, as some components included in the processing device 1000. In addition, the memory cell 1025, the sense amplifier 1026, and the sub-sense amplifier 1027 included in the memory portion 1020 are illustrated.

The processing device 1000 illustrated in FIG. 48A includes the layer 1085, the layer 1083, and the layer 1084[1] to the layer 1084[K]. As illustrated in FIG. 48A, the arithmetic portion 1011, the control portion 1012, the scan flip-flop circuit 1015, and the sense amplifier 1026 are placed in the layer 1085. Although not illustrated, the control portion 1030 and the control portion 1022 included in the memory portion 1020 are also placed in the layer 1085. Note that the sense amplifier 1026 can be placed between the arithmetic portion 1011 and the control portion 1012, for example. The backup memory 1016 is placed in the layer 1083 to overlap with the scan flip-flop circuit 1015. The sub-sense amplifier 1027 is placed in the layer 1083 so as to overlap with the sense amplifier 1026. Note that the sub-sense amplifier 1027 can be placed to overlap with the arithmetic portion 1011 and the control portion 1012, for example. The memory cells 1025 are placed in the layer 1084[1] to the layer 1084[K] to overlap with the sub-sense amplifier 1027. Note that the memory cells 1025 can also be placed to overlap with the arithmetic portion 1011 and the control portion 1012, for example. The memory cells 1025 can be placed to overlap with the backup memory 1016, for example.

In other words, the processing device 1000 illustrated in FIG. 48A has a structure in which the memory array portion 1021 included in the memory portion 1020 is placed in the processing portion 1010. Note that the control portion 1022 can also be placed in the processing portion 1010.

Such placement can reduce the space unused in the layer 1083 and the layer 1084[1] to the layer 1084[K], for example, to improve the area efficiency. Thus, the surface density (recording density) of the memory array portion 1021 can be increased. Accordingly, the memory capacity of the memory portion 1020 included in the processing device 1000 can be increased and the size of the processing device 1000 can be reduced. For example, the bus line 1071 between the processing portion 1010 and the memory portion 1020 can be shortened. Thus, the access time (time needed for data writing or data reading) and the access energy (energy consumed by data writing or data reading) can be reduced. As a result, the operation speed of the processing device 1000 can be improved and power consumption thereof can be reduced.

The processing device 1000 illustrated in FIG. 48B is a modification example of the processing device 1000 illustrated in FIG. 48A and differs from the processing device 1000 in not including the sub-sense amplifier 1027. As described above, the processing device 1000 does not necessarily include the sub-sense amplifier 1027 depending on the structure of the memory cell 1025.

The processing device 1000 illustrated in FIG. 48C is a modification example of the processing device 1000 illustrated in FIG. 48B and differs from the processing device 1000 in including a functional circuit 1028. The functional circuit 1028 is placed over the sense amplifier 1026 to overlap with the layer 1083. Note that the functional circuit 1028 can also be placed to overlap with the arithmetic portion 1011 and the control portion 1012, for example.

For example, when the memory array portion 1021 illustrated in FIG. 48C is divided into a plurality of memory cell arrays as shown in the area surrounded by dotted lines, the functional circuit 1028 can have a function of selecting one of the plurality of memory cell arrays. This enables the sense amplifier 1026 to write and read data to/from the memory cells 1025 included in the selected memory cell array. The sense amplifier 1026 and the control portion 1022 are thus shared among the plurality of memory cell arrays, for example, which leads to a reduction in the layout area of the layer 1085. Accordingly, the processing device 1000 can be downsized.

The processing device 1000 illustrated in FIG. 48D is a modification example of the processing device 1000 illustrated in FIG. 48A and differs in that the layer 1083 is not included and the layer 1083[1] and that the layer 1083[2] are included. The backup memory 1016 is placed in the layer 1083[1] to overlap with the scan flip-flop circuit 1015. The sub-sense amplifier 1027 is placed in the layer 1083[2] to overlap with the sense amplifier 1026. Note that the sub-sense amplifier 1027 can be placed to overlap with the arithmetic portion 1011, the control portion 1012, and the backup memory 1016, for example.

In the processing device 1000 illustrated in FIG. 48D, the parasitic capacitance between the sub-sense amplifier 1027 and each of the arithmetic portion 1011 and the control portion 1012 can be reduced, for example. Thus, for example, one operation can be less likely to cause noise and affect the other operation. Consequently, the reliability of the processing device 1000 can be improved.

Specific structure examples of the register that can be used for the register unit 1014 and the memory device that can be used for the memory block 1023 will be described below.

In the subsequent description, a potential corresponding to “1” of binary data is a high power supply potential VDD, and a potential corresponding to “0” of binary data is a low power supply potential VSS. The potential VDD is a potential higher than the potential VSS by at least the threshold voltage of the transistor. Note that the potential VSS can be a ground potential, for example. The potential of the signal is the potential H or the potential L. The potential H is a potential which, when being supplied to a gate of an n-channel transistor, makes the transistor in the conduction state and, when being supplied to a gate of a p-channel transistor, makes the transistor in the non-conduction state. The potential L is a potential which, when being supplied to a gate of an n-channel transistor, makes the transistor in the non-conduction state and, when being supplied to a gate of a p-channel transistor, makes the transistor in the conduction state. The potential H can be, for example, a potential equal to or higher than the potential VDD. The potential L can be, for example, a potential equal to or lower than the potential VSS.

Note that the potentials H are not necessarily the same among a plurality of signals and the potentials L are not necessarily the same among a plurality of signals. The plurality of signals may have different potentials H or potentials L in accordance with the threshold voltages of the transistors to which the signals are supplied. For example, the potential H and potential L of a signal supplied to a gate of a Si transistor provided in the layer 1085 may be different from those of a signal supplied to gates of OS transistors provided in the layer 1083 and the layer 1084[1] to the layer 1084[K].

### Register That Can Be Used for Processing Device 1010

A register 1110 of one embodiment of the present invention is described. At least part of the register 1110 can be used in the above-described processing device 1000 illustrated in FIG. 46 to FIG. 48D, for example. At least part of the register 1110 can be used for the register unit 1014 included in the processing portion 1010, for example.

### Structure Example

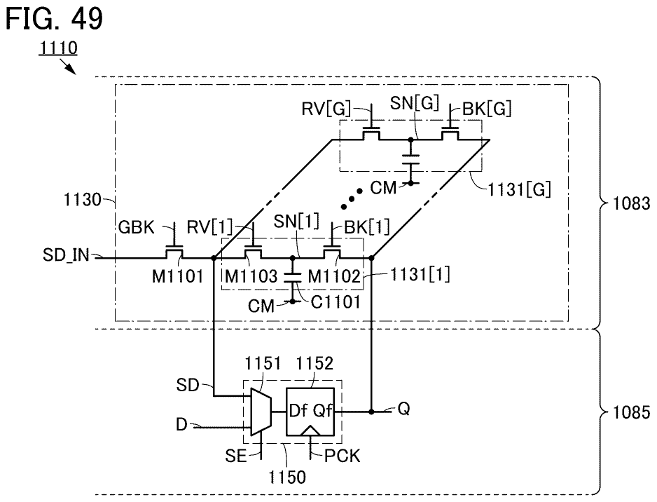

FIG. 49 is a circuit diagram illustrating a structure example of the register 1110.

The register 1110 illustrated in FIG. 49 includes a scan flip-flop circuit 1150 and a backup circuit 1130.

In the case where the register 1110 is used for the register unit 1014 included in the above-described processing device 1000 in one embodiment of the present invention, the scan flip-flop circuit 1150 corresponds to the scan flip-flop 1015, and the backup circuit 1130 corresponds to the backup memory 1016, for example. That is, for example, the scan flip-flop circuit 1150 is placed in the layer 1085, and the backup circuit 1130 is placed in the layer 1083. Thus, a Si transistor can be used in the scan flip-flop circuit 1150, and an OS transistor can be used in the backup circuit 1130, for example.

The scan flip-flop circuit 1150 includes a selector circuit 1151 and a flip-flop circuit 1152. The backup circuit 1130 includes a retention circuit 1131[1] to a retention circuit 1131[G] (G is an integer greater than or equal to 2) and a transistor M1101. The retention circuit 1131[1] to the retention circuit 1131[G] each include a transistor M1102, a transistor M1103, and a capacitor C1101.

A variety of signals for controlling the operation of the register 1110 are supplied to a wiring BK[1] to a wiring BK[G], a wiring RV[1] to a wiring RV[G], a wiring SE, a wiring PCK, and a wiring GBK.

The register 1110 can store and retain data input from a wiring D or data input from a wiring SD in the flip-flop circuit 1152 in the scan flip-flop circuit 1150 and can output the data to a wiring Q in synchronization with a clock signal supplied to the wiring PCK. The data retained in the flip-flop circuit 1152 is retained after being written to any one of the retention circuit 1131[1] to the retention circuit 1131[G] in the backup circuit 1130 through the wiring Q in accordance with signals supplied to the wiring BK[1] to the wiring BK[G]. Such an operation is sometimes referred to as saving, storage, backup, or the like. The data retained in any one of the retention circuit 1131[1] to the retention circuit 1131[G] is retained after being written back to the flip-flop circuit 1152 through the wiring SD in accordance with signals supplied to the wiring RV[1] to the wiring RV[G]. Such an operation is sometimes referred to as loading, restoration, recovery, or the like.

The flip-flop circuit 1152 has a function of storing and retaining data supplied to an input terminal Df and outputting the data from an output terminal Qf in synchronization with the clock signal supplied to the wiring PCK. As the flip-flop circuit 1152, a flip-flop circuit prepared in a standard circuit library can be employed. A positive edge-triggered D flip-flop can be used, for example.

The selector circuit 1151 has a function of transmitting data supplied to the wiring D or the wiring SD to the flip-flop circuit 1152 in accordance with a signal supplied to the wiring SE. Data input from the outside of the register 1110 is supplied to the wiring D. The data retained in any one of the retention circuit 1131[1] to the retention circuit 1131[G] in the backup circuit 1130 or data input from a wiring SD_IN is supplied to the wiring SD. Data for a scan test is supplied to the wiring SD_IN.

When a power gating operation is performed, the backup circuit 1130 can retain the state of the scan flip-flop circuit 1150 in any one of the retention circuit 1131[1] to the retention circuit 1131[G]. When processing is performed with switching between a plurality of tasks, the backup circuit 1130 can retain the state of the scan flip-flop circuit 1150 for each task in each of the retention circuit 1131[1] to the retention circuit 1131[G] in a one-to-one correspondence.

When data is saved in the backup circuit 1130, any one of the retention circuit 1131[1] to the retention circuit 1131[G] is selected in accordance with the signals supplied to the wiring BK[1] to the wiring BK[G]. When data is loaded into the backup circuit 1130, any one of the retention circuit 1131[1] to the retention circuit 1131[G] is selected in accordance with the signals supplied to the wiring RV[1] to the wiring RV[G]. Signals are supplied to the wiring BK[1] to the wiring BK[G] and the wiring RV[1] to the wiring RV[G] in a one-to-one correspondence to the retention circuit 1131[1] to the retention circuit 1131[G].

Note that a matter common to the retention circuit 1131[1] to the retention circuit 1131[G] is sometimes described as a matter of the retention circuit 1131. In that case, each of the wiring BK[1] to the wiring BK[G] is referred to as the wiring BK, and each of the wiring RV[1] to the wiring RV[G] is referred to as the wiring RV in the description in some cases.

As illustrated in FIG. 49, the retention circuit 1131 is electrically connected to each of the wiring Q and the wiring SD. In the retention circuit 1131, a terminal (wiring) electrically connected to the wiring Q serves as an input terminal and a terminal (wiring) electrically connected to the wiring SD serves as an output terminal. That is, in the register 1110, the output terminal Qf of the flip-flop circuit 1152 is electrically connected to the input terminal of the retention circuit 1131, and the input terminal Df of the flip-flop circuit 1152 is electrically connected to the output terminal of the retention circuit 1131 through the selector circuit 1151.

In the retention circuit 1131, one of a source and a drain of the transistor M1102 is electrically connected to one terminal of the capacitor C1101. One of a source and a drain of the transistor M1103 is electrically connected to the one terminal of the capacitor C1101. The other terminal of the capacitor C1101 is electrically connected to a wiring CM. The other of the source and the drain of the transistor M1102 is electrically connected to the input terminal of the retention circuit 1131 (i.e., the wiring Q). The other of the source and the drain of the transistor M1103 is electrically connected to the output terminal of the retention circuit 1131 (i.e., the wiring SD). A gate of the transistor M1102 is electrically connected to the wiring BK. A gate of the transistor M1103 is electrically connected to the wiring RV.

In the retention circuit 1131[1] to the retention circuit 1131[G], wirings to each of which the one of the source and the drain of the transistor M1102, the one of the source and the drain of the transistor M1103, and the one terminal of the capacitor C1101 are electrically connected are sometimes referred to as a wiring SN[1] to a wiring SN[G] in the description. In the case where a matter common to the retention circuit 1131[1] to the retention circuit 1131[G] is described, each of the wiring SN[1] to the wiring SN[G] is sometimes referred to as a wiring SN in the description.

In the backup circuit 1130, one of a source and a drain of the transistor M1101 is electrically connected to the wiring SD. The other of the source and the drain of the transistor M801 is electrically connected to the wiring SD_IN.

A gate of the transistor M1101 is electrically connected to the wiring GBK. A signal for controlling whether a scan test is performed is supplied to the wiring GBK.

In one embodiment of the present invention, OS transistors can be used as the transistor M1101, the transistor M1102, and the transistor M1103, for example. OS transistors have a characteristic of extremely low off-state current. In addition, OS transistors have a characteristic of off-state current that hardly increases and on-state current that is unlikely to decrease even in a high-temperature environment.

Accordingly, the retention circuit 1131 can retain data written to the wiring SN for a long time when the transistor M1102 and the transistor M1103 are brought into a non-conduction state. For example, the data can be continuously retained even in a state where power is not supplied to the scan flip-flop circuit 1150 for a power gating operation. That is, the retention circuit 1131 can be used as a nonvolatile memory.

Here, when data retained in the wiring SN is written back to the flip-flop circuit 1152 in the register 1110, the potential of the data may change owing to parasitic capacitance of the wiring SD. Thus, the electrostatic capacitance of the capacitor C1101 is preferably larger than the parasitic capacitance of the wiring SD so that the amount of change in the potential of the data is smaller than the logic threshold value of the flip-flop circuit 1152 or the like, for example.

In another structure example of the register 1110, a structure can be employed in which the transistor M1101 is provided for every plurality of retention circuits 1131. For example, a structure can be employed in which a Si transistor is used as the transistor M1101.

The register 1110 can have a structure in which a plurality of layers 1083 are stacked and each of the layers 1083 is provided with the backup circuit 1130 in order to increase the number of retention circuits 1131 without increasing the area overhead.

In one embodiment of the present invention, the backup circuit 1130 can be provided in the register 1110 without change in the circuit structure and layout of the scan flip-flop circuit 1150. That is, the backup circuit 1130 is a circuit that has very broad utility.

Since the register 1110 has a structure in which the backup circuit 1130 is stacked over the scan flip-flop circuit 1150, the lengths of wirings that electrically connect the two can be short. Accordingly, energy (access energy) necessary for data saving and data loading can be reduced. Thus, power consumption of the register 1110 can be reduced.

### Operation Example 1

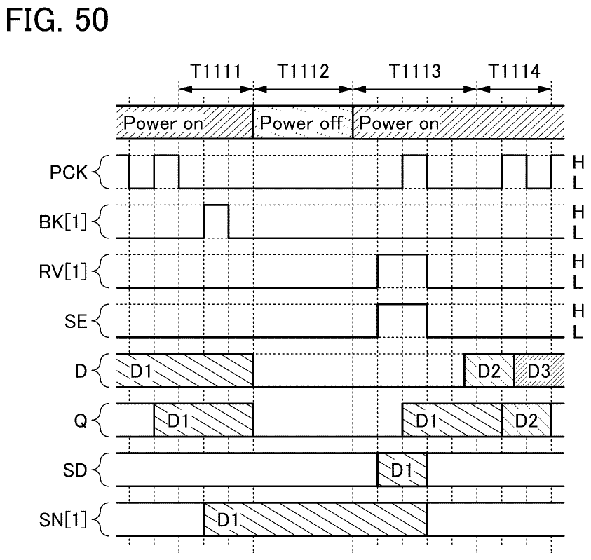

FIG. 50 is a timing chart illustrating an operation example of the register 1110 illustrated in FIG. 49.

Described in this operation example is an operation example of the register 1110 in the case where a power gating operation is performed in the above-described processing device 1000, for example.

Here, the operation of the register 1110 is described using an example where the number of retention circuits 1131 included in the backup circuit 1130 is four (G=4).

In the following description of the operation, the flip-flop circuit 1152 stores data supplied to the input terminal Df and outputs the data from the output terminal Qf in synchronization with the timing at which the clock signal supplied to the wiring PCK switches from the potential L to the potential H (the rising edge). The potential L is supplied to the wiring GBK. A constant potential (e.g., the potential VSS) is supplied to the wiring CM.

The timing chart in FIG. 50 illustrates the states of signals (the potential H and the potential L) supplied to the wiring PCK, the wiring BK[1], the wiring RV[1], and the wiring SE in operation periods (Period T1111 to Period T1114). Note that illustrations for the wiring BK[2] to the wiring BK[4] and the wiring RV[2] to the wiring RV[4] are omitted. In addition, the timing chart in FIG. 50 illustrates the state of data (data D1 to data D3) supplied to each of the wiring D, the wiring Q, the wiring SD, and the wiring SN[1]. Note that illustrations of the wiring SN[2] to the wiring SN[4] are omitted. In addition, the timing chart in FIG. 50 illustrates a state where power is supplied to the scan flip-flop circuit 1150 (Power on) or a state where power is not supplied (Power off).

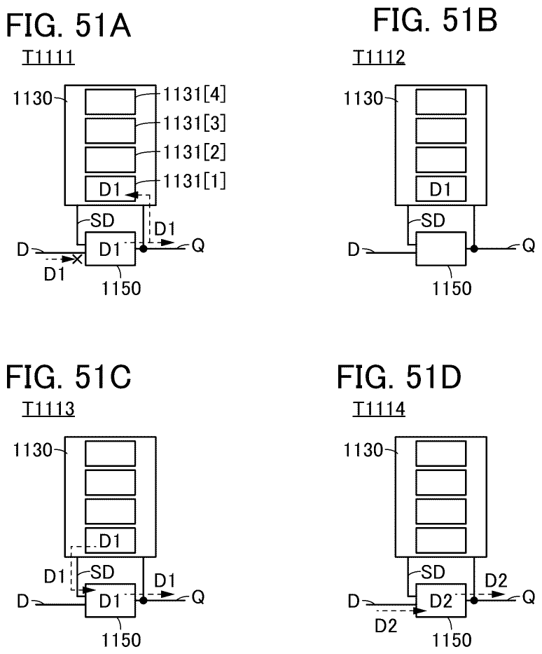

FIG. 51A to FIG. 51D are schematic diagrams illustrating the manner in which data is stored in the scan flip-flop circuit 1150 and the retention circuit 1131[1] to the retention circuit 1131[4] included in the backup circuit 1130 in the periods of the timing chart illustrated in FIG. 50. In the schematic diagrams, the manner in which data is input and output (data flow) is indicated by dashed arrows.

Immediately before Period T1111, the potential L is supplied to each of the wiring BK[1] to the wiring BK[4], the wiring RV[1] to the wiring RV[4], and the wiring SE. The states of the data supplied to the wiring SN[1] and the wiring SN[2] are indeterminate (none of the data DI to the data D3 is illustrated). The clock signal is supplied to the wiring PCK. Power is supplied to the scan flip-flop circuit 1150. The data DI is stored in the scan flip-flop circuit 1150. Note that in the following description, the immediately preceding state is maintained unless otherwise specified.

In Period T1111, first, the clock signal supplied to the wiring PCK is stopped.

Next, the potential H is supplied to the wiring BK[1], whereby the data DI output from the output terminal Qf of the flip-flop circuit 1152 to the wiring Q is stored in the wiring SN[1] of the retention circuit 1131[1]. After that, the potential L is supplied to the wiring BK[1], whereby the data DI stored in the wiring SN[1] is retained (see FIG. 51A).

In Period T1112, power supply to the scan flip-flop circuit 1150 is stopped. Then, the data D1 stored in the scan flip-flop circuit 1150 is lost. Meanwhile, the data DI retained in the wiring SN[1] of the retention circuit 1131[1] is retained (see FIG. 51B).

In Period T1113, first, power supply to the scan flip-flop circuit 1150 is restarted.

Next, the potential H is supplied to the wiring RV[1], whereby the data DI stored in the wiring SN[1] of the retention circuit 1131[1] is supplied to the wiring SD, and the potential H is supplied to the wiring SE, whereby the wiring SD is selected by the selector circuit 1151.

Next, a pulse signal is supplied to the wiring PCK, whereby, in synchronization with the rising edge, the data D1 supplied to the wiring SD is stored in the scan flip-flop circuit 1150 and the data DI is output to the wiring Q through the flip-flop circuit 1152. After that, the potential L is supplied to the wiring RV[1] and the wiring SE (see FIG. 51C).

In Period T1114, the clock signal supplied to the wiring PCK is restarted. Furthermore, the data D2 is supplied to the wiring D. Then, in synchronization with the rising edge of the clock signal, the data D2 supplied to the wiring D is stored in the scan flip-flop circuit 1150 and the data D2 is output to the wiring Q through the flip-flop circuit 1152 (see FIG. 51D).

In the above manner, the register 1110 can be operated as illustrated in the timing chart in FIG. 50. Accordingly, in the case where a power gating operation is performed in the processing device 1000, when the scan flip-flop circuit 1150 is powered on, for example, it can be promptly returned to a state immediately before power-off, and the time taken for the restart of processing can be shortened.

### Operation Example 2

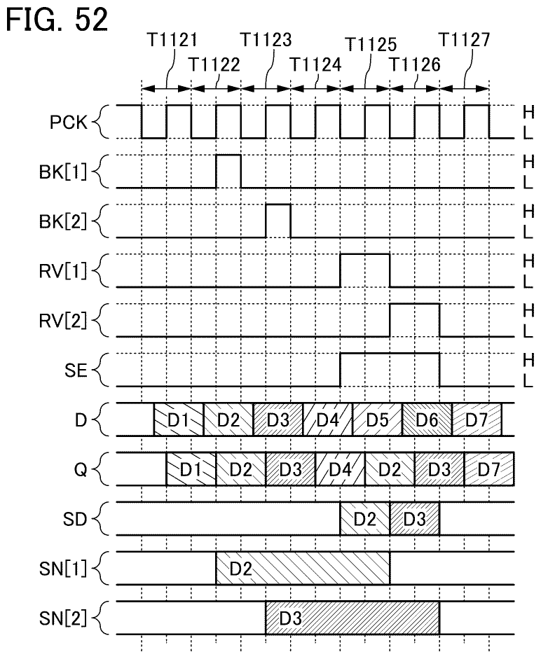

FIG. 52 is a timing chart illustrating an operation example of the register 1110 illustrated in FIG. 49.

Described in this operation example 2 is an operation example of the register 1110 in the case where processing is performed with switching between a plurality of tasks in the above-described processing device 1000, for example.

Here, the operation of the register 1110 is described using an example where the number of retention circuits 1131 included in the backup circuit 1130 is four (G=4).

In the following description of the operation, the flip-flop circuit 1152 stores data supplied to the input terminal Df and outputs the data from the output terminal Qf in synchronization with the timing at which the clock signal supplied to the wiring PCK switches from the potential L to the potential H (the rising edge). The potential L is supplied to the wiring GBK. A constant potential (e.g., the potential VSS) is supplied to the wiring CM.

The timing chart in FIG. 52 illustrates the states of signals (the potential H and the potential L) supplied to the wiring PCK, the wiring BK[1], the wiring BK[2], the wiring RV[1], the wiring RV[2], and the wiring SE in operation periods (Period T1121 to Period T1127). Note that illustrations for the wiring BK[3], the wiring BK[4], the wiring RV[3], and the wiring RV[4] are omitted. In addition, the timing chart in FIG. 52 illustrates the state of data (data DI to data D7) supplied to each of the wiring D, the wiring Q, the wiring SD, the wiring SN[1], and the wiring SN[2]. Note that illustrations for the wiring SN[3] and the wiring SN[4] are omitted.

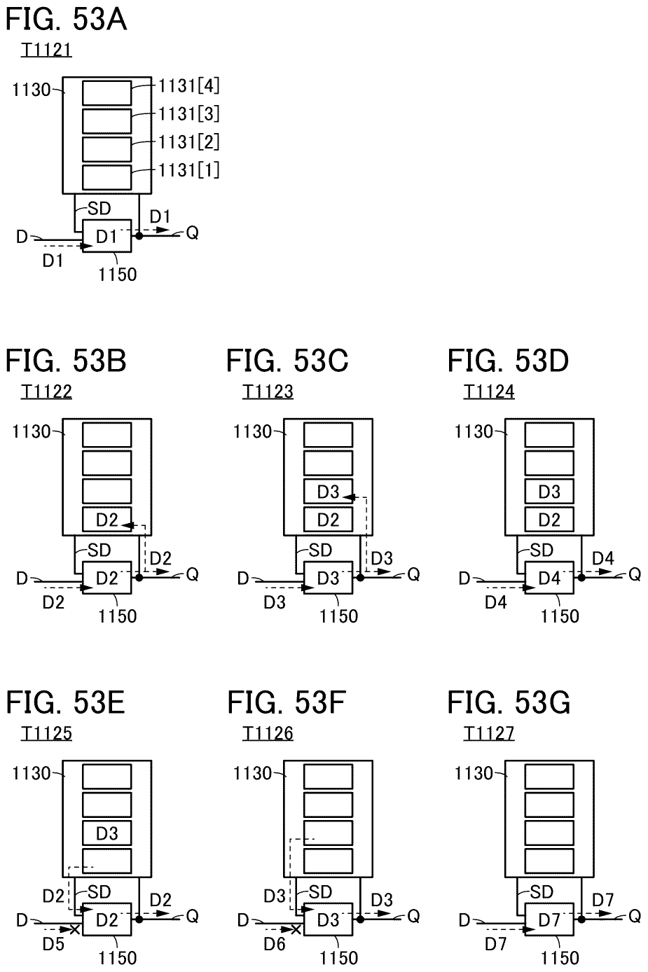

FIG. 53A to FIG. 53G are schematic diagrams illustrating the manner in which data is stored in the scan flip-flop circuit 1150 and the retention circuit 1131[1] to the retention circuit 1131[4] included in the backup circuit 1130 in the periods of the timing chart illustrated in FIG. 52. In the schematic diagrams, the manner in which data is input and output (data flow) is indicated by dashed arrows.

Immediately before Period T1121, the potential L is supplied to each of the wiring BK[1] to the wiring BK[4], the wiring RV[1] to the wiring RV[4], and the wiring SE. The states of the data supplied to the wiring SN[1] and the wiring SN[2] are indeterminate (none of the data D1 to the data D7 is illustrated). Note that in the following description, the immediately preceding state is maintained unless otherwise specified.

In Period T1121, in synchronization with the rising edge of the signal supplied to the wiring PCK, the data D1 supplied to the wiring D is stored in the scan flip-flop circuit 1150 and the data DI is output to the wiring Q through the flip-flop circuit 1152 (see FIG. 53A).

In Period T1122, in synchronization with the rising edge of the signal supplied to the wiring PCK, the data D2 supplied to the wiring D is stored in the scan flip-flop circuit 1150 and the data D2 is output to the wiring Q through the flip-flop circuit 1152.

At this time, the potential H is supplied to the wiring BK[1], whereby the data D2 output to the wiring Q is stored in the wiring SN[1] of the retention circuit 1131[1]. After that, the potential L is supplied to the wiring BK[1], whereby the data D2 stored in the wiring SN[1] is retained (see FIG. 53B).

In Period T1123, in synchronization with the rising edge of the signal supplied to the wiring PCK, the data D3 supplied to the wiring D is stored in the scan flip-flop circuit 1150 and the data D3 is output to the wiring Q through the flip-flop circuit 1152.

At this time, the potential H is supplied to the wiring BK[2], whereby the data D3 output to the wiring Q is stored in the wiring SN[2] of the retention circuit 1131[2]. After that, the potential L is supplied to the wiring BK[2], whereby the data D3 stored in the wiring SN[2] is retained (see FIG. 53C).

In Period T1124, in synchronization with the rising edge of the signal supplied to the wiring PCK, the data D4 supplied to the wiring D is stored in the scan flip-flop circuit 1150 and the data D4 is output to the wiring Q through the flip-flop circuit 1152 (see FIG. 53D).

In Period T1125, first, the potential H is supplied to the wiring RV[1], whereby the data D2 stored in the wiring SN[1] of the retention circuit 1131[1] is supplied to the wiring SD. Although the data D5 is supplied to the wiring D, the wiring SD is selected by the selector circuit 1151 because the potential H is supplied to the wiring SE.

Next, in synchronization with the rising edge of the wiring PCK, the data D2 supplied to the wiring SD is stored in the scan flip-flop circuit 1150 and the data D2 is output to the wiring Q through the flip-flop circuit 1152. After that, the potential L is supplied to the wiring RV[1] (see FIG. 53E).

In Period T1126, first, the potential H is supplied to the wiring RV[2], whereby the data D3 stored in the wiring SN[2] of the retention circuit 1131[2] is supplied to the wiring SD. Although the data D6 is supplied to the wiring D, the wiring SD is selected by the selector circuit 1151 because the potential H is supplied to the wiring SE.

Next, in synchronization with the rising edge of the wiring PCK, the data D3 supplied to the wiring SD is stored in the scan flip-flop circuit 1150 and the data D3 is output to the wiring Q through the flip-flop circuit 1152. After that, the potential L is supplied to the wiring RV[2], and the potential L is supplied to the wiring SE (see FIG. 53F).

In Period T1127, in synchronization with the rising edge of the signal supplied to the wiring PCK, the data D7 supplied to the wiring D is stored in the scan flip-flop circuit 1150 and the data D7 is output to the wiring Q through the flip-flop circuit 1152 (see FIG. 53G).

In the above manner, the register 1110 can be operated as illustrated in the timing chart in FIG. 52. Accordingly, in the case where processing is performed with switching between a plurality of tasks in the processing device 1000, a structure can be achieved in which data of a suspended task is saved and data of a resuming task is loaded, for example.

### Memory Device That Can Be Used for Memory Device

A memory device 1210 of one embodiment of the present invention is described. At least part of the memory device 1210 can be used for the above-described processing device 1000 illustrated in FIG. 46 to FIG. 48D, for example. For example, part of the memory device 1210 can be used for the memory block 1023 included in the memory portion 1020.

### Structure Example

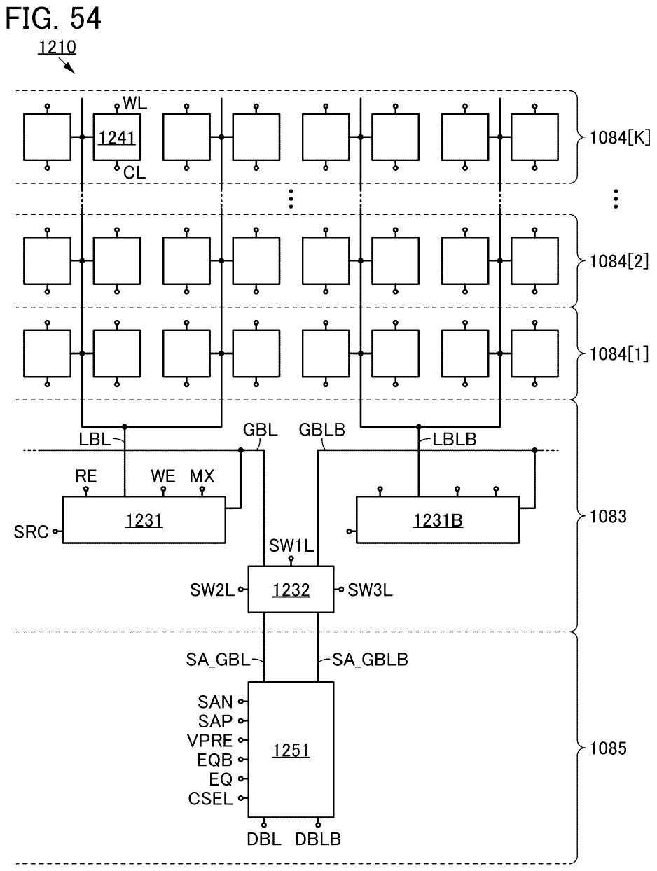

FIG. 54 is a circuit diagram illustrating a structure example of the memory device 1210.

The memory device 1210 illustrated in FIG. 54 includes a plurality of memory cells 1241, a sub-sensing circuit 1231, a sub-sensing circuit 1231B, a switch circuit 1232, and a sensing circuit 1251.

As the memory cell 1241, a memory cell that can be used as the memory cell 1025 described above can be used, for example. Specifically, for example, the memory cell MC or the memory cell MC1 to the memory cell MC4 described in the above embodiment can be used as the memory cell 1241. For example, the memory cell 921A to the memory cell 921H in FIG. 44A to FIG. 44H described in Embodiment 4 can be used as the memory cell 1241.

In this structure example, the case where a memory cell including one transistor and one capacitor (a DRAM or a DOSRAM) is used as the memory cell 1241 is described. Specifically, for example, the case where the structure of the memory cell 10 illustrated in FIG. 35 described in Embodiment 3 is used for the memory cell 1241 is described.

In the case where the memory device 1210 is used for the memory block 1023 included in the above-described processing device 1000 in one embodiment of the present invention, the memory cell 1241 corresponds to the memory cell 1025, the sub-sensing circuit 1231, the sub-sensing circuit 1231B, and the switch circuit 1232 each correspond to the sub-sense amplifier 1027, and the sensing circuit 1251 corresponds to the sense amplifier 1026, for example. In other words, the memory cell 1241 is placed in the layer 1084[1] to the layer 1084[K], the sub-sensing circuit 1231, the sub-sensing circuit 1231B, and the switch circuit 1232 are placed in the layer 1083, and the sensing circuit 1251 is placed in the layer 1085, for example. Thus, vertical OS transistors can be used in the memory cells 1241, OS transistors can be used in the sub-sensing circuit 1231, the sub-sensing circuit 1231B, and the switching circuit 1232, and a Si transistor can be used in the sensing circuit 1251, for example.

FIG. 54 illustrates selectively eight memory cells 1241 placed in the layer 1084[1], eight memory cells 1241 placed in the layer 1084[2], and eight memory cells 1241 placed in the layer 1084[K].

Some of the plurality of memory cells 1241 are electrically connected to the sub-sensing circuit 1231 through a wiring LBL having a function of a local bit line. The others are electrically connected to the sub-sensing circuit 1231B through a wiring LBLB having a function of a local bit line. The sub-sensing circuit 1231 is electrically connected to the switch circuit 1232 through a wiring GBL having a function of a global bit line. The sub-sensing circuit 1231B is electrically connected to the switch circuit 1232 through a wiring GBLB having a function of a global bit line. The switch circuit 1232 is electrically connected to the sensing circuit 1251 through a wiring SA_GBL and a wiring SA_GBLB each having a function of a global bit line.

The sub-sensing circuit 1231 has, in the case where data is written to the memory cell 1241, a function of supplying a potential corresponding to the data from the wiring GBL to the wiring LBL. The sub-sensing circuit 1231 has, in the case where data is read from the memory cell 1241, a function of amplifying a change in the potential of the wiring LBL and outputting the amplified change to the wiring GBL.

The sub-sensing circuit 1231B has a structure similar to that of the sub-sensing circuit 1231. Thus, for the description of the sub-sensing circuit 1231B, the description of the sub-sensing circuit 1231 can be referred to as appropriate by replacing the wiring GBL with the wiring GBLB and the wiring LBL with the wiring LBLB.

The switch circuit 1232 has a function of establishing or breaking electrical continuity between the wiring GBL, the wiring GBLB, the wiring SA_GBL, and the wiring SA_GBLB.

In the case of writing data, the sensing circuit 1251 has a function of supplying a potential corresponding to the data to each of the wiring SA_GBL and the wiring SA_GBLB. In the case of reading data, the sensing circuit 1251 has a function of outputting a potential corresponding to the data in accordance with a potential difference between the wiring SA_GBL and the wiring SA_GBLB.

In particular, the structure of the sense amplifier 46 described in Embodiment 3 can be employed for the sensing circuit 1251.

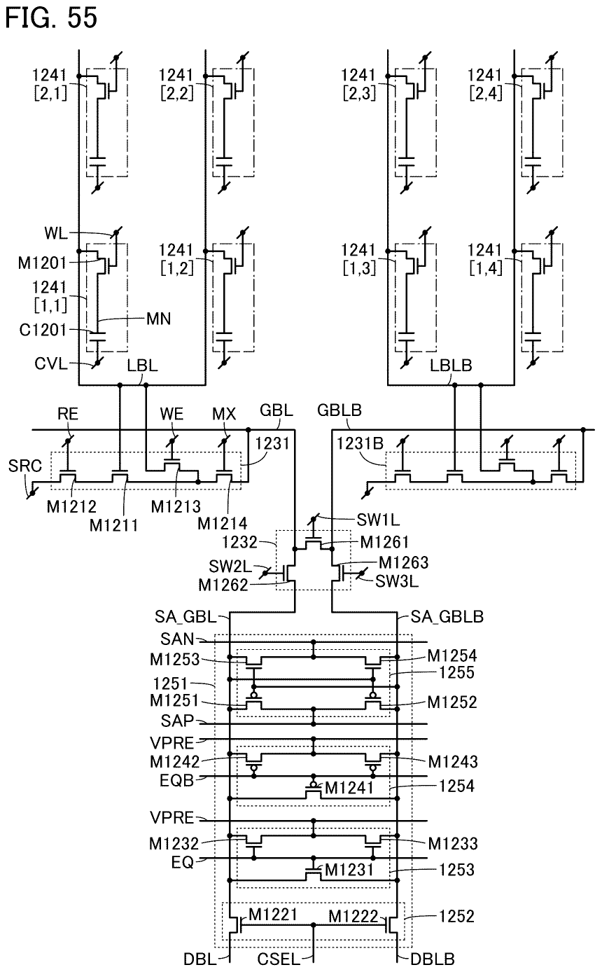

FIG. 55 is a circuit diagram illustrating a specific structure example of the memory device 1210 illustrated in FIG. 54. Note that FIG. 55 selectively illustrates two memory cells (a memory cell 1241[1,1] and a memory cell 1241[1,2]) electrically connected to the wiring LBL and two memory cells (a memory cell 1241[1,3] and a memory cell 1241[1,4]) electrically connected to the wiring LBLB, which are placed in the layer 1084[1]. FIG. 55 also illustrates two memory cells (a memory cell 1241[2,1] and a memory cell 1241[2,2]) electrically connected to the wiring LBL and two memory cells (a memory cell 1241[2,3] and a memory cell 1241[2,4]) electrically connected to the wiring LBLB, which are placed in the layer 1084[2].

A plurality of memory cells (a memory cell M1241[1,1] to a memory cell M1241[2,4]) illustrated in FIG. 55 each include a transistor M1201 and a capacitor C1201. Note that the transistor M1201 corresponds to the transistor M1 in FIG. 35, and the capacitor C1201 corresponds to the capacitor C1 in FIG. 35.

The sub-sensing circuit 1231 includes a transistor M1211, a transistor M1212, a transistor M1213, and a transistor M1214. One of a source and a drain of the transistor M1211 is electrically connected to one of a source and a drain of the transistor M1213 and one of a source and a drain of the transistor M1214. The other of the source and the drain of the transistor M1211 is electrically connected to one of a source and a drain of the transistor M1212. A gate of the transistor M1211 is electrically connected to the other of the source and the drain of the transistor M1213 and the wiring LBL. The other of the source and the drain of the transistor M1212 is electrically connected to a wiring SRC. The other of the source and the drain of the transistor M1214 is electrically connected to the wiring GBL. A gate of the transistor M1212 is electrically connected to a wiring RE. A gate of the transistor M1213 is electrically connected to a wiring WE. A gate of the transistor M1214 is electrically connected to a wiring MX. The transistor M1211 has a function of flowing current between the source and the drain in accordance with the potential of the wiring LBL.

The sub-sensing circuit 1231 has a function of changing the potential of the wiring GBL by making current corresponding to the potential of the wiring LBL flow from the wiring GBL to the wiring SRC through the transistor M1214, the transistor M1211, and the transistor M1212. In addition, the sub-sensing circuit 1231 has a function of transmitting the potential of the wiring GBL to the wiring LBL through the transistor M1214 and the transistor M1213.

Furthermore, the sub-sensing circuit 1231 has a function of changing the potential of the gate of the transistor M1211 to a potential corresponding to the threshold voltage of the transistor M1211 by discharging charges accumulated in the gate of the transistor M1211 through the transistor M1213, the transistor M1211, and the transistor M1212 to the wiring SRC. With this function, the sub-sensing circuit 1231 is capable of correction so as to reduce the effect of the threshold voltage of the transistor M1211. Such correction can reduce the effect on data reading even when the threshold voltage of the transistor M1211 varies between a plurality of sub-sensing circuits 1231; thus, the reliability of the memory device 1210 can be improved.

The switch circuit 1232 includes a transistor M1261, a transistor M1262, and a transistor M1263.

One of a source and a drain of the transistor M1261 is electrically connected to the wiring GBL. The other of the source and the drain of the transistor M1261 is electrically connected to the wiring GBLB. A gate of the transistor M1261 is electrically connected to a wiring SW1L. One of a source and a drain of the transistor M1262 is electrically connected to the wiring GBL. The other of the source and the drain of the transistor M1262 is electrically connected to a wiring SA_GBL. A gate of the transistor M1262 is electrically connected to a wiring SW2L. One of a source and a drain of the transistor M1263 is electrically connected to the wiring GBLB. The other of the source and the drain of the transistor M1263 is electrically connected to a wiring SA_GBLB. A gate of the transistor M1263 is electrically connected to a wiring SW3L.

The sensing circuit 1251 includes a switch circuit 1252, a precharge circuit 1253, a precharge circuit 1254, and an amplifier circuit 1255. The switch circuit 1252, the precharge circuit 1253, the precharge circuit 1254, and the amplifier circuit 1255 are each electrically connected to the wiring SA_GBL and the wiring SA_GBLB. The switch circuit 1252 is electrically connected to a wiring DBL and a wiring DBLB. The sensing circuit 1251 has a function of controlling data writing and reading to and from the memory cells 1241.

The switch circuit 1252 has a function of establishing or interrupting electrical continuity between the wiring pair of the wiring SA_GBL and the wiring SA_GBLB and the wiring pair of the wiring DBL and the wiring DBLB in accordance with a signal supplied to a wiring CSEL. Specifically, the switch circuit 1252 includes a transistor M1221 and a transistor M1222. One of a source and a drain of the transistor M1221 is electrically connected to the wiring SA_GBL. The other of the source and the drain of the transistor M1221 is electrically connected to the wiring DBL. One of a source and a drain of the transistor M1222 is electrically connected to the wiring SA_GBLB. The other of the source and the drain of the transistor M1222 is electrically connected to the wiring DBLB. A gate of the transistor M1221 and a gate of the transistor M1222 are electrically connected to the wiring CSEL. The transistor M1221 and the transistor M1222 are n-channel transistors.

Thus, the switch circuit 1252 corresponds to the circuit OP included in the memory device in FIG. 36 described in Embodiment 3.

The precharge circuit 1253 has a function of precharging the wiring SA_GBL and the wiring SA_GBLB with a potential supplied to a wiring VPRE, in accordance with a signal supplied to a wiring EQ. Specifically, the precharge circuit 1253 includes a transistor M1231, a transistor M1232, and a transistor M1233. One of a source and a drain of the transistor M1231 is electrically connected to the wiring SA_GBL. The other of the source and the drain of the transistor M1231 is electrically connected to the wiring SA_GBLB. One of a source and a drain of the transistor M1232 is electrically connected to the wiring SA_GBL. One of a source and a drain of the transistor M1233 is electrically connected to the wiring SA_GBLB. The other of the source and the drain of the transistor M1232 and the other of the source and the drain of the transistor M1233 are electrically connected to the wiring VPRE. A gate of the transistor M1231, a gate of the transistor M1232, and a gate of the transistor M1233 are electrically connected to the wiring EQ. The transistor M1231, the transistor M1232, and the transistor M1233 are n-channel transistors.

The precharge circuit 1254 has a function of precharging the wiring SA_GBL and the wiring SA_GBLB with the potential supplied to the wiring VPRE, in accordance with a signal supplied to a wiring EQB. Specifically, the precharge circuit 1254 includes a transistor M1241, a transistor M1242, and a transistor M1243. One of a source and a drain of the transistor M1241 is electrically connected to the wiring SA_GBL. The other of the source and the drain of the transistor M1241 is electrically connected to the wiring SA_GBLB. One of a source and a drain of the transistor M1242 is electrically connected to the wiring SA_GBL. One of a source and a drain of the transistor M1243 is electrically connected to the wiring SA_GBLB. The other of the source and the drain of the transistor M1242 and the other of the source and the drain of the transistor M1243 are electrically connected to the wiring VPRE. A gate of the transistor M1241, a gate of the transistor M1242, and a gate of the transistor M1243 are electrically connected to the wiring EQB. The transistor M1241, the transistor M1242, and the transistor M1243 are p-channel transistors.

That is, the precharge circuit 1253 and the precharge circuit 1254 each have a function of leveling the potentials of the two wirings, like the circuit EQP included in the memory device in FIG. 36 described in Embodiment 3.

The amplifier circuit 1255 has a function of outputting a potential corresponding to one of binary data to the wiring SA_GBL and outputting a potential corresponding to the other of the binary data to the wiring SA_GBLB when a predetermined potential is supplied to a wiring SAP and a wiring SAN. Specifically, the amplifier circuit 1255 includes a transistor M1251, a transistor M1252, a transistor M1253, and a transistor M1254. One of a source and a drain of the transistor M1251 is electrically connected to the wiring SA_GBL. One of a source and a drain of the transistor M1252 is electrically connected to the wiring SA_GBLB. One of a source and a drain of the transistor M1253 is electrically connected to the wiring SA_GBL. One of a source and a drain of the transistor M1254 is electrically connected to the wiring SA_GBLB. The other of the source and the drain of the transistor M1251 and the other of the source and the drain of the transistor M1252 are electrically connected to the wiring SAP. The other of the source and the drain of the transistor M1253 and the other of the source and the drain of the transistor M1254 are electrically connected to the wiring SAN. A gate of the transistor M1251 and a gate of the transistor M1253 are electrically connected to the wiring SA_GBLB. A gate of the transistor M1252 and a gate of the transistor M1254 are electrically connected to the wiring SA_GBL. The transistor M1251 and the transistor M1252 are p-channel transistors. The transistor M1253 and the transistor M1254 are n-channel transistors.

Here, in the case where any one of the plurality of memory cells 1241 in the memory device 1210 is selected and data is written to and read from the memory cell 1241, a signal is preferably supplied to a wiring WL electrically connected to the memory cell 1241. The wiring WL has a function of a word line in the memory cell 1241.

In FIG. 55, in the case where data is written to and read from the memory cell 1241[1,1] placed in the layer 1084[1], for example, the potential H is preferably supplied to the wiring WL electrically connected to the memory cell 1241[1,1] and the potential L is preferably supplied to the wiring WL electrically connected to the other memory cells 1241.

### Operation Example

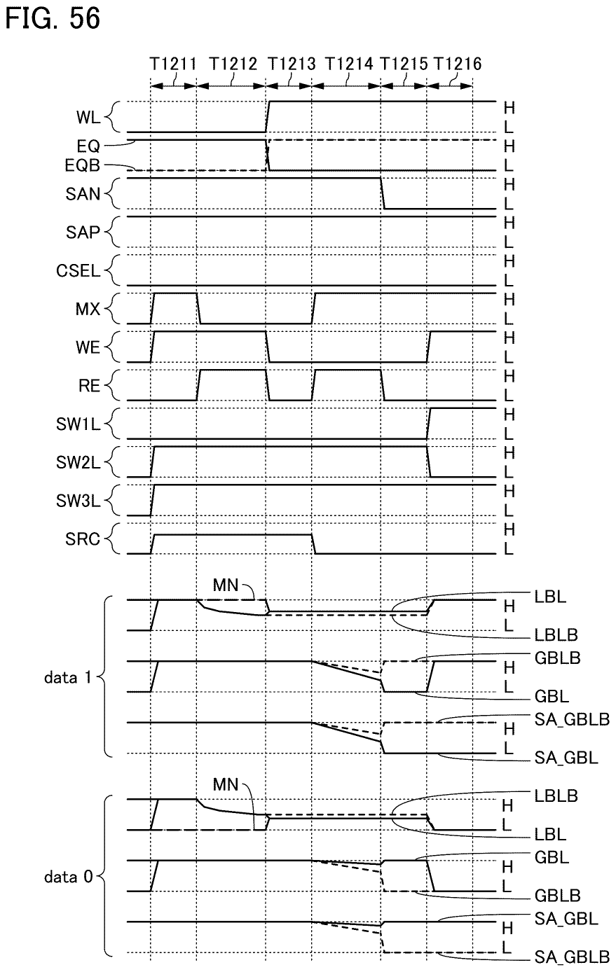

FIG. 56 is a timing chart illustrating an operation example of the memory device 1210 illustrated in FIG. 55.

In the subsequent description of the operation, the potential VDD which is a high power supply potential is supplied to the wiring VPRE. In addition, a given fixed potential (e.g., a potential VSS which is a low power supply potential) is supplied to the wiring CVL.

The timing chart in FIG. 56 illustrates the states of signals (the potential H and the potential L) supplied to the wiring WL, the wiring MX, the wiring WE, the wiring RE, the wiring SW1L, the wiring SW2L, the wiring SW3L, the wiring EQ, the wiring EQB, and the wiring CSEL in operation periods (Period T1211 to Period T1216). The potentials supplied to the wiring SRC, the wiring SAP, and the wiring SAN are also shown. Changes in the potentials of the wiring MN, the wiring LBL, the wiring LBLB, the wiring GBL, the wiring GBLB, the wiring SA_GBL, and the wiring SA_GBLB in the case where data “1” is read (data 1) and the case where data “0” is read (data 0) are also shown.

Period T1211 to Period T1213 are periods in which the threshold voltage of the transistor M1211 are corrected. Period T1213 to Period T1215 are periods in which data is read. Period T1216 is a period in which data is written back (refreshed).

Immediately before Period T1211, the potential L is supplied to each of the wiring WL, the wiring MX, the wiring WE, and the wiring RE. A predetermined potential (e.g., the potential VSS) is supplied to the wiring SRC. The potential L is supplied to each of the wiring SW1L, the wiring SW2L, and the wiring SW3L. The potential H is supplied to the wiring EQ, and the potential L is supplied to the wiring EQB. The potential L is supplied to the wiring CSEL. In addition, the potential VDD is supplied to each of the wiring SAP and the wiring SAN. At this time, the wiring SA_GBL and the wiring SA_GBLB are each precharged with the potential VDD. The wiring GBL and the wiring GBLB are each in a floating state, and the potential of each wiring is the potential VDD or the potential VSS. The wiring LBL and the wiring LBLB are each in a floating state, and the potential of each wiring is the potential VDD or the potential VSS. In addition, the wiring MN of the memory cell 1241 retains the potential VDD (a potential corresponding to data “1”) or the potential VSS (a potential corresponding to data “0”). Note that in the following description, the immediately preceding state is maintained unless otherwise specified.

In Period T1211, the potential H is supplied to the wiring SW2L and the wiring SW3L. In addition, the potential H is supplied to the wiring MX and the wiring WE. Then, the wiring GBL and the wiring GBLB are each precharged with the potential VDD. Furthermore, the wiring LBL and the wiring LBLB are each precharged with the potential VDD. In addition, the potential of the wiring SRC becomes a predetermined potential between the potential VDD and the potential VSS. The predetermined potential affects the amount of current flowing through the transistor M1211 during the operation in Period T1214 described later. Thus, the predetermined potential is preferably determined such that the current amount can become an appropriate value.

In Period T1212, the potential L is supplied to the wiring MX, and the potential H is supplied to the wiring RE. Then, the potentials of the wiring LBL and the wiring LBLB are each decreased to “the potential of the wiring SRC+the threshold voltage of the transistor M1211” by the discharging to the wiring SRC through the transistors M1211 included in the sub-sensing circuit 1231 and the sub-sensing circuit 1231B.

In Period T1213, the potential L is supplied to the wiring WE and the wiring RE. Then, the wiring LBL and the wiring LBLB are each brought into a floating state. Accordingly, potentials corresponding to the threshold voltages of the transistors M1211 included in the sub-sensing circuit 1231 and the sub-sensing circuit 1231B are retained in the wiring LBL and the wiring LBLB, respectively. Accordingly, correction is performed such that the amount of current flowing through the transistors M1211 during the operation in Period T1214 described later is not affected by the threshold voltages of the transistors M1211. Such correction can reduce the effect on data reading even when the threshold voltages of the transistors M1211 vary. This can improve reliability of the memory device 1210.

In Period T1213, the potential L is supplied to the wiring EQ and the potential H is supplied to the wiring EQB. This stops precharging of the wiring SA_GBL and the wiring GBL and precharging of the wiring SA_GBLB and the wiring GBLB. Thus, the wiring SA_GBL and the wiring GBL each become floating, and the wiring SA_GBLB and the wiring GBLB each become floating.

In Period T1213, the signal supplied to the wiring WL that is connected to the memory cell 1241 electrically connected to the wiring LBL becomes the potential H. Then, charge sharing is performed between the wiring LBL and the wiring MN. Thus, the potential of the wiring LBL changes in accordance with data stored in the memory cell 1241 (i.e., in accordance with the potential retained in the wiring MN). Accordingly, the potential of the wiring LBL becomes equal to the potential of the wiring MN.

Specifically, in the case where the data stored in the memory cell 1241 is “1” (i.e., the potential VDD is retained in the wiring MN), for example, the signal supplied to the wiring WL becomes the potential H, whereby the potential of the wiring LBL increases and the potential of the wiring MN decreases. Accordingly, the potential of the wiring LBL becomes equal to the potential of the wiring MN. Alternatively, in the case where the data stored in the memory cell 1241 is “0” (i.e., the potential VSS is retained in the wiring MN), for example, the signal supplied to the wiring WL becomes the potential H, whereby the potential of the wiring LBL decreases and the potential of the wiring MN increases. Accordingly, the potential of the wiring LBL becomes equal to the potential of the wiring MN.

By contrast, in Period T1213, the signal supplied to the wiring WL that is connected to the memory cell 1241 electrically connected to the wiring LBLB remains the potential L. That is, charge sharing is not performed by the wiring LBLB. Thus, the potential of the wiring LBL does not change.

Note that the potential of the wiring MN is changed by charge sharing. In other words, data stored in the memory cell 1241 is destroyed. That is, destructive reading is performed. Thus, data is written back by the operation in Period T1216 described later.

In Period T1214, the potential H is supplied to the wiring MX and the wiring RE. The potential that is the same as the potential immediately before Period T1211 (e.g., the potential VSS) is supplied to the wiring SRC. Then, current flows through the transistor M1211 included in the sub-sensing circuit 1231 and the transistor M1211 included in the sub-sensing circuit 1231B in accordance with the potentials of the wiring LBL and the wiring LBLB. Accordingly, the potentials of the wiring SA_GBL and the wiring GBL and the potentials of the wiring SA_GBLB and the wiring GBLB decrease gradually. At this time, the difference between the potential of the wiring LBL and the potential of the wiring LBLB causes a difference between the amount of current flowing through the transistor M1211 included in the sub-sensing circuit 1231 and the amount of current flowing through the transistor M1211 included in the sub-sensing circuit 1231B. This difference in the current amount corresponds to the potential of the wiring LBL changed due to charge sharing in the above-described operation in Period T1213. That is, the speed at which the potentials of the wiring SA_GBL and the wiring GBL decrease is changed in accordance with the potential of the wiring LBL. Thus, the potential of the wiring LBL can be converted into a potential difference between the wiring SA_GBL and the wiring SA_GBLB.

Specifically, in the case where the data stored in the memory cell 1241 is “1”, for example, the amount of current flowing through the transistor M1211 included in the sub-sensing circuit 1231 is larger than the amount of current flowing through the transistor M1211 included in the sub-sensing circuit 1231B. Thus, the speed at which the potentials of the wiring SA_GBL and the wiring GBL decrease is higher than the speed at which the potentials of the wiring SA_GBLB and the wiring GBLB decrease. This makes the potential of the wiring SA_GBL lower than the potential of the wiring SA_GBLB. For another example, in the case where the data stored in the memory cell 1241 is “0”, the amount of current flowing through the transistor M1211 included in the sub-sensing circuit 1231 is smaller than the amount of current flowing through the transistor M1211 included in the sub-sensing circuit 1231B. Thus, the speed at which the potentials of the wiring SA_GBL and the wiring GBL decrease is lower than the speed at which the potentials of the wiring SA_GBLB and the wiring GBLB decrease. This makes the potential of the wiring SA_GBL higher than the potential of the wiring SA_GBLB.

In Period T1215, the potential L is supplied to the wiring RE. The potential VSS is applied to the wiring SAN. Then, by the operation of the amplifier circuit 1255, the potential difference between the wiring SA_GBL and the wiring SA_GBLB generated by the above-described operation in Period T1214 is amplified. Thus, the potentials of the wiring SA_GBL and the wiring SA_GBLB are each determined to be either the potential VDD or the potential VSS. That is, reading of data stored in the memory cell 1241 is completed.

Specifically, for example, in the case where the data stored in the memory cell 1241 is “1”, the potential of the wiring SA_GBL becomes the potential VSS and the potential of the wiring SA_GBLB becomes the potential VDD. For another example, in the case where the data stored in the memory cell 1241 is “0”, the potential of the wiring SA_GBL becomes the potential VDD and the potential of the wiring SA_GBLB becomes the potential VSS.

In Period T1216, the potential H is supplied to the wiring SW1L, and the potential L is supplied to the wiring SW2L. The potential H is supplied to the wiring WE. Then, an operation of writing back data to the memory cell 1241 is performed in accordance with data read from the memory cell 1241. That is, the potentials of the wiring GBL and the wiring LBL become equal to the potential of the wiring SA_GBLB determined by the operation in Period T1215. Furthermore, the potential is written back to the memory cell 1241.

Specifically, for example, in the case where the data stored in the memory cell 1241 is “1”, the potential of the wiring SA_GBLB immediately before Period T1216 is the potential VDD. Thus, the potentials of the wiring GBL and the wiring LBL become the potential VDD. Furthermore, the potential VDD is written back to the memory cell 1241. For another example, in the case where the data stored in the memory cell 1241 is “0”, the potential of the wiring SA_GBLB immediately before Period T1216 is the potential VSS. Thus, the potentials of the wiring GBL and the wiring LBL become the potential VSS. Furthermore, the potential VSS is written back to the memory cell 1241.

In the case where data is written to the memory cell 1241, the memory device 1210 can perform operation similar to that in Period T1216 described above, for example. For example, in the case where data “1” is written to the memory cell 1241, the potential VDD can be supplied to the wiring SA_GBLB to perform the operation similar to that in Period T1216. For another example, in the case where data “0” is written to the memory cell 1241, the potential VSS can be supplied to the wiring SA_GBLB to perform the operation similar to that in Period T1216.

In each of the register 1110 and the memory device 1210 of one embodiment of the present invention, although the OS transistor is a three-terminal semiconductor element including a gate, a source, and a drain in the above description, the OS transistor can be a four-terminal semiconductor element including a back gate. In the case where the OS transistor includes a back gate, on-state resistance can be reduced (on-state current can be increased), for example, by supplying the same potential as the gate to the back gate. When the same potential as the potential of the source is supplied to the back gate, for example, an electric field generated outside the transistor is unlikely to affect the channel formation region, and consequently the electrical characteristics can be stabilized and the reliability can be improved. When a given potential is supplied to the back gate, the threshold voltage can be changed, for example. Furthermore, current flowing between the source and the drain can be independently controlled in accordance with potentials supplied to the gate and the back gate, for example.

In the above description of the operation example of each of the register 1110 and the memory device 1210, a rise time and a fall time sometimes are generated at the time of potential change owing to a load on a wiring (parasitic capacitance and parasitic resistance), for example. Such a time is, for example, longer than 0 seconds and is shorter than 1000 nanoseconds, shorter than 100 nanoseconds, shorter than 10 nanoseconds, or shorter than 1 nanosecond. Furthermore, for example, two different operations that appear to occur at the same timing do not necessarily occur at exactly the same timing. The operations can be sometimes considered to occur at the same timing even though a signal delay in a wiring or the like causes a slight time lag between the operations, for example. The time lag is, for example, longer than 0 seconds and is shorter than 1000 nanoseconds, shorter than 100 nanoseconds, shorter than 10 nanoseconds, or shorter than 1 nanosecond.

The plurality of wirings are not necessarily supplied with the same potential H or the same potential L. The potentials supplied to the wirings can be different from each other in consideration of the threshold voltage of the transistor supplied with the potential, for example. Note that the potential H or the potential L supplied to each wiring may include a potential decrease due to the threshold voltage of the transistor, for example.

The lengths of the periods in the timing chart are different from each other in some cases even when the lengths of the periods appear the same. That is, in the case where each of the register 1110 and the memory device 1210 is actually operated, the length of each period is preferably set as appropriate.

Note that this embodiment can be combined with the same embodiment or any of the other embodiments in this specification as appropriate. For example, the configurations, structures, methods, and the like described in this embodiment can be used in an appropriate combination with any of the other configurations, the other structures, the other methods, and the like described in the same embodiment. For another example, the configurations, structures, methods, and the like described in this embodiment can be used in an appropriate combination with any of the configurations, structures, methods, and the like described in the other embodiments and the like.

### Embodiment 7

In this embodiment, a transistor whose channel formation region includes an oxide semiconductor (an OS transistor) is described. In the description of the OS transistor, comparison with a transistor whose channel formation region includes silicon (also referred to as a Si transistor) is also described briefly.

### OS Transistor

An oxide semiconductor having a low carrier concentration is preferably used in an OS transistor. For example, the carrier concentration in the channel formation region of the oxide semiconductor is lower than or equal to 1×10¹⁸ cm⁻³, preferably lower than 1×10¹⁷ cm⁻³, further preferably lower than 1×10¹⁵ cm⁻³, still further preferably lower than 1×10¹³ cm⁻³, yet still further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is preferably reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor. Note that depending on circumstances, an oxide semiconductor with a relatively high carrier concentration can be used for an OS transistor. Specifically, the carrier concentration in the channel formation region of the oxide semiconductor may exceed 1×10¹⁸ cm⁻³, for example.

A highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. Thus, a transistor whose channel formation region is formed in an oxide semiconductor having a high density of trap states has unstable electrical characteristics in some cases.

Accordingly, in order to obtain stable electrical characteristics of the transistor, reducing the concentration of impurities in the oxide semiconductor is effective. In order to reduce the impurity concentration in the oxide semiconductor, the impurity concentration in a film that is adjacent to the oxide semiconductor is preferably reduced. Examples of the impurity include hydrogen and nitrogen. Note that an impurity in an oxide semiconductor refers to, for example, elements other than the main components of the oxide semiconductor. For example, an element with a concentration lower than 0.1 atomic % is regarded as an impurity.

When impurities and oxygen vacancies are in a channel formation region in an oxide semiconductor in the OS transistor, electrical characteristics of the OS transistor easily change, which might degrade the reliability. In the OS transistor, a defect that is an oxygen vacancy in the oxide semiconductor into which hydrogen enters (VoH described in Embodiment 2) may be formed and may generate an electron serving as a carrier. When VoH is formed in the channel formation region, the donor concentration in the channel formation region increases in some cases. As the donor concentration in the channel formation region increases, the threshold voltage might vary. Accordingly, when the channel formation region in the oxide semiconductor includes oxygen vacancies, the transistor tends to have normally-on characteristics (a state where a channel exists and a current flows through the transistor even when no voltage is applied to the gate electrode). Thus, impurities, oxygen vacancies, and VoH are preferably reduced as much as possible in the channel formation region in the oxide semiconductor.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With use of an oxide semiconductor having a larger band gap than silicon, the off-state current (also referred to as off-leakage current or Ioff) of the transistor can be reduced.

In the Si transistor, a short-channel effect (also referred to as SCE) appears as miniaturization of the transistor proceeds. Thus, it is difficult to miniaturize the Si transistor. One factor that causes the short-channel effect is a small band gap of silicon. By contrast, the OS transistor includes an oxide semiconductor that is a semiconductor material having a wide band gap, and thus can suppress the short-channel effect. In other words, a short-channel effect does not appear or hardly appears in the OS transistor.

The short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometimes referred to as S value), an increase in leakage current, and the like. Here, the S value means the amount of change in gate voltage in the subthreshold region by which the drain current is changed by one order of magnitude at a constant drain voltage.

The characteristic length is widely used as an indicator of resistance to a short-channel effect. The characteristic length is an indicator of curving of potential in a channel formation region. When the characteristic length is shorter, the potential rises more sharply, which means that the resistance to a short-channel effect is high.

The OS transistor is an accumulation-type transistor and a Si transistor is an inversion-type transistor. Accordingly, the OS transistor has a shorter characteristic length between a source region and a channel formation region and a shorter characteristic length between a drain region and the channel formation region than the Si transistor. Therefore, the OS transistor has higher resistance to a short-channel effect than the Si transistor. That is, in the case where a transistor with a short channel length is desired to be manufactured, the OS transistor is more suitable than the Si transistor.

Even in the case where the carrier concentration in an oxide semiconductor is reduced until a channel formation region becomes an i-type or substantially i-type region, the conduction band minimum of the channel formation region in a short-channel transistor decreases because of the Conduction-Band-Lowering (CBL) effect; thus, the energy difference between the conduction band minimum of a source region or a drain region and that of the channel formation region might decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source region and the drain region become n⁺-type regions.

The OS transistor having the above structure enables a semiconductor device to have favorable electrical characteristics even when the semiconductor device is miniaturized or highly integrated. For example, the semiconductor device can have favorable electrical characteristics even when the OS transistor has a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. In contrast, it is sometimes difficult for the Si transistor to have a gate length less than or equal to 20 nm or less than or equal to 15 nm because of appearance of a short-channel effect. Therefore, the OS transistor can be suitably used as a transistor having a short channel length as compared with the Si transistor. Note that the gate length refers to the length of a gate electrode in a direction in which carriers move inside a channel formation region during an operation of the transistor and to the width of a bottom surface of the gate electrode in a plan view of the transistor.

Miniaturization of the OS transistor can improve the high frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz at room temperature, for example.

As described above, the OS transistor has an effect superior to that of the Si transistor, such as a low off-state current and capability of having a short channel length.

Note that this embodiment can be combined with the same embodiment or any of the other embodiments in this specification as appropriate. For example, the configurations, structures, methods, and the like described in this embodiment can be used in an appropriate combination with any of the other configurations, the other structures, the other methods, and the like described in the same embodiment. For another example, the configurations, structures, methods, and the like described in this embodiment can be used in an appropriate combination with any of the configurations, structures, methods, and the like described in the other embodiments and the like.

### Embodiment 8

In this embodiment, electronic components, electronic devices, a large computer, space equipment, and a data center (also referred to as DC) in which the semiconductor device described in the above embodiment can be used will be described. Electronic components, electronic devices, a large computer, space equipment, and a data center in which the semiconductor device of one embodiment of the present invention is used are effective in improving performance, e.g., reducing power consumption.

### Electronic Component

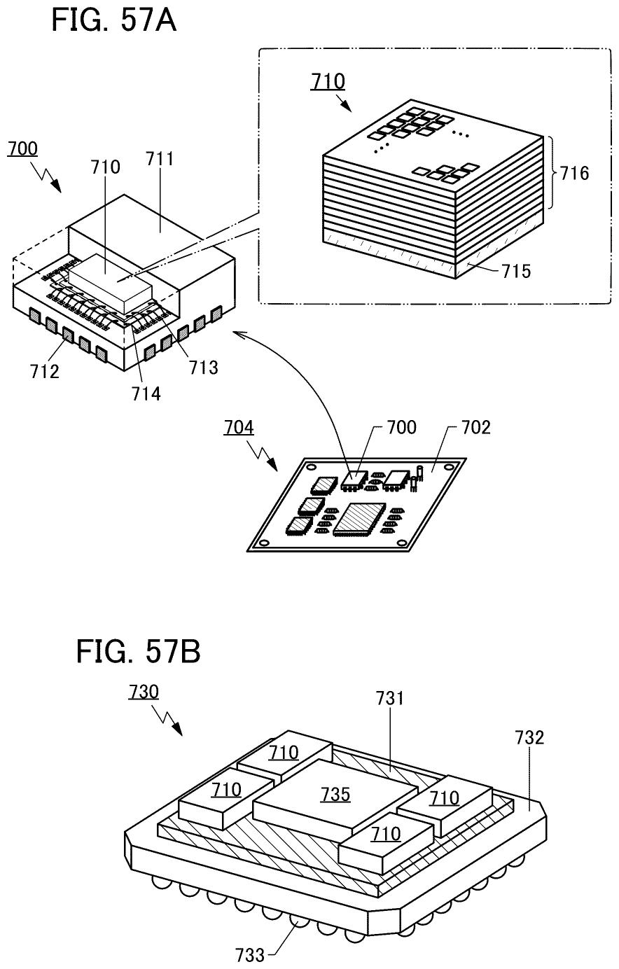

FIG. 57A shows a perspective view of a substrate (a circuit board 704) on which an electronic component 700 is mounted. The electronic component 700 illustrated in FIG. 57A includes a semiconductor device 710 in a mold 711. Some components are omitted in FIG. 57A to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the circuit board 704.

The semiconductor device 710 includes a driver circuit layer 715 and a memory layer 716. The memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique (e.g., TSV (Through Silicon Via)) or a bonding technique such as Cu-to-Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is employed; thus, the number of connection pins can be increased. An increase in the number of connection pins enables parallel operations, which can increase the bandwidth of the memory (also referred to as a memory bandwidth).

It is preferable that the plurality of memory cell arrays included in the memory layer 716 be formed using OS transistors and the plurality of memory cell arrays be monolithically stacked. Monolithically stacking the plurality of memory cell arrays can improve one or both of a memory bandwidth and a memory access latency. Note that a bandwidth refers to a data transfer volume per unit time, and an access latency refers to time from access to start of data transmission. In the case where the memory layer 716 is formed using Si transistors, it is difficult to obtain the monolithic stacked-layer structure as compared with the case where the memory layer 716 is formed using OS transistors. Thus, an OS transistor is superior to a Si transistor in the monolithic stacked-layer structure.

The semiconductor device 710 can be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Examples of a semiconductor material that can be used for a die include silicon (Si), silicon carbide (SiC), and gallium nitride (GaN). A die obtained from a silicon substrate (also referred to as a silicon wafer) may be referred to as a silicon die, for example.

FIG. 57B shows a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of the semiconductor devices 710 are provided over the interposer 731.

The electronic component 730 that includes the semiconductor device 710 as a high bandwidth memory (HBM) is illustrated as an example. The semiconductor device 735 can be used for an integrated circuit such as a CPU, a GPU, or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP or an MCM that includes a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected to each other using a silicon interposer and TSV, a space for the width of the terminal pitches and the like is needed. Thus, in the case where the size of the electronic component 730 is to be reduced, the width of the terminal pitches causes a problem, which sometimes makes it difficult to provide a large number of wirings for a wide memory bandwidth. For this reason, the above-described monolithic stacked-layer structure using OS transistors is suitable. A composite structure combining memory cell arrays stacked using TSV and monolithically stacked memory cell arrays can be employed, for example. A structure combining memory cell arrays stacked using a TSV and monolithically stacked memory cell arrays is referred to as a composite structure in some cases.

When the temperature of the electronic component 730 is increased by current heat or the like, various characteristics of a circuit element (e.g., a transistor) provided in the electronic component 730 might be degraded; thus, a heat sink (a radiator plate) is preferably provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 can be provided on a bottom portion of the package substrate 732. FIG. 57B shows an example in which the electrode 733 is formed of a solder ball. Solder balls are provided in a matrix on the bottom portion of the package substrate 732, so that BGA (Ball Grid Array) mounting can be achieved. Alternatively, the electrode 733 can be formed of a conductive pin. When conductive pins are provided in a matrix on the bottom portion of the package substrate 732, PGA (Pin Grid Array) mounting can be achieved.

The electronic component 730 can be mounted on another substrate by any of various mounting methods not limited to BGA and PGA. Examples of a mounting method include an SPGA (Staggered Pin Grid Array), an LGA (Land Grid Array), a QFP (Quad Flat Package), a QFJ (Quad Flat J-leaded package), and a QFN (Quad Flat Non-leaded package).

### Electronic Device

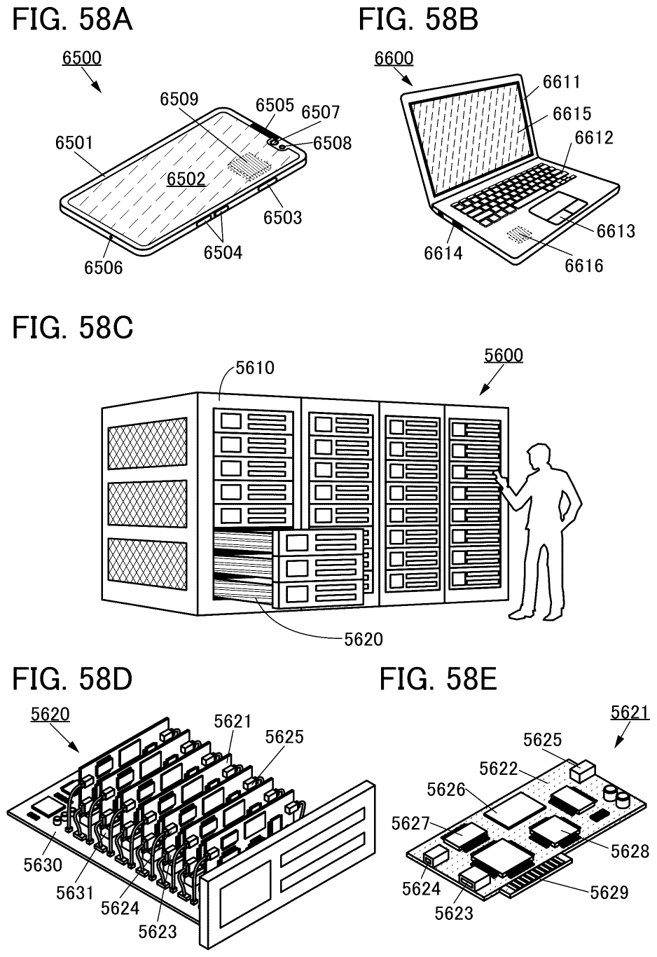

FIG. 58A shows a perspective view of an electronic device 6500. The electronic device 6500 illustrated in FIG. 58A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, and a control device 6509. One or more selected from a CPU, a GPU, and a memory device are provided as the control device 6509, for example. The semiconductor device of one embodiment of the present invention can be used for the display portion 6502, the control device 6509, and the like.

An electronic device 6600 illustrated in FIG. 58B is an information terminal that can be used as a laptop personal computer. The electronic device 6600 includes a housing 6611, a keyboard 6612, a pointing device 6613, an external connection port 6614, a display portion 6615, and a control device 6616. One or more selected from a CPU, a GPU, and a memory device are provided as the control device 6616, for example. The semiconductor device of one embodiment of the present invention can be used for the display portion 6615, the control device 6616, and the like.

The semiconductor device of one embodiment of the present invention is suitably used for the control device 6509 and the control device 6616, in which case power consumption can be reduced.

### Large Computer

FIG. 58C shows a perspective view of a large computer 5600. In the large computer 5600 illustrated in FIG. 58C, a plurality of rack mount computers 5620 are stored in a rack 5610. Note that the large computer 5600 is referred to as a supercomputer in some cases.

The computer 5620 can have a structure in a perspective view shown in FIG. 58D, for example. In FIG. 58D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 58E is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Although FIG. 58E illustrates semiconductor devices other than the semiconductor device 5626, the semiconductor device 5627, and the semiconductor device 5628, the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

Space Equipment

The semiconductor device of one embodiment of the present invention can be suitably used for space equipment (e.g., equipment having a function of processing and storing information).

The semiconductor device of one embodiment of the present invention can include an OS transistor. A change in electrical characteristics of the OS transistor due to radiation irradiation is small. That is, the OS transistor is highly resistant to radiation and thus can be suitably used in an environment where radiation can enter. For example, the OS transistor can be suitably used in outer space.

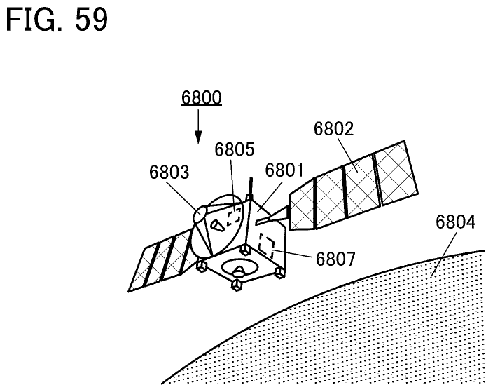

FIG. 59 illustrates an artificial satellite 6800 as an example of space equipment. The artificial satellite 6800 includes a body 6801, a solar panel 6802, an antenna 6803, a secondary battery 6805, and a control device 6807. FIG. 59 illustrates a planet 6804 in outer space, for example. Note that outer space refers to, for example, space at an altitude greater than or equal to 100 km, and outer space in this specification also includes thermosphere, mesosphere, and stratosphere in some cases.

Although not illustrated in FIG. 59, a battery management system (also referred to as BMS) or a battery control circuit can be provided in the secondary battery 6805. The battery management system or the battery control circuit preferably includes an OS transistor, in which case power consumption is low and high reliability is achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, power required for an operation of the artificial satellite 6800 is generated. However, for example, in the situation where the solar panel is not irradiated with sunlight or in the situation where the amount of sunlight with which the solar panel is irradiated is small, the amount of generated power is small. Accordingly, power required for an operation of the artificial satellite 6800 might not be generated. In order to operate the artificial satellite 6800 even with a small amount of generated power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can constitute a satellite positioning system.

The control device 6807 has a function of controlling the artificial satellite 6800. The control device 6807 is formed using one or more selected from a CPU, a GPU, and a memory device, for example. Note that the semiconductor device of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of space equipment in this embodiment, one embodiment of the present invention is not limited thereto. The semiconductor device of one embodiment of the present invention can be suitably used for space equipment such as a spacecraft, a space capsule, or a space probe, for example.

As described above, an OS transistor has excellent effects of achieving a wide memory bandwidth and being highly resistant to radiation as compared with a Si transistor.

### Data Center

The semiconductor device of one embodiment of the present invention can be suitably used for a storage system used in a data center, for example. Long-term management of data, such as guarantee of data immutability, is required for the data center. The long-term management of data needs an increase in building size owing to installation of storages and servers for storing an enormous amount of data, a stable power source for data retention, cooling equipment necessary for data retention, and the like.

With use of the memory device of one embodiment of the present invention for the storage system used in the data center, power required for data retention can be reduced and a memory device retaining data can be downsized. Thus, downsizing of the storage system, downsizing of the power source for data retention, downscaling of the cooling equipment, and the like can be achieved, for example. This can reduce the space of the data center.

Since the memory device of one embodiment of the present invention has low power consumption, heat generation from a circuit can be reduced. Accordingly, adverse effects of the heat generation on each of the circuit itself, the peripheral circuit, and the module can be reduced. Furthermore, the use of the memory device of one embodiment of the present invention enables a data center that operates stably even in a high-temperature environment. Thus, the reliability of the data center can be increased.

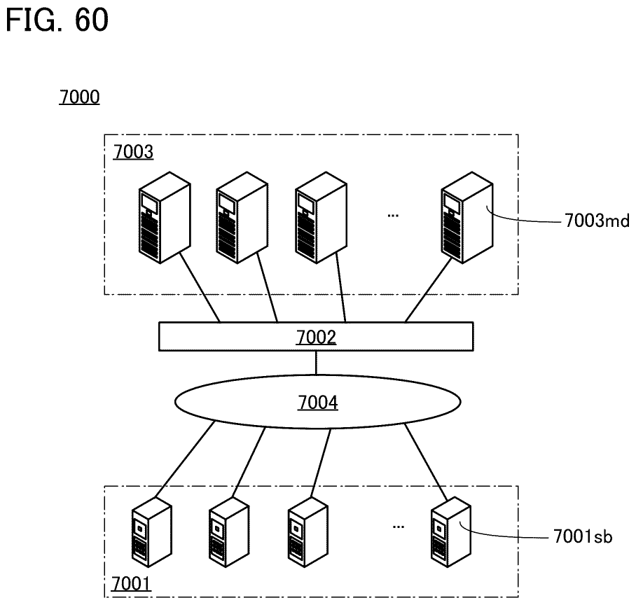

FIG. 60 illustrates a storage system that can be used in a data center. A storage system 7000 illustrated in FIG. 60 includes a plurality of servers 7001sb as a host 7001. The storage system 7000 includes a plurality of memory devices 7003md as a storage 7003. In the illustrated mode, the host 7001 and the storage 7003 are connected to each other through a storage area network 7004 and a storage control circuit 7002.

The host 7001 corresponds to a computer that accesses data stored in the storage 7003. The host 7001 is connected to another host 7001 through a network in some cases.

The data access speed, i.e., the time taken for storing and outputting data, of the storage 7003 is shortened by using a flash memory, but the time is still considerably longer than the time required for a DRAM that can be used as a cache memory in the storage. In the storage system, in order to solve the problem of low access speed of the storage 7003, a cache memory is usually provided in the storage to shorten the time taken for storing and outputting data.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

The use of the semiconductor device of one embodiment of the present invention for one or more selected from an electronic component, an electronic device, a large computer, space equipment, and a data center will produce an effect of reducing power consumption. While the demand for energy will increase with increasing performance and integration degree of semiconductor devices, the use of the semiconductor device of one embodiment of the present invention can thus reduce the emission amount of greenhouse gas typified by carbon dioxide (CO₂). The semiconductor device of one embodiment of the present invention can be effectively used as one of the global warming countermeasures because of its low power consumption.

Note that this embodiment can be combined with the same embodiment or any of the other embodiments in this specification as appropriate. For example, the configurations, structures, methods, and the like described in this embodiment can be used in an appropriate combination with any of the other configurations, the other structures, the other methods, and the like described in the same embodiment. For another example, the configurations, structures, methods, and the like described in this embodiment can be used in an appropriate combination with any of the configurations, structures, methods, and the like described in the other embodiments and the like.

### REFERENCE NUMERALS

MDV0: memory device, MDV0A: memory device, MC: memory cell, MC1: memory cell, MC2: memory cell, MC3: memory cell, M1: transistor, M1a: transistor, M1b: transistor, M2: transistor, M3: transistor, M4: transistor, M5: transistor, M6: transistor, M7: transistor, M8: transistor, M9: transistor, M10: transistor, MS1: transistor, MS2: transistor, MS3: transistor, MS4: transistor, M1101: transistor, M1102: transistor, M1103: transistor, M1201: transistor, M1211: transistor, M1212: transistor, M1213: transistor, M1214: transistor, M1221: transistor, M1222: transistor, M1231: transistor, M1232: transistor, M1233: transistor, M1241: transistor, M1242: transistor, M1243: transistor, M1251: transistor, M1252: transistor, M1253: transistor, M1254: transistor, M1261: transistor, M1262: transistor, M1263: transistor, C1: capacitor, C1a: capacitor, C1b: capacitor, C2: capacitor, C3: capacitor, C4: capacitor, C5: capacitor, C1101: capacitor, C1201: capacitor, IS1: insulating layer, IS2: insulating layer, IS2v: insulating film, IS3: insulating layer, IS3v: insulating film, IS4: insulating layer, DI1: insulating layer, GI1: insulating layer, IB1: insulating layer, IB2: insulating layer, IB3: insulating layer, IB4: insulating layer, IB5: insulating layer, IB6: insulating layer, LI1: insulating layer, LI2: insulating layer, LI3: insulating layer, LI4: insulating layer, ME1: conductive layer, ME1v: conductive film, ME2: conductive layer, ME3: conductive layer, ME4: conductive layer, ME4v: conductive film, ME4w: conductive film, ME5: conductive layer, LM1: conductive layer, LM2: conductive layer, LM3: conductive layer, LM4: conductive layer, LM5: conductive layer, SC1: semiconductor layer, SC1v: semiconductor film, KK1: opening, KK2: opening, PON1: signal, PON2: signal, ADDR: signal, BW: signal, CE: signal, GW: signal, CLK: signal, WAKE: signal, WDA: signal, RDA: signal, BL: wiring, BLa: wiring, BLb: wiring, BLB: wiring, BRL: wiring, WL: wiring, WWL: wiring, WBL: wiring, RWL: wiring, RBL: wiring, SL: wiring, VDL: wiring, GNL: wiring, CVL: wiring, OL: wiring, OLa: wiring, OLb: wiring, VCP: wiring, VPL: wiring, EQL: wiring, IVL: wiring, SWL: wiring, BK: wiring, RV: wiring, SE: wiring, PCK: wiring, GBK: wiring, D: wiring, SD: wiring, SD_IN: wiring, Q: wiring, SWIL: wiring, SW2L: wiring, SW3L: wiring, LBL: wiring, LBLB: wiring, GBL: wiring, GBLB: wiring, SA_GBL: wiring, SA_GBLB: wiring, SRC: wiring, RE: wiring, WE: wiring, MX: wiring, DBL: wiring, DBLB: wiring, CSEL: wiring, VPRE: wiring, CM: wiring, EQ: wiring, EQB: wiring, SAP: wiring, SAN: wiring, MN: wiring, Df: input terminal, Qf: output terminal, MCA: memory cell array, EQP: circuit, ILP: circuit, OP: circuit, SA: circuit, SW1a: switch, SW1b: switch, SW2: switch, SWVa: switch, SWVb: switch, SWOa: switch, SWOb: switch, IVa: inverter, IVb: inverter, T1111: Period, T1112: Period, T1113: Period, T1114: Period, T1121: Period, T1122: Period, T1123: Period, T1124: Period, T1125: Period, T1126: Period, T1127: Period, T1211: Period, T1212: Period, T1213: Period, T1214: Period, T1215: Period, T1216: Period, 10: memory cell, 10a: circuit, 10b: circuit, 22: PSW, 23: PSW, 31: peripheral circuit, 32: control circuit, 33: voltage generation circuit, 41: peripheral circuit, 42: row decoder, 43: row driver, 44: column decoder, 45: column driver, 46: sense amplifier, 47: input circuit, 48: output circuit, 50: driver circuit layer, 60: memory layer, 301: insulating layer, 311: substrate, 313: semiconductor region, 314a: low-resistance region, 314b: low-resistance region, 315: insulating layer, 316: conductive layer, 317: insulating layer, 320: insulating layer, 324: insulating layer, 326: insulating layer, 328: conductive layer, 330: conductive layer, 350: insulating layer, 353: insulating layer, 352: insulating layer, 356: conductive layer, 357: insulating layer, 358: conductive layer, 400: transistor, 700: electronic component, 702: printed circuit board, 704: circuit board, 710: semiconductor device, 711: mold, 712: land, 713: electrode pad, 714: wire, 715: driver circuit layer, 716: memory layer, 730: electronic component, 731: interposer, 732: package substrate, 733: electrode, 735: semiconductor device, 910: driver circuit, 910L1: driver circuit, 910L2: driver circuit, 910L3: driver circuit, 910L4: driver circuit, 912: row decoder, 913: row driver, 914: column decoder, 915: column driver, 916: sense amplifier, 920: memory array, 920L1: memory cell array, 920L2: memory cell array, 920L3: memory cell array, 920L4: memory cell array, 921: memory cell, 921A: memory cell, 921B: memory cell, 921C: memory cell, 921D: memory cell, 921E: memory cell, 921F: memory cell, 921G: memory cell, 921H: memory cell, 930: layer, 940L1: connection electrode, 940L2: connection electrode, 940L3: connection electrode, 940L4: connection electrode, 950: layer, 960: arithmetic device, 970A: processing device, 970B: processing device, 970C: processing device, 970D: processing device, 970E: processing device, 989: cache interface, 990: substrate, 991: ALU, 992: ALU controller, 993: instruction decoder, 994: interrupt controller, 995: timing controller, 996: register, 997: register controller, 998: bus interface, 999: cache, 1000: processing device, 1010: processing portion, 1011: arithmetic portion, 1012: control portion, 1013: register portion, 1014: register unit, 1015: scan flip-flop circuit, 1016: backup memory, 1020: memory portion, 1021: memory array portion, 1022: control portion, 1023: memory block, 1024: memory unit, 1025: memory cell, 1026: sense amplifier, 1027: sub-sense amplifier, 1028: functional circuit, 1030: control portion, 1071: bus line, 1082: layer, 1083: layer, 1084: layer, 1085: layer, 1110: register, 1130: backup circuit, 1131: retention circuit, 1150: scan flip-flop circuit, 1151: selector circuit, 1152: flip-flop circuit, 1210: memory device, 1231: sub-sensing circuit, 1231B: sub-sensing circuit, 1232: switch circuit, 1241: memory cell, 1251: sensing circuit, 1252: switch circuit, 1253: precharge circuit, 1254: precharge circuit, 1255: amplifier circuit, 5600: large computer, 5610: lack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: mother board, 5631: slot, 6500: electronic device, 6501: housing, 6502: display portion, 6503: power button, 6504: button, 6505: speaker, 6506: microphone, 6507: camera, 6508: light source, 6509: control device, 6600: electronic device, 6611: housing, 6612: keyboard, 6613: pointing device, 6614: external connection port, 6615: display portion, 6616: control device, 6800: artificial satellite, 6801: body, 6802: solar panel, 6803: antenna, 6804: planet, 6805: secondary battery, 6807: control device, 7000: storage system, 7001: host, 7001sb: server, 7002: storage control circuit, 7003: storage, 7003md: memory device, 7004: storage area network

1. A semiconductor device comprising:
a transistor and a capacitor,
wherein the transistor is positioned above the capacitor,
wherein the transistor comprises:
a first conductive layer configured to function as one of a source and a drain of the transistor;
a semiconductor layer comprising a channel formation region of the transistor;
a second conductive layer configured to function as the other of the source and the drain of the transistor;
a first insulating layer configured to function as a gate insulating film of the transistor; and
a third conductive layer configured to function as a gate of the transistor,
wherein the second conductive layer is positioned above the first conductive layer with a second insulating layer therebetween,
wherein, in a cross-sectional view, the second insulating layer and the second conductive layer comprise a first opening reaching the first conductive layer,
wherein the semiconductor layer comprises a region in contact with a side surface of each of the second insulating layer and the second conductive layer in the first opening, a region in contact with a top surface of the first conductive layer in the first opening, and a region in contact with a top surface of the second conductive layer,
wherein the first insulating layer comprises regions a region in contact with a top surface of the semiconductor layer and a region in contact with a top surface of the second insulating layer,
wherein the third conductive layer positioned above the first insulating layer comprises a region overlapping with the first opening and the semiconductor layer,
wherein, in the cross-sectional view, the capacitor comprises:
a first capacitor region in a second opening provided in a third insulating layer; and
a second capacitor region in a region overlapping with a top surface of the third insulating layer,
wherein the first conductive layer is configured to function as one electrode of a pair of electrodes of the capacitor in each of the first capacitor region and the second capacitor region, and
wherein, in the cross-sectional view, the first opening comprises a region overlapping with at least the part of the first conductive layer that is included in the second capacitor region.

2.

2. The semiconductor device according to claim 1,
wherein the capacitor comprises a fourth insulating layer configured to function as a dielectric and a fourth conductive layer configured to function as the other electrode of the pair of electrodes of the capacitor,
wherein the fourth conductive layer comprises regions a region in contact with a side surface of the third insulating layer the second opening and a region in contact with the top surface of the third insulating layer,
wherein the fourth insulating layer comprises a region in contact with a top surface of the fourth conductive layer and a region in contact with the top surface of the third insulating layer,
wherein the first conductive layer positioned above the fourth insulating layer comprises a region overlapping with the fourth conductive layer, and
wherein the capacitor has a trench structure in the first capacitor region.

3. The semiconductor device according to claim 2, further comprising a fifth conductive layer,
wherein the second opening reaches the fifth conductive layer, and
wherein the fourth conductive layer comprises a region in contact with a top surface of the fifth conductive layer in the second opening.

4. The semiconductor device according to claim 1,
wherein the channel formation region in the semiconductor layer comprises one or more selected from indium, zinc, and an element M, and
wherein the element M is one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, cobalt, magnesium, and antimony.

5. A memory device comprising a memory layer comprising a first memory cell including the semiconductor device according to claim 1, a second memory cell including the semiconductor device according to claim 1, and a driver circuit,
wherein the memory layer is positioned above the driver circuit, and
wherein the driver circuit comprises a write circuit configured to transmit writing data to the semiconductor device of the first memory cell and the semiconductor device of the second memory cell, a read circuit configured to read data retained in the semiconductor device of the first memory cell and the semiconductor device of the second memory cell, and a selection circuit configured to select the semiconductor device of the first memory cell and/or the semiconductor device of the second memory cell to which the writing data is to be transmitted or from which the data is to be read.

6. The memory device according to claim 5, further comprising a plurality of the memory layers,
wherein the plurality of the memory layers are stacked above the driver circuit.

7. An electronic device comprising the memory device according to claim 6 and a housing.

8. A processing device comprising:
a processing portion;
a sense amplifier; and
a memory cell,
wherein the memory cell is positioned above the processing portion and the sense amplifier,
wherein the memory cell is configured to retain data related to a task processed in the processing portion,
wherein the sense amplifier is configured to read the data retained in the memory cell,
wherein the memory cell comprises a transistor and a capacitor,
wherein the transistor is positioned above the capacitor,
wherein the transistor comprises:
a first conductive layer configured to function as one of a source and a drain, drain of the transistor;
a semiconductor layer comprising a channel formation region of the transistor;
a second conductive layer configured to function as the other of the source and the drain of the transistor;
a first insulating layer configured to function as a gate insulating film of the transistor; and
a third conductive layer configured to function as a gate of the transistor,
wherein the second conductive layer is positioned above the first conductive layer with a second insulating layer therebetween,
wherein, in a cross-sectional view, the second insulating layer and the second conductive layer comprise a first opening reaching the first conductive layer,
wherein the semiconductor layer comprises a region in contact with a side surface of each of the second insulating layer and the second conductive layer in the first opening, a region in contact with a top surface of the first conductive layer bottom portion of in the first opening, and a region in contact with a top surface of the second conductive layer,
wherein the first insulating layer comprises a region in contact with a top surface of the semiconductor layer and a region in contact with a top surface of the second insulating layer,
wherein the third conductive layer positioned above the first insulating layer comprises a region overlapping with the first opening and the semiconductor layer,
wherein, in the cross-sectional view, the capacitor comprises:
a first capacitor region in a second opening provided in a third insulating layer positioned below the second insulating layer; and
a second capacitor region in a region overlapping with a top surface of the third insulating layer,
wherein the first conductive layer is configured to function as one electrode of a pair of electrodes of the capacitor in each of the first capacitor region and the second capacitor region, and
wherein, in the cross-sectional view, the first opening comprises a region overlapping with at least the part of the first conductive layer that is included in the second capacitor region.

9. The processing device according to claim 8,
wherein the memory cell is configured to be a cache memory or a main memory in the processing portion.

10. The processing device according to claim 9,
wherein the processing portion comprises a control portion, an arithmetic portion, a scan flip-flop circuit, and a backup circuit,
wherein the control portion is configured to perform power gating on the scan flip-flop circuit,
wherein the scan flip-flop circuit is configured to retain the data related to the task processed in the arithmetic portion, and
wherein the backup circuit is configured to retain the data while power supply to the scan flip-flop circuit is stopped by the power gating.

11. The processing device according to claim 10, further comprising a first layer,
wherein the first layer comprises the sense amplifier, the control portion, the arithmetic portion, the scan flip-flop circuit, and a driver circuit, and
wherein the driver circuit comprises a write circuit configured to transmit writing data to the memory cell and a selection circuit configured to select the memory cell for data writing or data reading.

12. The processing device according to claim 11, further comprising a second layer positioned above the first layer,
wherein the second layer comprises a plurality of memory cell arrays each comprising the memory cell, and
wherein the plurality of memory cell arrays are stacked.

13. The processing device according to claim 8,
wherein the capacitor comprises a fourth insulating layer configured to function as a dielectric and a fourth conductive layer configured to function as the other electrode of the pair of electrodes of the capacitor,
wherein the fourth conductive layer comprises a region in contact with a side surface of the third insulating layer in the second opening and a region in contact with the top surface of the third insulating layer,
wherein the fourth insulating layer comprises a region in contact with a top surface of the fourth conductive layer and a region in contact with the top surface of the third insulating layer,
wherein the first conductive layer positioned above the fourth insulating layer comprises a region overlapping with the fourth conductive layer, and
wherein the capacitor has a trench structure in the first capacitor region.

14. The processing device according to claim 13, further comprising a fifth conductive layer comprising a region overlapping with the third insulating layer,
wherein the second opening reaches the fifth conductive layer, and
wherein the fourth conductive layer comprises a region in contact with a top surface of the fifth conductive layer in the second opening.

15. The processing device according to claim 14,
wherein the channel formation region in the semiconductor layer comprises one or more selected from indium, zinc, and an element M, and
wherein the element M is one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, cobalt, magnesium, and antimony.
